(19) United States
(12) Patent Application Publication
(10) Pub. No.: US 2026/0278191 A1
(43) Pub. Date: Sep. 17, 2026

(54) ARTIFICIAL INTELLIGENCE DETERMINATION OF BUILDING CODE COMPLIANCE RELATING TO WHEEL CHAIR TURNING CLEARANCE

(71) Applicant: CodeComply.Ai, Corp., Miami, FL (US)

(72) Inventors: Michael Sheehan, Coral Gables, FL (US); Matthew Foley, Boxborough, MA (US); Patrick E Murphy, Miami, FL (US); Johnny Maghzal, Miami, FL (US)

(73) Assignee: CodeComply.Ai, Corp., Miami, FL (US)

(21) Appl. No.: 19/471,689

(22) PCT Filed: Aug. 30, 2024
(86) PCT No.: PCT/US2024/044877

§ 371 Date: Oct. 1, 2025

Related U.S. Application Data
(60) Provisional application No. 63/535,703, filed on Aug. 31, 2023.

(51) Int. Cl. G06F 30/13; G01C 21/20; G06Q 30/018

(52) U.S. Cl. CPC G06F 30/13; G01C 21/206; G06Q 30/018

(57) ABSTRACT

Methods and apparatus operative to analyze wheelchair turning clearance within building design plans are disclosed. The invention utilizes artificial intelligence (AI) to convert design plans into dynamic components representing structural elements and fixtures. A controller identifies critical wheelchair turning points, calculates turning radii, and compares them against compliance conditions specified by relevant building codes. The system includes an interactive user interface that allows users to view, modify, and interact with design components in real-time. The AI engine simulates wheelchair navigation, predicts occupancy loads, and evaluates surface conditions to determine safe and accessible routes, particularly to points of egress. The apparatus further provides visual indicators of compliance and suggests modifications for non-compliant areas.

### CROSS REFERENCE TO RELATED APPLICATIONS

This application is a U.S. National Phase Application of International Application Number PCT/US24/44877, filed Aug. 30, 2024, and entitled ARTIFICIAL INTELLIGENCE DETERMINATION OF BUILDING CODE COMPLIANCE RELATING TO WHEEL CHAIR TURNING CLEARANCE, which in turn claims priority to U.S. Provisional Application Number 63/535,703, filed Aug. 31, 2023, and entitled ARTIFICIAL INTELLIGENCE DETERMINATION OF BUILDING CODE COMPLIANCE RELATING TO WHEEL CHAIR TURNING CLEARANCE, the entire disclosures of each of which are incorporated herein by reference.

### FIELD OF THE INVENTION

The present invention provides improved methods and apparatus for analyzing wheelchair turning clearance within building design plans to determine compliance with relevant building codes and accessibility standards. Utilizing artificial intelligence (AI), the invention allows for the detailed evaluation of design components, including structural elements and fixtures, to assess their impact on wheelchair maneuverability. The invention further enhances the design process through an interactive user interface that enables real-time modifications, simulations, and visual feedback, thereby facilitating the creation of accessible and safe environments for wheelchair users in various building types.

### BACKGROUND OF THE INVENTION

The use of wheelchairs is a daily reality for millions of people worldwide who depend on these mobility aids to navigate their environments. In the United States alone, the number of wheelchair users is substantial, with estimates suggesting that approximately 3.6 million people aged 15 and older rely on wheelchairs for mobility. This number includes individuals with a wide range of disabilities, such as spinal cord injuries, neuromuscular disorders, multiple sclerosis, and age-related conditions that impair mobility. The situation is similar on a global scale, where the World Health Organization (WHO) estimates that 1.85% of the world's population, or roughly 131.8 million people, use a wheelchair. This demographic is diverse, encompassing people of all ages, ethnicities, and socioeconomic backgrounds, highlighting the universal need for accessible infrastructure that accommodates the specific requirements of wheelchair users.

In the context of building designs, accessibility is not limited to providing ramps or elevators. One of the most critical aspects of accessibility involves the space required for wheelchair maneuverability, particularly in situations where turning is necessary. Wheelchair users often face significant challenges when attempting to navigate spaces that lack adequate turning radii. For example, a standard manual wheelchair requires a turning radius of approximately 60 inches, while a power wheelchair may require even more space due to its larger size and different steering mechanisms. This requirement is especially pertinent in areas such as narrow corridors, restrooms, and rooms with fixed furniture or equipment. Inadequate space for turning can render these areas inaccessible to wheelchair users, limiting their ability to move freely and independently within a building. Moreover, insufficient turning space can increase the risk of accidents, as wheelchair users may struggle to navigate tight corners or may be forced to make multiple attempts to turn around, leading to frustration and potential injury.

Building codes and accessibility standards around the world recognize the importance of accommodating wheelchair users in the built environment. In the United States, the Americans with Disabilities Act (ADA) sets forth comprehensive requirements to ensure that buildings are accessible to individuals with disabilities, including those who use wheelchairs. The ADA Standards for Accessible Design provide detailed specifications on the dimensions and features of spaces that must be designed to allow for wheelchair access and maneuverability. For example, these standards mandate that restrooms, corridors, and other public spaces must include a clear turning space of at least 60 inches in diameter to allow a wheelchair to turn in place. This requirement is not only about providing access but also about ensuring that wheelchair users can navigate these spaces safely and efficiently.

Other countries have implemented similar regulations to address the needs of wheelchair users. In the United Kingdom, the Equality Act 2010 and its accompanying regulations require that buildings be accessible to individuals with disabilities, including those who use wheelchairs. The UK's Approved Document M offers guidance on how to comply with these regulations, including specific requirements for the space needed for wheelchair users to turn in different types of buildings. In Australia, the Disability Discrimination Act (DDA) and the National Construction Code (NCC) include provisions that require buildings to be designed and constructed in a way that provides access for wheelchair users. These standards reflect a global recognition of the importance of accessible design, which is increasingly seen as a fundamental aspect of building design rather than a mere afterthought.

Traditionally, the process of determining whether a building design complies with these accessibility standards has been manual and labor-intensive. Architects, designers, and building code officials typically review design plans to assess whether they meet the required standards for wheelchair accessibility. This process often involves the use of checklists, measuring tools, and software applications that help identify areas where the design might fall short of compliance. However, the task of determining if a building allows for adequate wheelchair turning space is particularly challenging. It requires a nuanced understanding of the various factors that can affect maneuverability, including the layout of the space, the presence of obstacles, and the specific types of wheelchairs that are likely to be used.

One of the major drawbacks of this traditional approach is the potential for human error. Building codes and accessibility standards can be complex and open to interpretation, leading to inconsistencies in how they are applied. Different reviewers may have different opinions about whether a particular design meets the necessary requirements, resulting in variability in the level of accessibility provided. Moreover, the process of manually reviewing design plans is time-consuming and requires a high level of expertise. This can be particularly problematic in large or complex projects, where the sheer volume of design information can make it difficult to identify every potential issue related to wheelchair accessibility. As a result, some areas may be overlooked, leading to non-compliance with accessibility standards and creating barriers for wheelchair users.

Another significant challenge associated with traditional compliance determination is the dynamic nature of building design. As a project evolves, design plans may undergo multiple revisions, each of which must be reviewed to ensure continued compliance with accessibility standards. This iterative process can introduce additional opportunities for errors or omissions, particularly if changes to the design are not fully documented or understood. Furthermore, as the design progresses from concept to detailed construction documents, the focus may shift from accessibility to other priorities, such as cost, aesthetics, or functionality. This shift can lead to compromises in the design that negatively impact the accessibility of the final built environment.

The ongoing evolution of building codes and accessibility standards further complicates the process of determining compliance. Building codes are regularly updated to reflect new research, emerging technologies, and changing societal expectations regarding accessibility. Keeping up with these changes requires continuous education and training for architects, designers, and building code officials. However, the rapid pace of change can make it difficult for professionals to stay current with the latest requirements, increasing the risk that design plans may not fully comply with the most up-to-date standards. This is particularly concerning in the context of wheelchair accessibility, where even minor deviations from the required dimensions can have a significant impact on the usability of a space for wheelchair users.

Given these challenges, there is a clear need for an improved system and method for determining compliance with accessibility standards, particularly with regard to wheelchair turning and maneuverability. Such a system would need to overcome the limitations of the traditional approach by providing a more objective, accurate, and efficient means of assessing design plans. It should be capable of analyzing complex building layouts and identifying potential issues related to wheelchair accessibility, including the space required for turning and maneuvering. Additionally, the system should be able to accommodate the continuous changes in building codes, so that the analysis is always based on the most current standards.

Moreover, an improved system should integrate seamlessly into the design and construction process, allowing for real-time analysis of design plans as they evolve. This would enable designers and compliance officers to identify and address potential issues early in the process, reducing the need for costly and time-consuming revisions later on. By automating the analysis of design plans, such a system could also help to reduce the potential for human error, providing a more consistent and reliable means of determining compliance with accessibility standards.

In conclusion, the growing number of wheelchair users worldwide underscores the importance of accessible design in the built environment. While existing building codes provide a framework for achieving accessibility, the traditional methods for determining compliance have significant limitations, including the potential for human error, the time-consuming nature of manual review, and the challenges associated with keeping up with evolving standards. There is a pressing need for an improved system that can more effectively and efficiently assess design plans for compliance with accessibility standards, particularly with regard to wheelchair turning and maneuverability. Such a system would not only enhance the accuracy and consistency of compliance determinations but also support the creation of more accessible and inclusive environments for wheelchair users around the world.

### SUMMARY OF THE DISCLOSURE

Accordingly, the present disclosure provides methods and apparatus for deploying artificial intelligence (“AI”) analyzing two-dimensional (sometimes referred to as “2D”) documents, such as design plans, floor plans, or other architectural drawing type document, to ascertain one or both of a proposed use of the building, or an area within the building (which may be referred to herein collectively as a “design plan”) and values for variables pertinent to an analysis of clear areas, such as clear areas in a washroom, restroom, corridors, or other spaces where wheelchair maneuverability is critical, required by an authority having jurisdiction (“authority having jurisdiction”). An AI engine is constructed and trained to review a 2D document, identify critical features such as walls, doors, and fixtures, and ascertain a proposed use of the building and an occupant load for the building when used for the ascertained use. For example, the AI engine may determine that a space is intended for commercial use and calculate the expected number of occupants based on building code standards. The AI engine further evaluates whether adequate clearances, such as those required for wheelchair turning, door swings, and fixture placements, are present in the design plans.

The system analyzes critical wheelchair turning points, including intersections, room entrances, and corners, and compares the calculated turning radii against the required dimensions specified by the relevant building codes. For example, the AI may identify a turning space in a hallway intersection and calculate whether the space provides the necessary 60-inch diameter clearance for wheelchair users. If the turning space is insufficient, the AI engine can suggest modifications, such as widening corridors or repositioning fixtures, to enhance accessibility.

Additionally, the AI engine is designed to provide meaningful analysis and feedback, delivering results quickly, accurately, and consistently. These results are presented in an interactive user interface, where users can visualize compliant and non-compliant areas with color-coded indicators. The AI engine may also simulate scenarios, such as the movement of a wheelchair through a proposed path to assess real-world usability and compliance under various conditions, including emergency evacuations.

Embodiments of the present disclosure include the ability of the AI engine to adapt its analysis based on different wheelchair models, taking into account varying turning radii and dimensions, thereby determining if the design plan is versatile and inclusive. The AI engine can also evaluate surface conditions along the routes, such as ramp slopes and floor textures, to determine if they hinder wheelchair mobility.

In some embodiments of the present invention, a method comprises analyzing wheelchair turning clearance based upon artificial intelligence (AI) analysis of a building design plan, the process begins by receiving the design plan into a controller. This design plan can include detailed architectural drawings or floor layouts representing at least a portion of the building. The design plan provides a comprehensive overview of the building's spatial configuration, including critical elements such as walls, doors, corridors, and fixtures.

Upon receiving the design plan, the controller processes the information by converting it into multiple dynamic components. Each dynamic component within the design plan represents either a structural element, such as boundaries, paths, and spaces, or a fixture, such as furniture or equipment. The conversion into dynamic components allows the controller to break down the design plan into manageable and interactive segments. For example, a boundary may represent a wall or a partition, a path may represent a corridor or doorway, and a space may correspond to a room or an open area.

The controller then generates a first interactive user interface that visualizes at least some of these dynamic components. The interactive user interface may provide users with the ability to view, modify, and interact with the dynamic components of the design plan. For example, a user may adjust the width of a corridor, reposition a door, or modify the layout of a room. Each dynamic component includes parameters that can be changed via the interactive user interface, allowing users to explore different design configurations and their impact on wheelchair accessibility in real time.

Next, the controller identifies one or more wheelchair turning points within the design plan. Wheelchair turning points are critical areas where sufficient space must be available for a wheelchair user to turn around, such as hallway intersections, room entrances, or corners. The identification process may involve scanning the design plan for areas where a wheelchair user may need to execute a turn, highlighting these points for further analysis.

Once the turning points have been identified, the controller calculates the turning radius for each of these points. The turning radius is used determining whether the space available at each turning point is adequate for wheelchair maneuverability. For example, the controller may calculate whether a circular area with a minimum diameter of 60 inches is available at a given turning point, as required by certain accessibility standards. The calculation process takes into account the dimensions of the space and the positioning of any nearby fixtures or structural elements that may affect the available turning radius.

Following the calculation of the turning radius, the controller determines a set of conditions related to wheelchair turning clearance compliance. These conditions are based on the relevant building codes set forth by the authority having jurisdiction over the building. The controller cross-references the calculated turning radii against the required conditions to assess whether the design plan meets the necessary standards for wheelchair accessibility. For example, the set of conditions may include requirements for minimum clearances, allowable overlaps between turning areas and fixtures, and specific dimensions for turning spaces in various parts of the building.

The controller may also indicate within the first interactive user interface whether the building design is in compliance with the set of conditions related to wheelchair turning clearance. The compliance status is visually represented in the user interface, providing users with immediate feedback on the accessibility of their design. If the design is not in compliance, the interface may highlight the non-compliant areas and offer suggestions for modifications. These suggestions may include widening corridors, repositioning fixtures, or altering room layouts to create sufficient space for wheelchair users to navigate comfortably.

Methods and apparatus are disclosed to quantify metrics for the calculation of turning space of accessible bathrooms using artificial intelligence (sometimes referred to herein as “AI”) analysis to ensure code compliance under authorities having jurisdiction. The disclosed invention specifically addresses the challenges associated with providing wheelchair turning areas within restrooms, hallways, and other critical spaces to meet the required standards for accessibility.

Specifically, the present invention uses AI to determine an available turning space, and to ascertain whether the available turning spaces are in compliance with relevant codes according to the authority having jurisdiction, such as, but not limited to, codes derived from or the same as the American Disabilities Act. For example, the AI engine may evaluate whether a restroom provides sufficient clearance around fixtures like toilets and sinks to allow a wheelchair to turn safely and effectively.

The present invention reduces inconsistencies in condition compliance analysis, such as code compliance analysis, discretionary assumptions made by skilled workers and/or mistakes made by skilled workers. Traditional methods often rely on manual assessments, which can vary based on the individual's experience and interpretation of the codes. The present invention provides accurate calculation of available turning areas. Consistent feedback is available providing reasons why a building described by a two-dimensional reference is in or out of compliance with turning space (or other clear area) conditions, such as those set forth by an authority having jurisdiction. For example, the AI may highlight specific areas in a restroom where the turning radius falls short of the required dimensions, and it may provide a detailed explanation of why these areas are non-compliant.

Furthermore, according to some embodiments, suggestions may be made regarding how to cure non-compliance with a condition(s); or how to adopt a best practice pertaining to clearance analysis or design plan layout, and whether or not a best practice is required to meet an obligation dictated by a relevant code. These suggestions may include modifying the layout to increase space around doorways, repositioning fixtures to create unobstructed pathways, or adjusting the dimensions of certain areas to better accommodate wheelchair users.

According to the present invention, two-dimensional references, such as those from an authority having jurisdiction, and applicable codes concerning wheelchair turning radius is input into an AI engine and the AI engine converts aspects of the code into components that may be processed by the AI engine, such as a rasterized version of the of two-dimensional renderings. For example, the AI may convert a floor plan into a pixel-based image that highlights key areas like entrances, turning points, and fixture placements. These renderings are then processed with machine learning to specify portions that may be specified as discernable components. Discernable components may include dimensions and placement of architectural items, plumbing fixtures, or other items. The AI engine can, for example, isolate the dimensions of a restroom stall and analyze whether it meets the required clearance for wheelchair users.

A scaling process is applied to any two-dimensional references and size descriptors are assigned to the discernable components. This may involve the AI engine interpreting scale indicators or known dimensions within the design plan to accurately measure all elements of the layout. In addition, distances, such as placement of fixtures, are calculated. For example, the AI engine may calculate the distance between a sink and the nearest wall to determine if there is enough space for a wheelchair to maneuver.

Variables are specified from codes of authority having jurisdiction that will be used to assess compliance, and a compliance determination is made based upon values for the specified variables. For example, the AI may determine that a sink encroaches slightly into the required turning radius and assess whether this overlap is within acceptable limits according to the code. In some embodiments, the variables may include some or all of an amount permissible overlap of a particular plumbing fixture with a diameter of turning space available. The AI engine generates values for some or all of the variables referenced to determine compliance.

In some embodiments, a controller will also set forth conditions required to be in compliance with turning space requirements. Some embodiments may also include, in the case where the available radius is in violation of the code, the portions referenced in determining non-compliance. For example, the AI engine may identify that a restroom's layout does not provide sufficient turning space near the entrance, marking this area as non-compliant and suggesting specific changes. Further, some embodiments may include suggested changes and/or options for sets of changes to the design to accommodate turning space requirements that may be implemented in order to achieve compliance, and relevant methods of correcting such violations. The AI may suggest widening a corridor or repositioning a toilet to create a compliant turning space.

Using the methods and apparatus described herein, a determination of whether a turning space available is compliant for use by people with disabilities may also be generated. The present invention indicates how AI may be used in the design, construction, and compliance of turning space requirements meant for important advances in safety and accessibility for the handicapped community and to mitigate risk from inaccessibility or other adverse conditions. For example, by determining that all necessary turning spaces are compliant, the AI engine helps prevent scenarios where wheelchair users are unable to navigate safely through a building during an emergency.

In general, the present invention provides for apparatus and methods related to receiving as input authority having jurisdiction code, including table, drawings, and writings (either physical or electronic) and generating one or more-pixel patterns based upon automated processing of areas subject to clearance requirements. These pixel patterns may be used to visually represent compliant and non-compliant areas within a building layout, allowing designers to easily identify and address potential issues.

The pixel patterns are analyzed using computerized processing techniques to mimic the perception, learning, problem-solving, and decision-making formerly performed by human workers. The AI engine's ability to learn from previous analyses allows it to continuously improve in accuracy and efficiency over time.

Based upon AI analysis of pixel patterns derived from the two-dimensional references and knowledge accumulated from increasing volumes of analyzed two dimensional references, interactive user interfaces may be generated that allow for a user to modify dynamic design plans relating to areas that have clearance requirements gleaned from the two-dimensional reference. For example, the user may interact with a visual representation of the floor plan, making adjustments to the layout and immediately seeing how these changes impact compliance. AI processing of the pixel patterns, based upon the two-dimensional references, may include mathematical analysis of polygons formed by joining select vectors included in the two-dimensional reference. This mathematical analysis allows the AI engine to precisely calculate areas, distances, and clearances, so that all measurements meet the required standards. The analysis of pixel patterns and manipulatable vector interfaces and/or polygon-based interfaces is advantageous over human processing in that AI analysis of pixel patterns, vectors and polygons is capable of leveraging knowledge gained from one or both of: selected groups and learnings derived from similar previous bodies of work, whether or not a human requesting a current analysis was involved in the previous learnings. This capability allows the AI engine to apply best practices and insights gained from past projects, so that each new analysis is informed by a broad base of experience and knowledge.

In some embodiments of the present invention, the AI engine is configured to dynamically assess and optimize turning spaces within various building layouts to provide compliance with accessibility standards and to enhance the safety and efficiency of emergency evacuations. The AI engine may first identify all potential paths of egress within a building, particularly focusing on those that may be utilized by wheelchair users. For each identified path, the AI engine locates critical turning areas, such as points along the path where a change in direction is required. These turning areas may be found at hallway intersections, near doorways, or at transitions between different sections of the building, such as from a corridor into a room or a lobby.

Once these turning areas are identified, the AI engine conducts a detailed analysis of each one, taking into account the specific dimensions of the turning areas, the surrounding environmental conditions, and the likely traffic during an emergency scenario. The AI engine measures the available space within each turning area, determining if it meets or exceeds the minimum required dimensions to accommodate the full turning radius of various wheelchair models. The AI engine may simulate the movement of a wheelchair user through these spaces under different conditions, such as during high traffic or in low visibility, to determine if the design facilitates smooth and safe navigation, for example, during emergency evacuation. In some embodiments, if a new room or corridor is added to a building design, the AI engine can automatically re-evaluate the affected turning areas and suggest adjustments to accommodate the new configuration.

Moreover, the AI engine is also capable of assessing the impact of multiple turning areas along the same path of egress. It can identify whether the number of turning areas is excessive, which may slow down the evacuation process for wheelchair users. The AI engine compares different potential egress paths, evaluating which one offers the most direct route with the fewest and most accessible turning areas. Based on this analysis, the AI engine may recommend designating a particular path as the primary egress route for wheelchair users, with additional signage and guidance systems so that this route is easily identifiable during an emergency.

In addition to optimizing the physical dimensions of turning areas, the AI engine may consider environmental factors that affect the usability of these spaces. For example, the AI engine can analyze the lighting conditions in each turning area, determining if the turning space is adequately illuminated to prevent accidents during an evacuation. It may recommend installation of additional lighting fixtures or the use of emergency lighting systems that activate automatically during a power outage or fire.

In some embodiments, the AI engine may predict and simulate potential congestion in turning areas during an emergency. By modeling the movement of all building occupants, not just wheelchair users, the AI engine can identify areas where congestion may occur, particularly in high-traffic intersections or narrow corridors. The AI engine may then recommend solutions to alleviate this congestion, such as by widening corridors, adding additional egress paths, or staggering evacuation times to reduce the number of people moving through the space simultaneously.

In scenarios where the AI engine identifies that a turning area is too small or otherwise non-compliant with accessibility standards, it provides detailed, actionable recommendations to bring the design into compliance. For example, if a hallway intersection is too narrow to accommodate a wheelchair turning radius, the AI engine may suggest widening the corridor or reconfiguring adjacent rooms to create additional space. If the surface of the turning area is uneven or presents a tripping hazard, the AI engine may recommend resurfacing the area with a more suitable material or adding tactile indicators to guide wheelchair users.

In still another aspect, in some embodiments, enhanced interactive interfaces may include one or more of: user definable and/or editable lines; user definable and/or editable vectors; and user definable and/or editable polygons. These features allow users to directly manipulate the design elements within the interface, providing a powerful tool for customizing and refining building layouts. The interactive interface may also be referenced to generate diagrams based upon the lines, vectors and polygons defined in the interactive interface. For example, a user may define a wheelchair turning radius by drawing a circle within the interface, which the system then uses to evaluate compliance with accessibility standards. Still further, various embodiments include values for variables that are definable via the interactive interface with AI processing and human input. These variables may include distances between fixtures, minimum required turning radii, or other critical measurements, all of which can be adjusted in real-time as the user interacts with the design.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. For example, the AI engine may recognize a recurring issue in turning radii across multiple design plans and suggest optimized layouts based on learned best practices. The analysis also combines these and other capabilities to perform functions the skilled labor force traditionally performed.

In general, the present invention provides for apparatus and methods related to receiving as input design plans (either physical or electronic) and generating one or more-pixel patterns based upon automated processing of the water closet plans, including turning space available. This processing may include detailed analysis of the space available for wheelchair maneuverability, determining if all areas meet the necessary accessibility standards. The pixel patterns are analyzed using computerized processing techniques to mimic the perception, learning, problem-solving, and decision-making formerly performed by human workers (sometimes referred to herein as artificial intelligence or “AI”).

Based upon AI analysis of pixel patterns derived from the two-dimensional references and knowledge accumulated from increasing volumes of analyzed two dimensional references, interactive user interfaces may be generated that allow for a user to modify dynamic design plans of features gleaned from the two-dimensional reference. These interfaces may enable users to adjust the layout of a restroom, for example, by dragging and dropping elements to test different configurations and their impact on accessibility. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from one or both of: selected groups and learnings derived from similar previous bodies of work, whether or not a human requesting a current analysis was involved in the previous learnings.

In still another aspect, in some embodiments, enhanced interactive interfaces may include one or more of: user definable and/or editable lines; user definable and/or editable vectors; and user definable and/or editable polygons. These tools enable users to create and adjust key elements of the design directly within the interface, offering a flexible and intuitive way to refine the layout. The interactive interface may also be referenced to generate diagrams based upon the lines, vectors and polygons defined in the interactive interface. Still further, various embodiments include values for variables that are definable via the interactive interface with AI processing and human input.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed.

The present invention reduces inconsistencies in design compliance analysis and mistakes by providing consistent feedback on reasons why a building design is in compliance, or which aspects of a design plan place the building design in a state of non-compliance. For example, the AI may highlight that a corridor's width is insufficient for wheelchair access, providing a detailed explanation and suggesting specific modifications to correct the issue.

Furthermore, according to some embodiments of the present invention, automated systems generate proposed modifications to achieve compliance with an applicable code, or to adopt a best practice whether or not the best practice is required to meet an obligation dictated by a relevant code. These modifications may include recommendations such as widening doorways, repositioning fixtures, or adjusting the layout of accessible restrooms to improve compliance and functionality.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. These components may include critical features such as entrances, exits, restrooms, and emergency egress paths, all of which are analyzed for compliance with accessibility standards. Discernable components may include, for example, rooms, residential units, hallways, stairs, dead ends, windows, or other discrete aspects of a building. For example, the AI may identify a room's dimensions and calculate whether they allow sufficient space for wheelchair maneuverability, particularly in areas where turning space is critical.

In some embodiments, a scaling process may be executed to determine floorplan size descriptors assigned to the discernable components. This allows all measurements and calculations to be accurate, reflecting the true scale of the building as it will be constructed. In addition, distances, such as, for example, a distance to a water closet or lavatory, and/or a distance of an exit path from the furthest point in a residential unit may be calculated. Embodiments may also include an area of a restroom or other area involved in a clearance determination.

Using the methods and apparatus described herein, a determination of whether a building is conducive for use by people with disabilities is generated. The present invention indicates how AI may be used in the design, construction and compliance of buildings meant for use by people to bring about profoundly important advances in equal opportunity and accessibility for the handicapped community. By verifying that all spaces are designed with accessibility in mind, the invention helps to create environments where people with disabilities can navigate freely and safely, enhancing their independence and quality of life.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (sometimes referred to herein as artificial intelligence or “AI”). This process allows for rapid, large-scale analysis of building designs, determining if all relevant accessibility standards are met across a wide range of projects.

Based upon AI analysis of pixel patterns derived from the two-dimensional references and knowledge accumulated from increasing volumes of analyzed two-dimensional references, interactive user interfaces may be generated that allow for a user to modify dynamic design plans of features gleaned from the two-dimensional reference. These interfaces enable users to interact with and adjust their designs in real-time, receiving immediate feedback on how changes impact compliance and functionality. AI processing of the pixel patterns, based upon the two-dimensional references, may include mathematical analysis of polygons formed by joining select vectors included in the two-dimensional reference. Analysis of pixel patterns and manipulatable vector interfaces and/or polygon-based interfaces is advantageous over human processing in that AI analysis of pixel patterns, vectors and polygons is capable of leveraging knowledge gained from one or both of: a select group and learnings derived from similar previous bodies of work, whether or not a human requesting a current analysis was involved in the previous learnings.

In still another aspect, in some embodiments, enhanced interactive interfaces may include one or more of: user definable and/or editable lines; user definable and/or editable vectors; and user definable and/or editable polygons. These tools empower users to customize and refine their designs directly within the interface, enabling them to meet specific accessibility requirements more effectively. The interactive interface may also be referenced to generate diagrams based upon the lines, vectors and polygons defined in the interactive interface. Still further, various embodiments include values for variables that are definable via the interactive interface with AI processing and human input.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. This advanced analysis allows the AI to continually improve its performance, delivering more accurate and reliable results over time. The analysis also combines these and other capabilities to perform functions the skilled labor force traditionally performed.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates an exemplary design plan portion describing a bathroom and accessible turning area.

FIG. 1D illustrates a “T” shaped turning space specification that may be used to analyze a design plan.

FIG. 1E illustrates an exemplary portion of a design plan used by the AI engine for compliance analyses related to wheelchair turning clearance.

FIG. 1F illustrates an exemplary portion of a design plan showcasing a water closet area comprising several non-compliant features identified by the AI engine during compliance analysis.

FIG. 1G illustrates an exemplary water closet area comprising compliant features including wheelchair turning around space in some embodiments of the present invention.

FIGS. 2A, 2B, 2C and 2D illustrate a-two-dimensional representation of a floor plan and an AI analysis of the same to assess boundaries.

FIG. 2E illustrates an exemplary reception counter as part of the design plan that the AI engine may analyze in some embodiments of the present invention.

FIGS. 3A-3D show various views of the AI-analyzed boundaries overlaid on the original floorplan including a table illustrated to contain hierarchical dominance relationships between area types.

FIG. 3E illustrates an exemplary ramp system designed for a wheelchair user showcasing its implementation as part of an accessible entrance to a building.

FIG. 3F illustrates an exemplary elevator as part of compliance analyses in some embodiments of the present invention.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols.

FIG. 8 illustrates exemplary processor architecture for use with the present disclosure.

FIG. 9 illustrates exemplary mobile device architecture for use with the present disclosure.

FIGS. 10A-10B illustrate method steps that may be executed in some embodiments of the present invention.

FIG. 11 illustrates additional method steps that may be executed in some embodiments of the present invention.

FIGS. 12A-12B illustrate diagrams of paths of egress including multiple wheelchair turning areas analyzed by the AI engine in some embodiments of the present invention.

FIG. 13 illustrates a conceptual framework showing multiple layers involved in the AI-powered collaborative system for compliance analyses of design plans in accordance with the present invention.

FIGS. 14A-14B illustrate an exemplary selection of a space in a design plan for compliance analysis according to some embodiments of the present invention.

FIG. 15 illustrates exemplary method steps for conducting wheelchair turning compliance analysis in some embodiments of the present invention.

FIGS. 16A and 16B illustrate additional exemplary method steps that may be included in some embodiments of the present invention.

### DETAILED DESCRIPTION

The present disclosure provides methods and apparatus for analyzing two-dimensional (sometimes referred to as “2D”) documents relating to bathroom accessibility with the aid of artificial intelligence (sometimes referred to herein as “AI”) to ascertain whether a design plan adheres to bathroom accessibility standards dimensions and layout design, as set forth by an authority having jurisdiction (“AHJ”). The system may be designed to evaluate key aspects of bathroom accessibility, such as turning spaces, door widths, and clear floor areas, to determine if all elements of the design meet the required standards for accommodating individuals with disabilities.

Specifically, the present invention uses AI to identify a bathroom area and to auto-detect, measure, and classify components of accessible bathrooms and ascertain whether requirements relating to the turning space of bathrooms are in compliance with relevant codes according to the AHJ, such as, but not limited to code for bathroom turning space, clear width of the door opening, clear floor space, and turning radius. For example, the AI engine may evaluate whether the space in front of a sink allows for sufficient wheelchair maneuverability, or whether the door opening provides the necessary clearance for easy access. Such requirements may be included in regulations designed to make bathrooms physically accessible to people with disabilities. By automating this analysis, the invention reduces the likelihood of oversight and enhances the reliability of compliance checks.

The present invention reduces inconsistencies in code compliance analysis and mistakes. It also provides consistent feedback on reasons why an accessible bathroom is in compliance with applicable codes; or out of compliance with applicable codes. For example, the AI engine may flag a bathroom layout that fails to provide the minimum required turning radius and offer a detailed explanation of the deficiency. Furthermore, according to some embodiments of the present invention, automated processes executed on a controller may be operative to make suggestions describing how to cure non-compliance with an AHJ, or to adopt a best practice, and whether or not the best practice is required to meet an obligation dictated by a relevant code. In some examples of the present invention, a best practice may be quantified via analysis of design plan changes made in a same design plan, or disparate design plans, to remedy a deficient design. Best practices may be generated via AI analysis of multiple design plans consistent with the processes presented herein.

One or more best practices may also be set forth in publications provided by relevant organizations, such as publications provided by the International Code Council (ICC). For example, a best practice may be to increase a circular turning space requirement to sixty-seven inches (67-inches) minimum diameter for new buildings based on the newest edition of ICC A117.1, instead of using a 60-inch requirement (e.g. ; such as the ADA requirement). This recommendation stems from research indicating that a larger turning radius better accommodates the dimensions of modern electric wheelchairs and scooters. Best practices may also be determined, by way of non-limiting example, based upon conclusions of research, such as the study completed by the Wheeled Mobility Task Group (which concluded that a 67-inch diameter clearance would better accommodate modern electric wheelchairs and scooters.

As described herein, a two-dimensional reference and AHJ codes may be accessed by an AI engine. The AI engine converts the two-dimensional reference into components that may be processed by the AI engine. For example, a rasterized version of the turning space drawings. These rasterized images allow the AI to analyze the layout with a high degree of precision, breaking down each element of the bathroom into measurable components. The drawings are then processed with machine learning to specify portions that may be specified as discernable components. Discernable components may include dimensions and placement of the turning space, clear width of the door opening, and clear floor space for an accessible bathroom. For example, the AI engine may identify the precise location and size of a turning space and assess whether it meets the required standards for wheelchair accessibility. Size, shape, and locations of discernable components are analyzed to determine whether the design plan in compliance with requirements and/or recommendations made by an AHJ.

A scaling process may be applied to the drawings and size descriptors may be assigned to the discernable components. In addition, distances, such as distances related to placement of turning spaces included in the design plan, may be calculated. For example, the AI engine may calculate the distance from a sink to the nearest wall to verify that there is sufficient space for a wheelchair to turn.

In addition, variables may be specified that are used to assess compliance and a compliance determination is made based upon values for the specified variables. These variables may include measurements such as the diameter of a turning space, the clear width of a door opening, or the amount of clear floor space around fixtures. In some embodiments, the variables may include some or all of: dimensions of the turning space, clear width of the door opening, clear floor space, overlap of fixtures or other factors on which a determination of compliance and/or lack of compliance may be based. For example, the AI engine may determine that a toilet encroaches into the turning radius, thereby violating accessibility standards. The AI engine will generate values for some, or all of the variables referenced to determine compliance. Any non-compliant areas are identified and addressed. The system may then provide suggestions for modifying the design to bring it into compliance, such as repositioning fixtures or expanding certain areas to increase accessibility.

In some embodiments, a method for analyzing wheelchair turning clearance in a building design leverages an AI engine to determine compliance with relevant building codes. The process begins by receiving the design plan of at least a portion of a building into a controller. The design plan may be an architectural drawing, a floor layout, or any similar representation that outlines the spatial configuration of the building, including walls, doors, fixtures, and open spaces.

Once the design plan is received, the controller converts it into multiple dynamic components. These components represent structural elements like boundaries, paths, and spaces, as well as fixtures such as furniture or equipment. The dynamic components may also include lines, polygons, or vectors. By breaking down the design plan into these manageable elements, the controller facilitates detailed analysis and manipulation of the building layout, enabling precise assessments of wheelchair accessibility.

The AI engine running on the controller then determines a proposed use of the building based on the design plan. The intended use of the building influences the accessibility requirements. For example, a commercial office space may have different accessibility needs compared to a healthcare facility. The proposed use guides the subsequent analysis by setting the context within which the building's accessibility features are evaluated.

Based on the proposed use, the controller may determine a set of conditions related to wheelchair turning clearance compliance. These conditions may include critical metrics such as a minimum turning radius, clear floor space requirements, door swing considerations, and permissible overlaps between turning areas and fixtures. For example, the set of conditions may specify that a 60-inch diameter turning space is required at certain critical points in the building to allow sufficient maneuverability for wheelchair users.

The controller then identifies one or more wheelchair turning points within the design plan. These turning points may be located at hallway intersections, room entrances, corners, dead ends, or L-shaped pathways. These are areas where a wheelchair user may need to execute a turn, and the analysis focuses on determining if sufficient space is available for this maneuver.

After identifying the turning points, the controller calculates the turning radius at each point. This calculation may be based on the dimensions of the space and the positioning of nearby structural elements and fixtures. The controller then compares the calculated turning radius with the set of conditions related to wheelchair turning clearance compliance. If the turning radius at any identified point does not meet the required standards, the controller flags this as an area of concern.

Additionally, the controller takes into account the dimensions and placement of any obstructions within the calculated turning radius. These obstructions may include furniture, fixtures, or structural elements that may encroach on the turning space and hinder wheelchair maneuverability. The controller evaluates the impact of these obstructions and provides recommendations for adjustments, such as repositioning fixtures or modifying the layout to improve accessibility.

The method may also involve identifying a route network within the design plan, which includes paths leading to points of egress. The controller evaluates the surface conditions along these paths, analyzing factors such as slope, surface texture, and any unevenness that may affect wheelchair movement. For example, if a ramp is included in the route network, the controller analyzes its slope to determine if it meets the required standards for wheelchair accessibility.

The controller further identifies the number of wheelchair turning points along the path to the point of egress and determines whether the number exceeds permissible limits. This may particularly be important during emergency evacuations, where multiple sharp turns may slow down wheelchair users' progress. The controller may simulate an emergency scenario where a virtual wheelchair user navigates the path to the point of egress, assessing the time required to evacuate safely and identifying any potential bottlenecks.

Moreover, the AI engine also predicts the occupancy load within the building based on its proposed use. This prediction helps in assessing how the design accommodates wheelchair users, especially in high-traffic areas or during peak occupancy. The controller considers the predicted occupancy load when analyzing the wheelchair turning clearance, determining if the design is capable of handling the expected number of occupants, including those using wheelchairs.

In scenarios where restrooms or other critical areas require specific wheelchair turning clearance, the controller analyzes these areas to determine compliance. It determines whether the space around fixtures like toilets, sinks, and partitions meets the necessary standards for wheelchair accessibility. If the design does not comply, the controller suggests modifications to the layout to improve accessibility.

The controller may also determine the number of wheelchair users the building can accommodate safely during an emergency evacuation, providing a count based on the available space and the design's compliance with accessibility standards.

Throughout the process, the controller generates visual representations of the analysis results within the interactive user interface. These visualizations include color-coded indicators to show whether the calculated turning radius at each identified point complies with or deviates from the required conditions. If any areas of the design are non-compliant, the controller provides suggested modifications to bring the design in line with the relevant building codes.

In some embodiments, a controller will also set forth where a turning space, clear width of the door opening, or clear floor space may be arranged to be in compliance with bathroom accessibility codes.

Some embodiments, such as, in the case where one or more of: a turning space, clear width of the door opening, and clear floor space, are found to be in violation of a code. In these cases, the system highlights the specific portions of the design that contribute to the non-compliance. Still further, some embodiments may include suggested changes and/or options for sets of changes to the bathroom that may be implemented in order to achieve compliance. For example, the system may recommend repositioning fixtures or widening doorways to create sufficient space for wheelchair maneuverability.

Using the methods and apparatus described herein, a determination of whether an accessible bathroom is compliant for use by people with disabilities is then generated. The present invention indicates how AI may be used in the design, construction, or code compliance for accessible bathrooms meant for use by disabled persons to bring about important advances in safety and accessibility for the handicapped community, and to mitigate injury or legal disputes. For example, by identifying and correcting non-compliant design elements early in the planning stages, the system helps to prevent costly renovations and potential litigation.

In general, the present invention provides for apparatus and methods related to receiving as input design plans (either physical or electronic) and generating one or more-pixel patterns based upon automated processing current accessible bathroom plans and applicable codes from AHJ. These pixel patterns are analyzed to evaluate compliance with specific accessibility requirements, providing a detailed assessment of the bathroom layout. The pixel patterns are analyzed using computerized processing techniques to mimic the perception, learning, problem-solving, and decision-making formerly performed by human workers.

Based upon AI analysis of pixel patterns derived from the two-dimensional references and knowledge accumulated from increasing volumes of analyzed two dimensional references, interactive user interfaces may be generated that allow for a user to modify dynamic design plans of features gleaned from the two-dimensional reference. These interfaces enable users to interact with the design in real-time, making adjustments as needed to improve compliance and functionality. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from one or both of: select groups and learnings derived from similar previous bodies of work, whether or not a human requesting a current analysis was involved in the previous learnings.

In still another aspect, in some embodiments, enhanced interactive interfaces may include one or more of: user definable and/or editable lines; user definable and/or editable vectors; and user definable and/or editable polygons. These tools allow users to directly manipulate design elements within the interface, providing a flexible and intuitive way to customize the layout to meet specific requirements. The interactive interface may also be referenced to generate diagrams based upon the lines, vectors and polygons defined in the interactive interface. For example, a user may draw a line to represent the minimum required distance between fixtures, which the system then uses to evaluate compliance. Still further, various embodiments include values for variables that are definable via the interactive interface with AI processing and human input.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind—including learning from examples and experience, recognizing patterns and/or objects, understanding and responding to patterns in positions relative to other patterns, making decisions, solving problems. For example, the AI engine may use machine learning to refine its analysis based on new data, continually improving its ability to detect and address non-compliance issues. The analysis also combines these and other capabilities to perform functions typically performed by human workers. This automation not only speeds up the process but also reduces the potential for human error, leading to more accurate and reliable compliance assessments.

The present invention provides improved methods and apparatus for artificial intelligence-based conversion of a two-dimensional reference, such as a design plan, into an interactive user interface operative to indicate whether the design plan includes an adequate quantity, and type, of plumbing fixtures in order for the design plan to be in compliance with one or more designated codes. For example, the system may evaluate whether the number of accessible sinks and toilets meets the requirements set by the applicable building codes. A designated code may be selected by a user, or based upon a building use and/or a number of permitted occupants in the building. The AI system can automatically apply the relevant codes based on these factors, streamlining the compliance review process. A building location and appropriate Authority Having Jurisdiction may also be referenced in designating an applicable code.

The present invention utilizes AI to provide a level of consistency and accuracy not currently available during analysis of a design plan to ascertain compliance with an applicable code. This AI-driven approach reduces the variability and subjectivity often present in manual reviews, resulting in more consistent and objective evaluations. The automated processes presented herein reduce mistakes and inconsistencies in code compliance analysis by associating patterns of pixels derived from design plan analysis to identify the available turning radius, and compare with the radius required by the applicable code. For example, the system may detect that the turning radius near a restroom sink is too small and flag this as a non-compliance issue. The present invention also provides understanding for where and how the turning radius size failed to determine what features need to change for compliance. Furthermore, according to some embodiments, suggestions may be made to on how to cure non-compliance or to adopt a best practice, and whether or not the best practice is required to meet an obligation dictated by a relevant code. These suggestions may include increasing the clear floor space around fixtures or adjusting the placement of elements to better accommodate wheelchair users.

AI and machine learning may follow a design analysis to recognize and/or recommend aspects of a building relating to an acceptable clear area proximate to a water closet and lavatory. For example, the AI engine may recommend repositioning a sink to create more clear floor space, so that the area meets accessibility standards.

In some embodiments, the AI and machine learning techniques may be combined with automated processes for one or both of: ascertaining a use of a design plan; ascertaining a required type of plumbing fixture; and ascertaining a clear area around plumbing fixtures as set forth in a design plan. The automated processes presented herein may also be used to analyze a floorplan described by a particular two-dimensional reference and generating suggested modifications to the floorplan. For example, the system may suggest widening a hallway or repositioning a door to improve accessibility. In some embodiments, the suggested modifications may include modifications that will convert a non-compliant design plan into a floorplan compliant with a particular set of conditions, such as conditions to meet a code adopted by an AHJ.

The interactive interface is operative to generate values of variables useful to ascertain whether the submitted design plan meets or exceeds a designated regulation, code, or other authoritative requirement. For example, the system may calculate the clear floor space in front of a sink and compare it to the minimum required by the applicable accessibility code.

The interactive interface may also indicate specific requirements of a building code and indications as to whether some or all of the requirements are met. These indications may include visual cues, such as color-coding, to highlight areas of the design that are compliant or non-compliant. In addition, the user interface may include pictorial indications of portions of a design plan that have been associated with specific requirements of the building code during the AI analysis. The pictorial indications may include description of why a particular portion meets, exceeds, or does not meet a compliance code requirement.

As described herein, a design plan may be associated with an existing building or a proposed project that includes construction of a building (or other structure, herein collectively referred to as a “building”). The system is designed to accommodate both new construction and renovations, providing valuable insights at any stage of the project. Generation of documentation quantifying compliance or non-compliance of a design plan with specific building codes is also within the scope of the present invention. In some embodiments, automated suggested revisions to the design plan to bring the design plan into conformity with the code are also within the scope of the invention.

According to the present invention, a controller is operative to execute artificial intelligence (AI) processes and analyze one or more design plans of at least a portion of a building (or other structure) for which a compliance determination will be generated and provides values for variables used to ascertain a state of compliance based upon descriptive content included in the design plans.

In some embodiments, the design plan may include technical drawings such as blueprints, floor plans, design plans, and the like. The AI analysis may include determination of boundaries and/or features indicated in the design plan. For example, the system may identify the boundaries of a restroom and evaluate whether the space within those boundaries meets the required accessibility standards. The design plan may be a two-dimensional static reference, or a two-dimensional or three-dimensional dynamic reference, such as a Revit compatible file. This boundary determination may be used to provide useful information about a building such as, one or more of: rooms that comprise a residential unit; an area of an individual room or other area; a distance of travel to a point of egress, a width of a doorway; a width of a path or egress; a dead end path; a perimeter of a defined area; a point furthest from another point (e.g.; a point furthest from a point of egress); a common path; and the like. Based upon values of parameters derived from a two-dimensional reference, the AI engine may generate additional values related to code compliance, such as one or more of: an egress capacity; an occupancy load; a function for a space; alternative paths of egress; dead end double back distances; or other parameters.

In the following sections, detailed descriptions of examples and methods will be given. The description of both preferred and alternative examples, though thorough, are exemplary only. It is understood that, to those skilled in the art, various modifications and alterations may be apparent and within the scope of the present invention. Unless otherwise indicated by the language of the claims, the examples do not limit the broadness of the aspects of the underlying invention as defined by the claims.

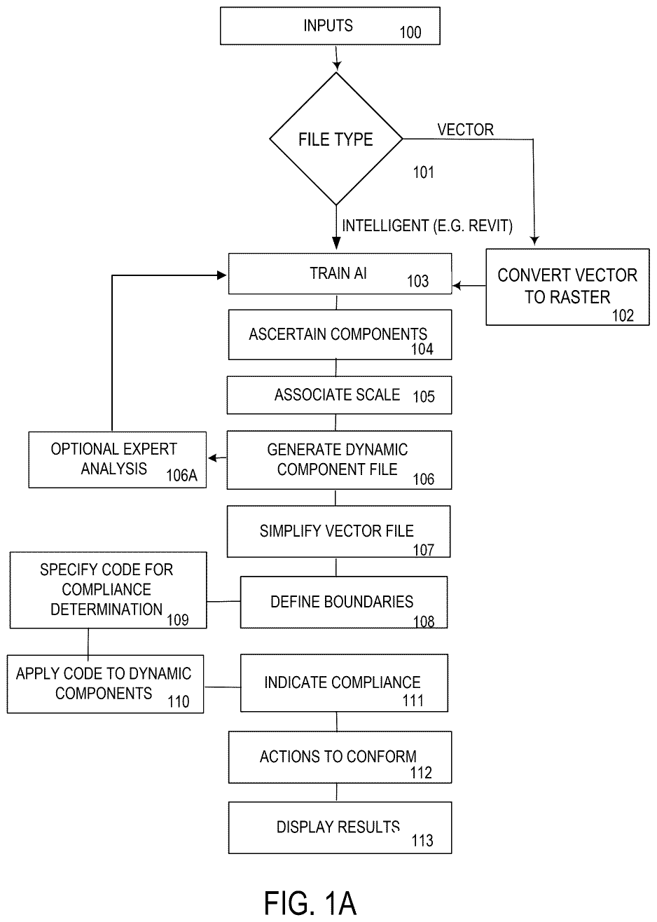

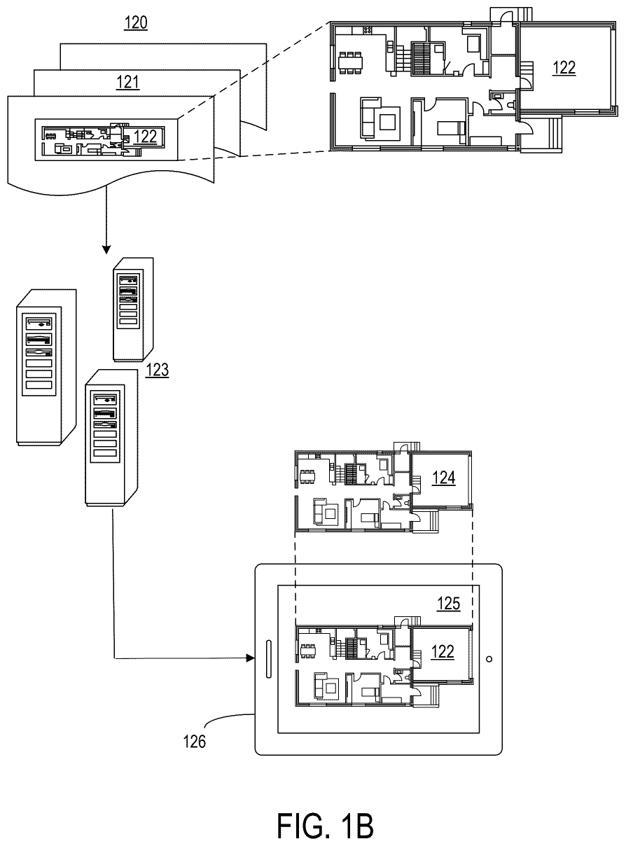

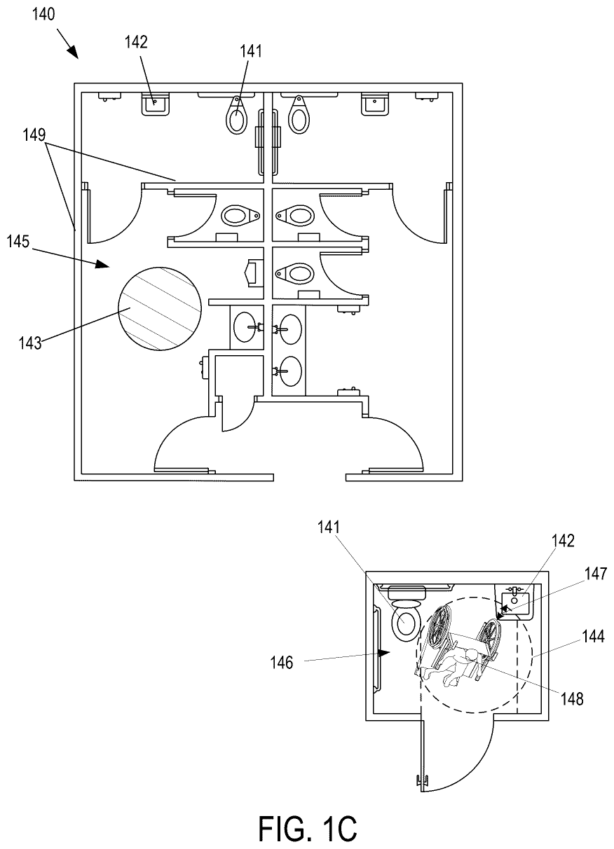

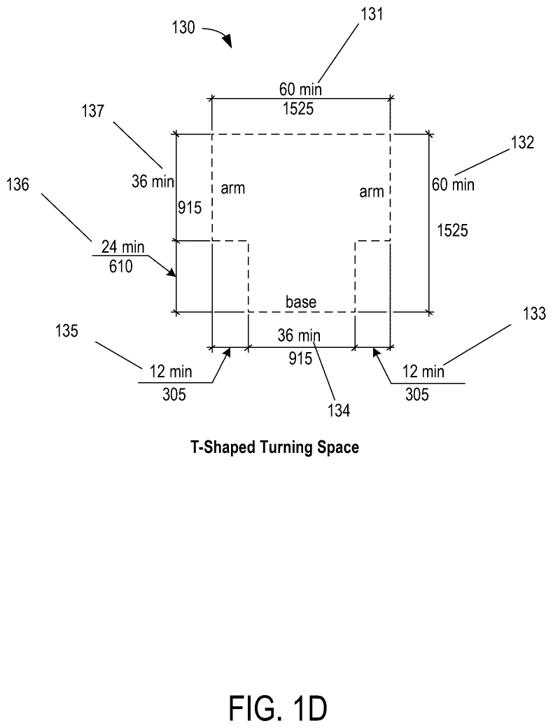

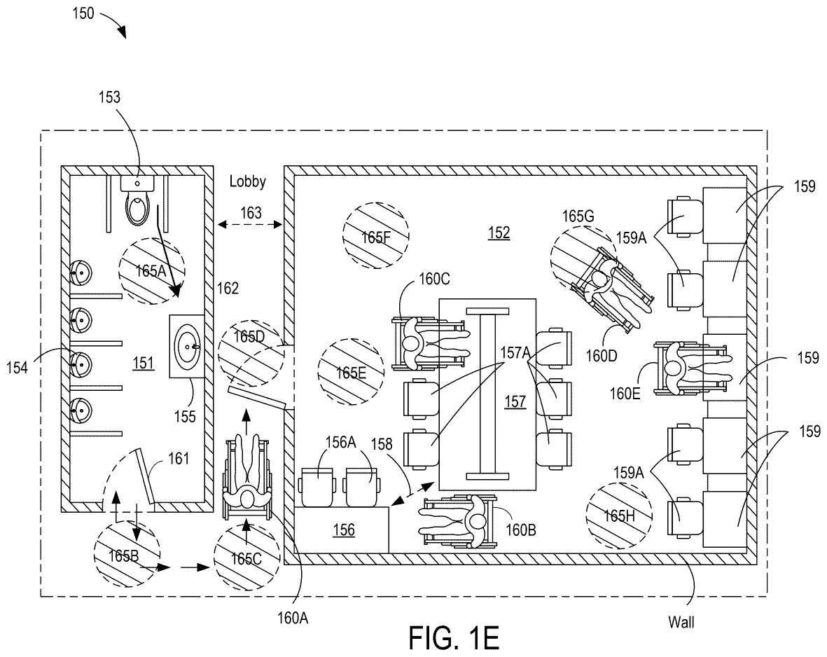

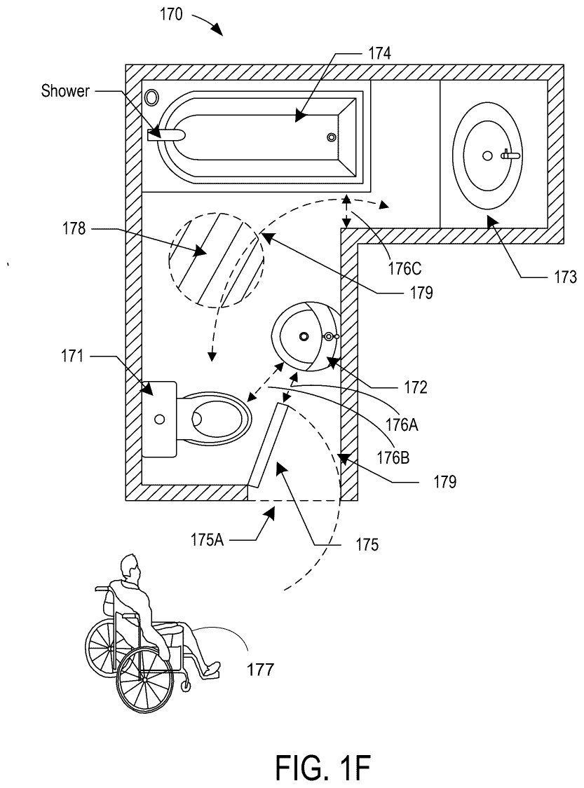

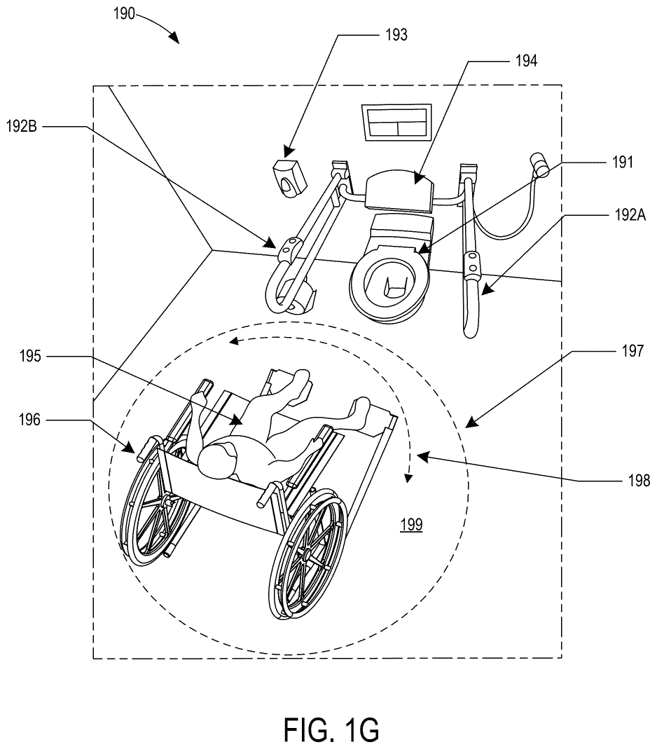

Referring now to FIG. 1A, a general flow diagram showing some preferred embodiments of the present invention is illustrated. At step 100, a design plan (which may be design plan or dynamic architectural design file (e.g., a Revit® compatible file) indicating aspects of a building; is input into a controller or other data processing system using a computing device. The design plan may represent various spaces within the building, including rooms, hallways, restrooms, and turning areas for wheelchair users. The design plan may include an item of a known size, such as, by way of non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide).

Input of the two-dimensional reference into the controller may occur, for example, via known ways of rendering an image as a vector diagram, such as via a scan of paper-based initial drawings; upload of a vector image file (e.g., encapsulated postscript file (epf file); adobe illustrator file (ai file); or portable document file (pdf file). In other examples, a starting point for estimation may be drawing file in an electronic file containing a model output for an architectural floor plan. In still further examples, other types of images stored in electronic files such as those generated by cameras may be used as inputs for automated processes that determine compliance with requirements of a code.

In some embodiments, the design plan may be files extensions that include but are not limited to: DWG, DXF, PDF, TIFF, PNG, JPEG, GIF, or other type of file based upon a set of engineering drawings. Some design plans may already be in a pixel format, such as, by way of non-limiting example a two-dimensional reference in a JPEG, GIF or PNG file format. In these cases, the system can directly analyze the image for relevant features, such as the placement of doorways and the size of turning spaces. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged couple device to create the file containing the image on the smart device.

In some embodiments, a degree of the processing as described herein may be performed on a controller, which may include a cloud server, a standalone computing device or a smart device. In many examples, the input file may be communicated by the smart device to a controller embodied to a remote server. In some embodiments, the remote server, which is preferably a cloud server, may have significant computing resources that may be applied to AI algorithmic calculations analyzing the image.

In some embodiments, dedicated integrated circuits tailored for deep learning AI calculations (AI Chips) may be utilized within a controller or in concert with a controller. These AI Chips are specifically designed to handle the intensive computations required for analyzing large-scale design plans, making them well-suited for tasks like identifying wheelchair turning spaces and evaluating compliance with accessibility codes. Dedicated AI chips may be located on a controller, such as a server that supports a cloud service or a local setting directly. These chips enhance the system's processing power, allowing for faster and more efficient analysis of design elements, even in complex or large-scale projects.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software only embodiments of the AI engine may be run on one or more of: local computers, cloud servers, or on smart device processing environments.

At step 101, a controller may determine if a design received into the controller includes a vector diagram. If a file type of the received design plan, such as an input architectural floor plan technical drawing, includes at least a portion that is not already in raster graphics image format (for example, that it is in vector format), then the input architectural floor plan technical drawing may be transformed to a pixel or raster graphics image format in step 102. Vector-to-image transforming software may be executed by the controller, or via a specialized processor and associated software.

In some embodiments, the controller may determine a pixel count of a resulting rasterized file. The rasterized file will be rendered suitable for a controller hosting an artificial intelligence engine (“AI engine”) to process, the AI engine may function best with a particular image size or range of image size and may include steps to scale input images to a pixel count range in order to achieve a desired result. Pixel counts may also be assigned to a file to establish the scale of a drawing—for example, 100 pixels equals 10 feet. This scaling process allows the system to accurately measure and evaluate distances and dimensions within the design plan, so that all relevant compliance metrics are correctly calculated.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metric.

At step 103, training (and/or retraining) of the AI engine is performed. Training may include, for example, manual identification of patterns in a rasterized version of an image included in a design plan that correspond with architectural aspects, walls, fixtures, piping, duct work, wiring or other features that may be present in the two-dimensional reference. The training may also include one or more of: identification of relative positions and/or frequencies and sizes of identified patterns in a rasterized version of the image included in the design plan. This detailed analysis allows the AI engine to accurately assess whether the design meets all necessary accessibility standards.

In some embodiments, and in a non-limiting sense, an AI engine used to analyze the design plan may be based on a deep learning artificial neural network framework. This framework is particularly well-suited for the complex task of identifying and evaluating wheelchair turning spaces within a building design. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, stairs, and the like.

In some embodiments, a structure of the artificial neural network may include multiple layers, such as input layers and hidden layers with designed interconnections with weighting factors. These layers enable the AI engine to process complex patterns within the design plan, allowing for accurate identification and analysis of wheelchair turning spaces. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may include areas where wheelchair users need to turn or navigate, making them useful in determining compliance with accessibility codes. Boundaries may also be automatically defined by a controller executing software during certain process steps, such as a user query. Using deep artificial neural networks, original architectural floor plans (along with any labeled boundaries) may be used to train AI models to make predictions about what is inside a boundary. In exemplary embodiments, the AI model may be given over ~50,000 similar architectural floor plans to improve boundary-prediction capabilities.

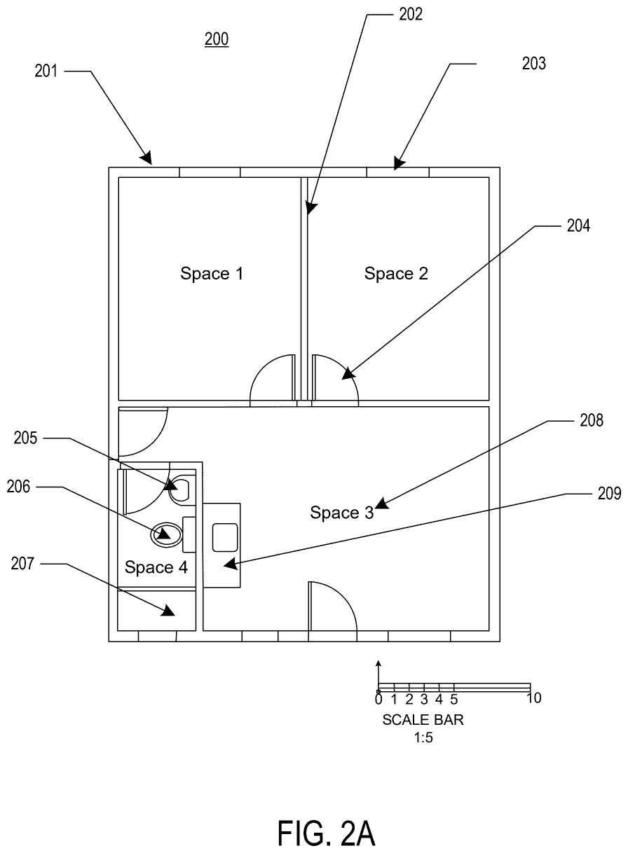

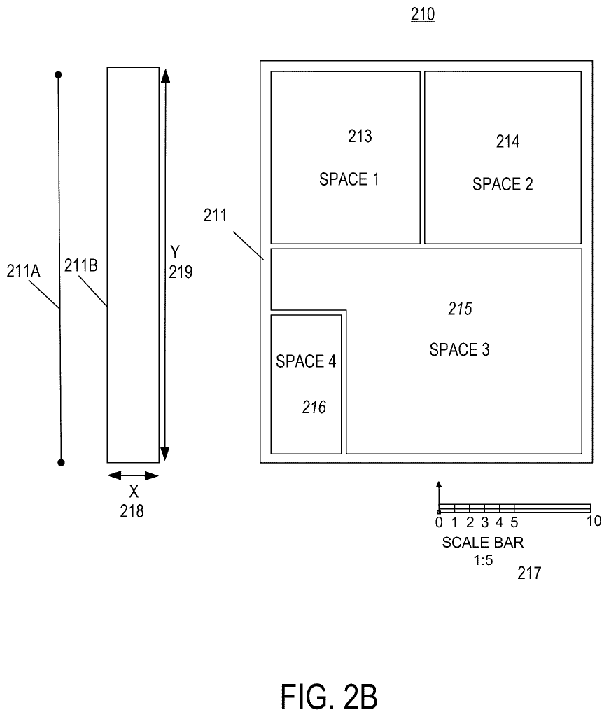

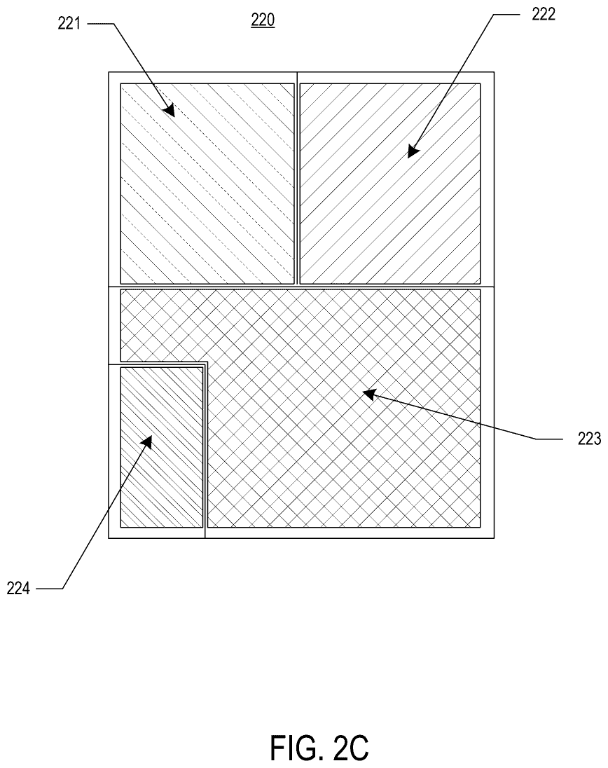

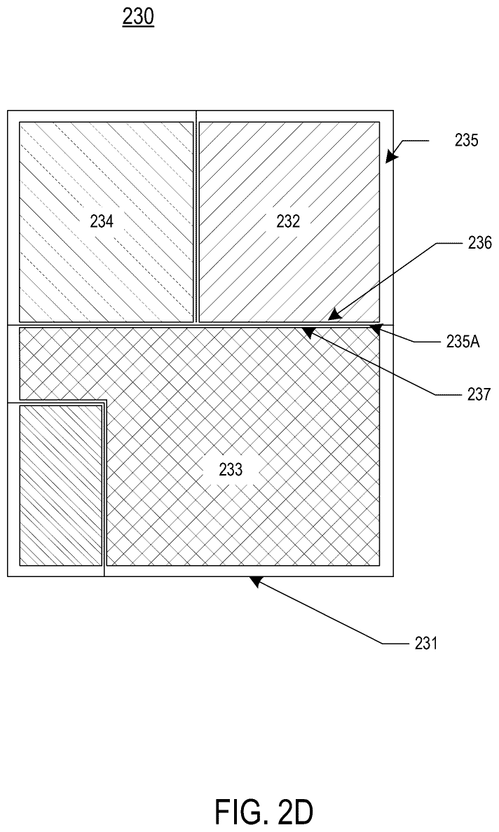

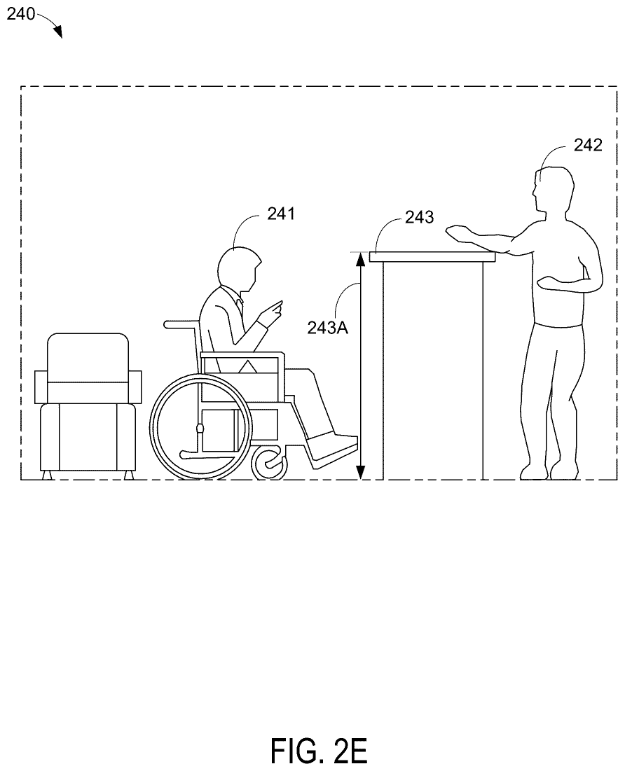

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. (An exemplary AI-processed two-dimensional reference that includes a design plan and/or a floorplan 210, with boundaries 211 predicted, is shown in FIG. 2B, based on the floorplan of FIG. 2A.)

In still another aspect, in some embodiments, a controller may access data from various types of BIM and Computer Aided Drafting (CAD) design programs and import dimensional and shape aspects of select spaces or portions of the designs as they related to a design plan.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects, fixtures, duct work, wiring, piping, or other items included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shape.

At step 105, a scale (e.g.; FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale for a particular image, drawing or other two-dimensional reference. The drawing scale, may for example, be in inches: feet, centimeters: meters, or any other appropriate scale.

In some embodiments, a scale may be determined by manually measuring a room, a component, or other empirical basis for assessing a scale (including the ruler discussed above). The manual input option may provide an additional level of accuracy, particularly in cases where the original design plan may not include a clearly defined scale. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. (Fig.

At step 106, a controller is operative to generate a user interface with dynamic components that may be manipulated by one or both of user interaction and automated processes. This dynamic interface allows users to interact directly with the design, making it easier to identify and address any compliance issues. Any or all of the components in a user interface may be converted to a version that allows a user to modify an attribute of the component, such as the length, size, beginning point, end point, thickness, or other attribute. In some embodiments, a boundary may be treated as a component and manipulated in like manner.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. These elements allow users to visually assess and modify the design, making it easier to identify and address any compliance issues. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or end point, associate a pattern of pixels with a predefined shape corresponding with a known component or otherwise modify a shape formed by a pattern of pixels. These improvements allow all components within the design to be accurately represented, providing a reliable basis for evaluating wheelchair turning spaces and other critical areas.

In addition, some embodiments that utilize the recognition step transforms features such as windows, doorways, vias and the like to other features and may remove them and/or replace them as elements—such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices. This simplification process allows the design to be optimized for analysis, allowing the AI engine to quickly and accurately assess compliance with accessibility standards.

The interaction of two elements at a vertex may define one or more new elements. For example, an intersection of two lines at a vertex may be assessed by the AI as an angle that is formed by this combination. This assessment allows the AI engine to accurately identify and evaluate critical features within the design, such as wheelchair turning spaces and doorways. As many construction plan drawings are rectilinear in nature, it may be that the simplification step inside a boundary can be considered a reduction in lines and vertices and replacing them with elements and/or polygons.

In another aspect, in some embodiments, one or both of a user and a controller may indicate a component type for a boundary. Component types may include, for example, one or more of line segments, polygons, multiple line segments, multiple polygons, and combinations of line segments and polygons.

At step 106A, In some embodiments, components presented in an interactive user interface may be analyzed by a user and refinements may be made to one or more components (e.g., size, shape and/or position of the component). In some embodiments, user modifications may also be input back to the AI engine train the AI engine. User modifications provided back to the AI Engine may be referenced to make subsequent AI processes more accurate and/or enable additional types of AI processes. This continuous improvement process allows the system to remain highly accurate and reliable, providing users with confidence in the compliance assessments it generates.

At step 108, a controller (such as, by way of non-limiting example, a cloud server) operative as an AI engine may create AI-predicted dynamic boundaries that are arranged to form a representation of submitted design plan that does not include the boundaries that bound it. These dynamic boundaries provide a clear and accurate representation of the design, allowing users to easily identify and address any compliance issues.

In various embodiments, a boundary may be used to define a unit, such as a residential unit, a commercial office unit, a common area unit, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may in turn be used as a basis for modifying an occupant load, defining an egress path, classifying a space, or other purpose.

For example, a change in a boundary may make an area larger. The larger area may be a basis for an increase in occupancy load. This increase in occupancy load may necessitate additional compliance checks, such as determining if egress paths are sufficient to accommodate the increased number of occupants. The larger area may also result in a longer path from the furthest point in the defined area to a point of egress (e.g.; if a user chooses to use a worst case in determining an egress route).

At step 109, one or both of the user and an automated process on a controller may specify a code for which a compliance determination based upon the AI generated boundaries. In some embodiments, a selection of a set of codes to apply to the floor plan may be automated, for example, based upon a geographic or geopolitical area in which the building resides or will be constructed. In other embodiments, a user may specify a set of codes, such as, for example, a drop-down menu may indicate available codes, and a user may select one or more sets of codes to apply to the floor plan. Accordingly, by way of non-limiting example, a user may select that a set of floorplans be analyzed with the AI engine to assess compliance with Americans with Disabilities Act (ADA) compliance and National Fire protection Association code, or other code adopted by an authority having jurisdiction.

At step 110, a set of parameters for a selected set of code is applied to some or all of the dynamic components generated via the AI engine.

At step 111, the user interface or other output may be caused to display an indication of whether a design plan is in compliance with the selected set(s) of codes. This display provides users with a clear and concise assessment of the design's compliance status, allowing them to quickly identify and address any issues. In some preferred embodiments, a list of conditions required in order for a building to be in compliance, and an indication of why one or more of the conditions is met may be illustrated within a user interface or other output. For example, if the ADA is the basis for a set of codes to ascertain compliance with, a set of floorplans may be input into an AI engine and the AI engine will determine a value, and/or a range of values, which may be compared to the code requirements and a determination may be generated indicating whether the design plans describe a building that is in compliance with a selected set of codes. The ADA may require that a building described in the design plan have accessible routes that are at least thirty-six (36) inches wide. The AI engine may analyze a design plan and generate boundaries that may be manipulated by a user and then generate values for variables required to assess whether a condition the code sets forth is present in the design plan, such as the 36-inch wide accessible routes.

In generating a value for such as variable, the AI engine and/or the user may need to that one or more boundaries define a specific type of area, such as a bedroom, a hallway, or a stairwell. Each specific type of area may have specified variables associated with it. By way of non-limiting example, the user interface may employ a simple yes/no indicator for compliance with a requirement of a selected code. This indicator provides users with a quick and easy way to assess the design's compliance status, allowing them to focus on areas that require further attention. In other embodiments, the user interface may visually indicate portion of the design plan that was referenced in determining a state of compliance or non-compliance, e.g.; a doorway that is thirty-six inches or more and therefore in compliance or a hallway that is only twenty-four inches wide and therefore not in compliance.

Some specific embodiments may include a first portion of a user interface with delineated conditions for code compliance, such as, for example, a listing of sections of a code, an ability for a user to select a specific section of the code, and a link that brings up an interface with visual indicators illustrating a state of compliance (or non-compliance as the case may be) with the user selected section of code.

At step 112, in another aspect, the present invention may use the AI to generate suggested modifications to a design plan in order to transition the design plan from a state of non-compliance to a state of compliance. In addition, the user interface may indicate other actions, in addition to a modification to the design plan, (e.g., reduce an occupant load) in order to conform to code.

At step 113, a conclusion of whether a design plan is in compliance may be displayed as a user interface in an integrated fashion in relation to a replication of the two-dimensional reference(such as the design plan, architectural floor plan, or technical drawing). The user interface may also be shown in a form that includes user modifiable elements, such as, but not limited to: polylines, polygons, arcs, circles, ellipses, splines, line segments, icons, points and other drawing features or combinations of lines and other elements.

Referring now to FIG. 1B, a high-level diagram illustrates components included in a system 120 that uses AI to generate an interactive user interface 125 and programmable apparatus (controller) 123 operative to execute method steps useful in determining compliance with a design plan or other architectural description. The system 120 enables users to interactively assess and modify architectural designs, making it easier to evaluate and achieve compliance with various building codes, particularly those related to wheelchair accessibility and other essential standards.

According to some embodiments of the present invention, a two-dimensional reference 121, such as a design plan, floorplan, blueprint, or other document includes a pictorial representation 122 of at least a portion of a building. The use of a two-dimensional reference is integral for assessing and processing architectural aspects of a building with precision. The pictorial representation 122 may include, for example, a portable document format (PDF) document, jpeg, png, or other essential non-dynamic file format, or a hardcopy document. These formats allow the AI system to analyze a wide range of document types, accommodating both modern digital files and traditional paper-based plans. The pictorial representation 122 includes an image descriptive of architectural aspects of the building, such as, by way of non-limiting example, one or more of: walls, doors, doorways, hallways, rooms, residential units, office units, bathrooms, stairs, stairwells, windows, fixtures, real estate accouterments, and the like.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. Presentation of the two-dimensional reference may include, for example, scanning a hardcopy version of the two-dimensional document into electronic format and transmitting the electronic format to the controller 123 running the AI engine. This process enables older or non-digital design plans to be analyzed with the same precision and thoroughness as modern digital files, expanding the system's applicability.

The controller is operative to generate a user interface 125 on a user computing device 126. The user interface 125 is the primary tool through which users interact with the system, providing a visual and interactive representation of the architectural design under analysis. The user computing device may include a smart device, workstation, tablet, laptop or other user equipment with a processor, storage, and display.

The user interface 125 includes a reproduction of the pictorial representation 122 and an overlay 124 with one or more user manipulatable components, such as, by way of non-limiting example: boundaries, line segments, polygons, images, icons, points, and the like. The line segments may have calculated lengths that may be mathematically manipulated and/or summarized. Aspects such as polygons, line segments, shapes, icons, and points may be counted, added, subtracted, extrapolated, and other functions performed on them.

In addition, renditions of the user interface 125 may be created and saved, and/or communicated to other users, or controllers, compared to subsequent interface renditions, archived and/or submitted to additional AI analysis. This capability allows for a continuous and iterative design process, where changes can be tracked, reviewed, and refined over time, so that the final design meets all necessary compliance standards.

In some embodiments, a first user interface 125 rendition may be modified by a user to create a second user interface 125, and submitted to AI analysis to ascertain compliance with a selected code. Some embodiments may also calculate costs, expenses, man hours or other variables associated with changes to a design plan in order to bring the design plan into compliance. Change order renditions provided as options to bring a design plan into compliance with a selected code may also be provided with a unique identifier, time and/or date stamped to create a continuum of work, as related to original projects and compliance-initiated changes. Each of the items in the continuum of work may be stored and subsequently used for ascertaining eventual compliance a building with each selected code.

Referring now to FIG. 1C, a design plan illustrates an exemplary layout of a restroom 140, which may be extracted from the two-dimensional reference 121 analyzed by the controller 123 operating an AI engine to assess compliance with accessibility standards as determined by relevant building codes. The restroom 140, depicted in the design plan portion, is furnished with plumbing fixtures, such as a water closet 141 and a sink 142, along with other architectural features 149 like walls and stall dividers. These elements are integral to the functionality and accessibility of the restroom, and their placement is critical to the overall usability of the space for individuals with disabilities. The AI engine, operating within the controller 123, analyzes these elements by converting the two-dimensional reference 121 into discernable or dynamic components that can be assessed for compliance with relevant building codes, particularly those focused on accessibility.

Within the restroom 140, the AI engine identifies and demarcates specific areas 145-146 that are intended to accommodate wheelchair turning, labeled as wheelchair turning areas 143-144. These areas may be typically circular or T-shaped zones where a wheelchair user 148 needs sufficient space to execute a full 360-degree turn without obstruction. The size and configuration of these turning areas are dictated by building codes, which often specify that the turning radius must be at least 60 inches in diameter to allow for smooth maneuverability. This requirement provides a standard manual for a powered wheelchair to navigate the space without difficulty, accommodating both the wheelchair's size and the user's ability to control it.

The restroom 140 may also include various other fixtures and features that the AI engine must consider when determining the adequacy of the wheelchair turning areas 143-144. Aside from the water closet 141 and sink 142, other potential features in the restroom may include grab bars, dispensers, mirrors, and accessible flush controls, all of which need to be placed in a manner that does not impede the turning space. These features are useful not only for their functional purposes but also because they contribute to the overall accessibility of the restroom. The placement of these items must be carefully considered to avoid creating obstacles within the designated turning areas 143-144.

For example, grab bars must be mounted at a height that is accessible to wheelchair users, typically between 33 to 36 inches from the floor, depending on the building code. The grab bars should be placed in a location that aids in transferring onto the toilet but does not encroach upon the 60-inch turning radius required by the code. Similarly, the placement of the sink 142 is another important consideration. The sink 142 should provide knee clearance underneath, typically at least 27 inches high, 30 inches wide, and 17 to 19 inches deep, and must be positioned so that it does not interfere with the wheelchair turning area 143-144.

The AI engine's analysis also includes identifying overlaps within the restroom design that may pose challenges to wheelchair users. In FIG. 1C, the AI engine identifies an overlap 147 where the turning area 144 intersects with the space occupied by the sink 142. The overlap 147 may potentially cause a problem when a wheelchair user 148 attempts to turn within the turning area 144, as the wheelchair may collide with the sink 142, preventing a smooth and unobstructed turn. For example, if the front casters of the wheelchair bump into the sink 142, it may halt the turn, requiring the user to make repeated adjustments to navigate the space. This not only creates a frustrating experience but also raises safety concerns, as any obstruction may lead to accidents or falls.

In cases where such an overlap 147 is detected, the AI engine is capable of generating automated suggestions to rectify the design flaw. For example, the AI engine may suggest relocating the sink 142 slightly away from the turning area 144 to eliminate the overlap 147. The suggestion may involve moving the sink 142 to a wall where it does not intrude into the required turning space or adjusting the layout of the restroom to increase the available space. The AI engine may also recommend reducing the size of adjacent fixtures, such as selecting a smaller sink model that provides adequate clearance, or altering the angle of installation to maximize the usable floor area.

Furthermore, building codes stipulate various other measurements that must be analyzed within the restroom 140 for compliance. For example, the distance between the water closet 141 and the nearest wall must be at least 16 to 18 inches to allow for proper wheelchair maneuverability. The height of the toilet seat is also a critical factor, with standards typically requiring it to be 17 to 19 inches above the floor to facilitate easy transfer from the wheelchair. The AI engine assesses these dimensions and others, such as the clear floor space in front of the sink 142, which should be at least 30 by 48 inches, and the placement of light switches and other controls, which should be within reach range, typically between 15 to 48 inches above the floor.

Another important aspect that the AI engine considers is the door width and swing direction. In an accessible restroom, the door must be at least 32 inches wide when open at 90 degrees, and it should not swing into the turning areas 143-144 unless there is sufficient space to accommodate both the door and the turning radius. If the door encroaches on the turning area, the AI engine may suggest repositioning the door to swing outward or using a sliding door mechanism to preserve the necessary clearance.

Additionally, the AI engine may evaluate the overall spatial arrangement within the restroom 140 to determine if any other elements, such as trash bins or storage units, interfere with the turning areas 143-144. These items must be located outside of the turning radius to prevent obstruction. In some cases, the AI engine may suggest removing unnecessary items from the restroom or redesigning storage solutions to be wall-mounted, thereby freeing up floor space.

FIG. 1C also underscores the importance of having clear and accessible pathways leading into and out of the restroom 140. The AI engine examines the approach and departure routes to the restroom 140, determining if they are wide enough (usually at least 36 inches) to accommodate wheelchair users. It also checks for any level changes or thresholds at the entrance that may hinder access. If such issues are detected, the AI engine may recommend ramping the threshold or leveling the floor to provide a seamless transition.

Referring now to FIG. 1D, a T-shaped turning space 130 is illustrated, which is a specific configuration used in spaces where a circular turning space cannot be accommodated. The T-shaped turning space is composed of several defined segments 131-137, each of which has a minimum length and width requirement dictated by accessibility codes. These requirements are used to provide sufficient space for wheelchair users to make a 180-degree or 360-degree turn within a confined area, such as in a restroom or other accessible space. The T-shaped design may particularly be useful in narrow or elongated spaces where a full circular turning radius would be impractical or impossible to implement.

The vertical and horizontal components of the T-shaped turning space form a structure that facilitates directional changes for the wheelchair. The user can move forward into the vertical segment before initiating a turn into the horizontal segment, allowing for a seamless transition between directions. This layout is particularly beneficial in environments where directional changes are frequently required, such as in multi-stall restrooms or in areas with multiple entry and exit points.

The T-shaped turning space 130 may particularly be advantageous in restrooms, where space is often limited by the presence of multiple fixtures, such as sinks, toilets, and stalls. In such environments, the full 60-inch circular turning space required by many codes may not be feasible, making the T-shaped configuration a practical alternative. The T-shape allows for the same degree of maneuverability but within a more confined footprint, which can be essential in retrofitting older buildings or designing spaces with constrained dimensions.

In addition to restrooms, the T-shaped turning space 130 is also applicable in other confined areas such as small kitchens, narrow hallways, or entryways in residential or commercial buildings. These areas often lack the width needed for a full circular turning space, making the T-shape an ideal solution for maintaining accessibility while optimizing the use of available space. The T-shape's adaptability to various environments underscores its importance in accessible design, particularly in spaces where maximizing floor area is a priority.

The T-shaped design also supports the needs of users with different types of mobility devices. Whether the user is in a manual wheelchair, an electric wheelchair, or using a walker, the T-shaped turning space 130 provides the necessary room for maneuvering. In addition to its spatial efficiency, the T-shaped turning space 130 is also designed to accommodate the needs of users in various scenarios. For example, in a restroom with multiple stalls, the T-shape allows users to navigate between stalls without the need for excessive back-and-forth movements. This reduces the physical effort required to move through the space and enhances the overall user experience.

The T-shaped turning space 130 also provides clear pathways for movement, reducing the likelihood of collisions with walls or fixtures. By creating a well-defined area for turning, the design helps to organize the space and guide users through it. This clarity is especially important in public spaces, where users may not be familiar with the layout and need to navigate quickly and efficiently. In environments where space is at a premium, the T-shaped turning space 130 can also be combined with other design strategies to maximize accessibility. For example, in a small restroom, wall-mounted fixtures can be used to free up floor space, while the T-shape provides the necessary turning room.

The T-shaped turning space 130 is also recognized by various building codes and standards as an acceptable alternative to circular turning spaces. This recognition makes it a practical choice for meeting accessibility requirements in a wide range of environments. By complying with these standards, the T-shaped design provides spaces that are accessible to all users, regardless of their mobility needs.

In addition to meeting regulatory requirements, the T-shaped turning space 130 enhances the overall usability of a space. By providing a designated area for turning, the design helps to create a more intuitive environment for wheelchair users. The T-shaped turning space 130 also offers flexibility in its implementation. Depending on the dimensions of the available space, the design can be adjusted to provide additional clearance in certain areas while still maintaining its overall functionality. This flexibility allows designers to tailor the T-shape to the specific needs of each project, so that it provides the optimal balance of accessibility and space efficiency.

In some embodiments, a turning area 130 is permitted to overlap with a lavatory and a water closet minimally due to the shape of fixtures involved. Some implementations of the present invention allow a user to provide input into an interactive user interface on a computing device to dictate how much turning area 130 is allowed as overlap. Some preferred embodiments provide that less than six inches of overlap may by allowed on each fixture.

Referring now to FIG. 1E, an exemplary portion 150 of a design plan is illustrated. The controller 123 may analyze the portion 150 for compliance with accessibility standards, specifically focusing on wheelchair turning clearance. The portion 150 includes two distinct areas: a bathroom area 151 and an office space 152. These areas are part of a comprehensive accessibility evaluation that considers the ease of movement and usability for wheelchair users in various environments. While FIG. 1E focuses on the two exemplary areas 151-152, the AI engine may be employed for similar analysis that can be used to assess other spaces, such as conference rooms, kitchens, hallways, and public gathering spaces, where wheelchair accessibility is a priority.

The bathroom area 151 depicted in FIG. 1E is equipped with a water closet 153, a series of urinals 154, and a sink 155. For a wheelchair user, such as the individual represented by 160A, navigating bathroom area 151 involves several key maneuvers that must be accommodated by the design. The AI engine identifies and defines several turning spaces, including 165A and 165B, which are used by the wheelchair user (160A) to navigate the bathroom 151. These turning spaces should provide the necessary clearance for the user to position their wheelchair in front of the fixtures, so that they can use them comfortably and safely.

When the wheelchair user 160A approaches the bathroom 151, they must first position themselves at the turning space 165B to open the door 161. The door 161 swings inward, requiring the user 160A to maneuver their wheelchair into the turning space 165B, allowing them to reach the door handle and pull the door open without obstruction. The width of the door 161 is also considered for providing unobstructed entry for the user 160A. A standard accessible door width is typically 32 inches, which allows enough room for the wheelchair to pass through while the user 160A manages the door. The inward swing of the door 161 is considered by the AI engine, which assesses whether the door's motion will interfere with the available space within the bathroom and whether the user can safely navigate through it.

Once inside the bathroom 151, the user 160A moves towards the water closet 153. The turning space 165A near the water closet 153 allows the user 160A to turn and position their wheelchair for use of the water closet 153. The turning space 165A provides the necessary room for the wheelchair to rotate, enabling the user 160A to either transfer onto the toilet or approach it for use. The AI engine evaluates whether the turning space 165A is adequate, considering factors such as the distance between the water closet 153 and surrounding walls or fixtures, which must not obstruct the user's movement.

After using the bathroom, the user 160A exits by reversing their path, requiring them to navigate back through the turning space 165B and open the door 161 once more. The transition from the bathroom 151 to the office space 152 involves passing through a lobby, marked by the width 163. The lobby's width 163 must be broad enough to allow the wheelchair user 160A to pass comfortably while also accommodating other users who may be moving through the space simultaneously. The AI engine assesses whether the lobby provides sufficient clearance for all users, especially in scenarios where the lobby is busy or where multiple users may intersect.

The path from the bathroom 151 to the office space 152 requires careful navigation through additional turning spaces, such as 165C and 165D. These turning spaces must be designed with adequate diameters to accommodate smooth directional changes as the wheelchair user 160A progresses from the bathroom 151, through the lobby, and into the office area 152. For example, at turning space 165D, the wheelchair user 160A encounters a door 162 that must be opened to enter the office space 152. The AI engine assesses this scenario by evaluating the swing direction of door 162 and the spatial constraints at turning space 165D.

Given that door 162 swings towards the user 160A, it creates a potential obstacle, especially in a confined area where space is limited. The AI engine thoroughly analyzes whether the current configuration provides enough room for the user 160A to approach, reach, and operate the door 162 without difficulty. It considers factors such as the wheelchair's approach angle, the required clearance for the door 162 to open fully, and the proximity of nearby walls or fixtures that may impede movement.

If the AI engine identifies that the inward-swinging door 162 poses a challenge, it may propose several modifications to enhance accessibility. One suggestion may be to reconfigure the door to swing outward, thereby eliminating the obstruction created by the inward swing. This change may allow the wheelchair user 160A to pull the door 162 open without having to back up or reposition their wheelchair within the limited space of turning area 165D.

Alternatively, the AI engine may recommend installing a sliding door as a more space-efficient solution. Sliding doors do not require swing clearance, which makes them ideal for areas where space is at a premium, such as the narrow lobby or corridor leading to the office space 152. By sliding along a track parallel to the wall, the door 162 would allow the wheelchair user160A to navigate the area without having to negotiate around a door that encroaches on their turning space. Another potential modification may involve altering the layout of the surrounding area to provide more space for maneuvering. For example, the AI engine may suggest increasing the width 163 of the lobby, thereby expanding turning space 165D to accommodate both the wheelchair and the door's operation.

Inside the office space 152, several other turning areas, including 165E through 165H, may be required for accommodating the maneuverability of wheelchair users. These turning areas enable wheelchair users to navigate the office space 152 efficiently, facilitating movement between desks, access to workstations, and participation in meetings. For example, turning space 165H, located near a wall, serves as a critical point where a wheelchair user may need to execute a 360-degree turn. This type of turn is required when a user needs to reverse their direction after reaching a dead-end or when they need to reposition themselves relative to a desk or workstation.

Consider a scenario where a wheelchair user is working at seat 159A (near the side wall). After completing their tasks, they may need to navigate to a different part of the office 152 or exit the area. The turning space 165H provides the necessary room for the user to perform a full rotation of their wheelchair, allowing them to exit the desk area and move towards another destination within the office 15. Without sufficient space at 165H, the user may be forced to make multiple smaller turns, which could be cumbersome and time-consuming, especially in a busy office environment.

In another example, a wheelchair user may be attending a meeting at the central table 157. After the meeting, they may need to turn their wheelchair to exit the table area and move towards another desk or the office exit. The turning space 165E may allow the user to make the necessary turn to navigate away from the table 157, providing a smooth transition between different areas of the office 152. If the space at 165E is too confined, the user may experience difficulty in maneuvering, which could hinder their ability to participate fully in the office environment.

The AI engine is adept at identifying potential constraints within the office space 152, with a key focus on areas where spatial limitations may hinder wheelchair accessibility. One such area is the narrow passage 158 between the wall-side desk 156 and the central table 157. This tight space 158 may not offer sufficient clearance for wheelchair users, such as 160B or 160C, to navigate comfortably, whether they need to pass through or perform a turning maneuver. The AI engine rigorously evaluates whether this passage complies with accessibility standards, considering factors such as the width required for a wheelchair to pass unobstructed, and the turning radius needed for effective maneuverability.

Upon identifying this potential bottleneck, the AI engine considers various solutions to improve accessibility. For example, it may recommend increasing the distance between the desk 156 and the table 157. By widening the passage, the office space 152 may accommodate a smoother and more straightforward movement for wheelchair users, reducing the risk of collisions or the need for complex maneuvering.

Alternatively, the AI engine may suggest reconfiguring the overall furniture layout to create a more accessible pathway. This may involve repositioning the desk 156 or the central table 157 to open up the passage or rearranging other elements in the office space 152 to alleviate congestion. For example, moving the central table 157 slightly or shifting the desk 156 closer to the wall may free up additional space, allowing for better flow and providing wheelchair users enough area to navigate the office space 152 without difficulty.

To thoroughly evaluate the compliance of the design portion 150, the AI engine may conduct detailed simulations of movements by multiple virtual wheelchair users (e.g., represented by 160A through 160E). These simulations meticulously explore various paths and spaces within the design portion 150, assessing how users interact with the environment under different scenarios. For example, the AI engine may simulate a user's journey from the bathroom 151 to a specific desk in the office space 152, taking into account factors like door navigation, hallway width, and the presence of obstacles. It also examines how a user moves through the lobby during peak times, when the space may be more crowded. This in-depth analysis helps uncover any potential accessibility issues that may not be apparent in static design plans, enabling designers to address these challenges proactively, making adjustments before the space is constructed or renovated.

In addition to simulating different user movements, the AI engine may incorporate a variety of wheelchair types, each with unique dimensions, turning radii, and maneuverability characteristics. This diversity in testing allows the AI engine to evaluate whether the design portion 150 can accommodate a wide range of wheelchair models. For example, a power wheelchair typically has a larger turning radius compared to a manual wheelchair, which may necessitate more space in certain areas of the design portion 150. The AI engine tests these scenarios to identify any areas where space may be too limited for a power wheelchair to maneuver effectively. By considering the specific needs of different wheelchair users, the AI engine's analysis contributes to a more versatile and inclusive design, one that is thoughtfully crafted to meet the varied requirements of all potential users, regardless of the type of mobility device they use.

In environments like the office space 152, the AI engine also considers how the arrangement of desks and furniture affects accessibility. For example, if a wheelchair user needs to approach a desk like 159 near the side wall, the turning space 165G must be adequate for them to position their wheelchair close enough to work comfortably while also allowing them to exit the space without difficulty. The AI engine evaluates whether the desk layout allows for such maneuverability and whether adjustments are needed to optimize the workspace for all users.

Another important aspect of the AI engine's analysis is how it assesses the usability of shared spaces within the office space 152, such as meeting rooms or communal areas. For example, the central table 157 in the office space 152 may be a focal point for meetings or collaborative work. The AI engine analyzes the space around the table 157, such as turning spaces 165E and 165F, to determine if wheelchair users can access the table 157, position themselves comfortably, and interact with others without facing physical barriers.

In cases where the AI engine identifies potential accessibility issues, it provides suggestions for improving the design. For example, if the limited space 158 between the desk 156 and table 157 is too narrow, the AI may suggest reconfiguring the desks or choosing smaller furniture to create more room. Similarly, if a door's swing direction is problematic, the AI engine may recommend changing the swing or opting for a different type of door that better suits the space.

The AI engine's ability to simulate different users and wheelchair types is a powerful tool in assessing the overall accessibility of the design portion 150. By considering a wide range of scenarios, the AI can identify potential problem areas that may not be immediately apparent in the initial design. For example, while the bathroom 151 may be accessible for a manual wheelchair, a power wheelchair could encounter difficulties due to its larger size. The AI engine's analysis helps to address these concerns, providing solutions that improve accessibility for all users.

Referring now to FIG. 1F, it illustrates an exemplary portion of a design plan depicting a water closet area 170, which comprises several non-compliant features identified by the AI engine during a detailed compliance analysis. The water closet area 170 includes several key fixtures including: a water closet 171, a urinal 172, a wash basin 173, and a bathtub 174. These fixtures are arranged within the space, but the AI engine's analysis reveals various issues related to clearances and spatial arrangements that hinder accessibility for a wheelchair user 177. The AI-based compliance analysis considers each element of the design portion, from the entry point to the interaction with each fixture, and highlights where the layout falls short of accessibility standards.

For entering the water closet area 170 through the door 175, the AI engine analyses the door width 175A and its swing direction 179. The width 175A of the door 175 determines whether the wheelchair user 177 can pass through without difficulty. If the door 175 is too narrow, the user may struggle to enter the space, particularly if they need to maneuver through a tight opening while managing the wheelchair. A standard accessible door typically requires a width of at least 32 inches to allow for smooth entry, but if this door 175 falls short of that measurement, it will restrict the user's ability to enter.

The door's inward swing direction presents another significant problem. As the door 175 swings inward, it risks colliding with the water closet 171, which is positioned near the entrance. This collision not only obstructs the door 175 from opening fully but also reduces the available space for the wheelchair user 177 to position themselves within the water closet area 170. The AI engine notes that when the door swings inward, it occupies a portion of the space that should otherwise be available for maneuvering, leading to a constrained environment that limits the user's mobility.

The placement of the water closet 171 relative to the door 175 also raises concerns regarding front clearance. There is insufficient space in front of the water closet 171 to allow the wheelchair user 177 to position themselves properly. This lack of clearance means that the user cannot approach the water closet 171 head-on, which is often necessary for transferring from the wheelchair to the water closet 171. If the user 177 is forced to approach at an angle or cannot get close enough, it complicates the transfer process and increases the risk of accidents.

Moving further into the water closet area 170, the AI engine identifies additional issues related to the distances between key fixtures. A first distance 176A, which measures the space between the inward swung door 175 and the urinal 172, is particularly problematic. The first distance 176A is too narrow to allow the wheelchair user 177 to pass through comfortably. When the door 175 is open, it further encroaches on the space in front of the water closet 171, making it nearly impossible for the user 177 to navigate between the door 175 and the urinal 172. This bottleneck creates a significant barrier that restricts the user's movement within the area.

Similarly, a second distance 176B, which is the space between the water closet 171 and the urinal 172, is also insufficient for wheelchair passage. The AI engine notes that although the turning space 178 near the urinal 172 may technically provide enough room for a wheelchair to turn, the space 178 becomes unusable due to the restricted clearance between the fixtures. The user 177 cannot effectively utilize the turning space 178 if they cannot pass through the narrow gap between the water closet 171 and the urinal 172. This layout flaw forces the user 177 into a position where they are unable to maneuver freely within the space, further limiting accessibility.

Additionally, the AI engine examines the third distance 176C, which refers to the width between the bathtub 174 and the adjacent side wall. This width is critical for determining whether the wheelchair user 177 can navigate to the wash basin 173 using a path 179. However, this space is found to be too narrow, preventing the user 177 from accessing the wash basin 173 directly. Without sufficient clearance along this path, the user 177 is unable to reach the wash basin 173 without difficulty, thereby reducing the functionality of the wash basin 173 within the overall design.

The AI engine's analysis does not stop at merely identifying these issues; it also provides actionable suggestions to improve the design. For the issue of the inward swinging door 175, the AI engine may recommend reconfiguring the door to swing outward instead. An outward swing would eliminate the collision with the water closet 171 and free up valuable interior space for maneuvering. Alternatively, the AI engine may suggest installation of a sliding door, which would not require swing space and would thus maximize the usable area within the water closet area 170.

To address the insufficient clearance between the water closet 171 and the urinal 172, the AI engine may propose repositioning these fixtures to create a wider gap. For example, moving the urinal 172 closer to the side wall may open up more space between the two fixtures, allowing the wheelchair user 177 to navigate through the area more easily. Similarly, the water closet 171 can be adjusted to provide adequate front clearance, making it easier for the user 177 to approach and use the water closet 171.

Regarding the narrow passage between the bathtub 174 and the side wall, the AI engine may recommend increasing the overall width of this section of the water closet area 170. This may involve shifting the bathtub 174 slightly to create more space along the path 179, enabling the user 177 to access the wash basin 173 without obstruction. If structural constraints prevent widening the passage, the AI engine may suggest alternative arrangements, such as repositioning the wash basin 173 to a more accessible location within the water closet area 170.

The AI engine's comprehensive analysis of the water closet area 170 highlights the importance of considering all aspects of space usage and fixture placement in an accessible design. Each identified issue, whether related to door swing direction, fixture spacing, or clearance widths, contributes to the overall accessibility of the space within the water closet area 170. By addressing these issues with targeted suggestions, the AI engine helps transform the water closet area 170 into a more functional and user-friendly environment for wheelchair users.

Moreover, the AI engine's recommendations extend beyond just the physical arrangement of the fixtures. It may also suggest using fixtures designed with accessibility in mind, such as lower-height sinks or water closets with grab bars, to further enhance usability. For example, a wall-mounted wash basin with open space underneath may provide more legroom for the wheelchair user 177, making it easier to approach and use the wash basin 173.

In some embodiments, the AI engine may determine various distances, widths, and dimensions of spaces and fixtures within a design plan by utilizing a scale that is either marked directly on the design plan or provided separately by the user. The scale may allow the AI engine to accurately assess the spatial layout and make informed decisions regarding accessibility compliance.

Upon receiving the design plan, the AI engine first identifies the presence of a scale marker, which is often included in architectural and design drawings. The scale marker may indicate that one inch on the plan corresponds to a specific number of feet or meters in real-world dimensions. For example, a common scale may be 1 inch=10 feet. The AI engine scans the design plan (or portion of the design plan) to locate the scale marker, and once identified, it uses this information to calibrate its measurements.

If the design plan lacks a visible scale marker, a user may have the option to input the scale manually. The user may provide this information by specifying the exact scale ratio, such as 1:100, meaning that 1 unit on the design plan equals 100 units in real life. Alternatively, the user may input the real-world dimensions of a known object or distance on the design plan, such as the length of a wall, which the AI engine may then use to extrapolate the scale for the entire design. An object with known dimension may also be marked on the design plan itself.

Once the scale is determined, the AI engine begins analyzing the design plan by measuring various distances, widths, and dimensions of the spaces and fixtures. It does this by interpreting the graphical elements on the design plan, such as lines representing walls, fixtures, doorways, and other architectural features. The AI engine calculates the lengths of these lines and converts them into real-world measurements using the identified scale.

For example, the AI engine may measure the width of a doorway on the design plan by calculating the distance between the two lines representing the door frame. Using the scale, the AI engine then converts this measurement to its real-world equivalent, determining whether the door width meets accessibility standards.

The AI engine can also determine the clearance around fixtures by measuring the distances between these fixtures and nearby walls or other objects. For example, if analyzing a bathroom layout, the AI engine may measure the space between a water closet and a nearby wall to assess whether there is sufficient room for a wheelchair to maneuver. It may calculate this distance on the plan and convert it to the actual dimension using the scale.

In some embodiments, the AI engine can also utilize pixel count as a method for determining various distances, widths, and dimensions on a design plan when the scale is known. In this approach, the AI engine first calculates the number of pixels between two points on the digital design image (design plan), such as the known distance between walls or the known width of a doorway. By correlating the pixel count with the known scale of the plan (e.g., 1 inch=10 feet), the AI engine can convert the pixel-based measurement into an actual real-world dimension. Distances, widths, and dimensions may encompass various elements such as the height of fixtures from the floor, the distance between fixtures, and the overall spatial layout.

Referring now to FIG. 1G, an exemplary water closet area 190 that has been extracted from a design plan for thorough compliance analysis by an AI engine, is illustrated. The water closet area 190 is designed to meet accessibility standards, providing all fixtures and spaces to accommodate the needs of wheelchair users. The water closet area 190 may include a water closet 191, grab bars 192A and 192B, a soap dispenser 193, and a backrest 194, all arranged to support the independent use of the water closet area 190 by individuals with mobility impairments.

The water closet 191 is positioned in such a way that it is easily accessible to a wheelchair user 195. The AI engine assesses whether the water closet 191 is appropriately placed within the water closet area 190 to allow for both direct approach and lateral transfer from a wheelchair 196. The distance from the adjacent walls, as well as the height and positioning of the water closet 191, are also analyzed to confirm that they meet the requirements for ease of use and comfort. Additionally, the positioning of the water closet 191 is coordinated with the surrounding elements, such as the grab bars 192A-192B and backrest 194, to facilitate secure transfers and stability.

Grab bars 192A and 192B may be installed around the water closet 191 to provide support for the wheelchair user 195 during transfers and while using the water closet 191. These bars are typically mounted at specific heights and distances from the water closet 191 to offer optimal leverage and stability. For example, grab bar 192A may be installed horizontally along the side wall, at a height that aligns with the user's seated position, allowing them to grip the bars 192A-192B securely as they maneuver themselves onto the water closet 191. In some embodiments, grab bar 192B may be positioned vertically on the rear wall, enabling the user 185 to maintain balance while seated or when transitioning back to the wheelchair 196.

The soap dispenser 193 is likely mounted at a height that is within easy reach of the user 195 while seated, so that they can complete their hygiene routine without having to stretch or stand. The AI engine may verify that the soap dispenser 193 is within the range specified by accessibility standards, typically between 15 to 48 inches from the floor, depending on the user's seated height. Furthermore, the soap dispenser 193 may be touchless, which adds another layer of convenience, reducing the need for manual dexterity or strength to operate the device.

The backrest 194 may be important component for certain users who require additional support while seated on the water closet 191. Positioned behind the water closet 191, the backrest 194 may provide comfort and stability, particularly for those who may have limited trunk control. The AI engine may analyze the backrest's height and angle to determine if it offers adequate support without impeding the user's ability to transfer to and from the wheelchair 196.

One of the most critical aspects of the water closet area 190 is the front clearance area 197. The front clearance area 197 may be designed to allow the wheelchair user 195 to approach the water closet 191 head-on, which is required for both frontal and lateral transfers. The AI engine examines this clearance to determine if it is wide enough to accommodate different types of wheelchairs, including those with larger dimensions or specialized configurations.

A wheelchair turning area 199 (within the front clearance area 197) provides sufficient space for the wheelchair to rotate fully, as indicated by the rotational path 198 of the wheelchair 196. The turning area 199 enables the user 195 to turn their wheelchair 196 around within the water closet area 190 without having to back out of the space, which can be challenging and unsafe in confined environments. The AI engine verifies that the turning area 199 meets the minimum required dimensions, typically a 60-inch diameter, which is the standard for allowing a full 360-degree turn for most wheelchair models.

The placement and arrangement of fixtures within the water closet area 190 are coordinated to avoid creating obstacles within the turning area 199. For example, the water closet 191 and grab bars 192A and 192B are positioned to be accessible without encroaching on the turning area 199 needed for the wheelchair 196 to turn. Similarly, the soap dispenser 193 is located in a way that allows easy access without interfering with the user's ability to maneuver within the turning area 199.

The AI engine's analysis also considers the overall layout of the water closet area 190 in relation to the rest of the building's design. For example, it may assess whether the water closet area 190 is positioned in a convenient location within the facility, such as near entrances, exits, or other key amenities, to reduce the distance that wheelchair users 195 need to travel. It also considers the path of travel leading to the water closet area 190, so that it is free of obstructions and provides sufficient width for easy navigation.

In addition to analyzing the physical dimensions and placement of fixtures, the AI engine may also evaluate the user's interaction with the environment within the water closet area 190. This may include assessing how easily the user 195 can reach and operate each fixture, such as the flush mechanism on the water closet 191, the soap dispenser 193, and any other controls or accessories within the water closet area 190. The AI engine may also simulate different user scenarios, such as varying wheelchair types, to determine if all users can access and use the space effectively.

The water closet area 190 is also assessed for compliance with broader accessibility standards, such as those outlined in the Americans with Disabilities Act (ADA) or similar regulations in other jurisdictions. These standards provide specific guidelines on the placement, height, and operation of fixtures within accessible bathrooms. The AI engine determines if the design plan meets these standards, and where discrepancies are found, it provides recommendations for modifications to bring the design into compliance.

For example, if the AI engine determines that the height of the soap dispenser 193 is slightly above the recommended range, it may suggest lowering it to a more accessible height. Similarly, if the turning area 199 is found to be slightly smaller than the required dimensions, the AI engine may recommend adjusting the placement of the water closet 191 or grab bars 192A-192B to create more space for maneuverability.

In some embodiments, the AI engine may also consider the materials and finishes used within the water closet area 190. For example, it may analyze whether the flooring provides sufficient traction to prevent slipping, especially when wet, or whether the grab bars are made from materials that offer a secure grip. Moreover, the AI engine may also simulate use of the water closet area 190 under different lighting conditions to determine if it remains accessible in various scenarios. Adequate lighting is required for all users, and the AI engine may recommend adjustments to the lighting design if it finds that certain areas are poorly illuminated or that the lighting creates glare that could affect visibility.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references. This text may include annotations, dimensions, or labels (e.g., name of a space) that provide additional context or instructions relevant to the building's design and compliance requirements.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; complexity of features (e.g. a number of angles or curves included in a perimeter of an area; a type of hardware that may be used to construct a portion of a building, a quantity of a type of hardware that may be used to construct a portion of the building; or other variable value.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). Other features may be removed, such as the text 208, the plumbing features and other internal appliances and furniture which may be shown on drawings used as input to the processing. Again, such feature recognition may be useful to accomplish other goals, but for a goal of boundary 211 definition that delineates a floorplan 210 as illustrated in FIG. 2B a pictorial representation may be purposefully devoid of such features, as illustrated.

Referring now to FIG. 2B, a boundary 211 is illustrated around a grouping of defined spaces 213-216. Spaces are areas within a boundary (which may include, but are not limited to rooms, hallways, stairwells etc.).

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. Boundaries that include polygons are useful, for example, in creating a three-dimensional representation of a design plan.

According to the present invention, a boundary may be represented on a user interface as one or both of: one or more line segments, and one or more polygons. In addition, a feature may be represented as a single point, a polygon, an icon, or a set of polygons. In some embodiments, a point may be placed in a centroid position for the feature, and the centroid points may be counted, summarized, subtracted, averaged, or otherwise included in mathematical processes.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. Extrapolation of a two-dimensional reference into a three-dimensional representation may be supported with a boundary that includes polygons.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Typical units referenced in a scale include inches: feet, centimeters: meters, or any other appropriate unit.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length.

Referring now to FIG. 2C, a user interface 220 is illustrated with multiple regions 221-224. The multiple regions 221-224 may be presented via different hatch representations or other distinguishing patterns (in some embodiments regions may also be represented as various colors etc.). During training of AI engines, and in some embodiments, when a submitted design drawing includes highly customized or unique features, a user may wish to adjust an automated identification of boundaries and automated filling of space within the boundaries.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, of change an aspect of polylines, polygons, arcs, circles, ellipses, splines, NURBS or predefined subsets of the interface. The user can thereby “correct” an assignment error made by the AI engine, or simply rearrange aspects included in the interface for a particular purpose or liking.

In some embodiments, modifications and/or corrections of this type can be documented and included in training datasets of the AI model, also in processes described in later portions of the specification.

Discrete regions may be regions associated with an estimation function. A region that is contained within a defined wall feature may be treated in different ways such as ignoring all areas in a boundary, to counting all areas in a boundary (even though regions do not include boundaries). If the AI engine counts the area, it may also make an automated decision on how to allocate the region to an adjacent region or regions that the region defines.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. Regions with similar dominance rank may share space, or regions with higher dominance rank may be automatically assigned to a boundary. In general, a dominance ranking schema will result in an area being allocated to the space with the higher dominance rank. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified.

In some embodiments, wheelchair turning clearance compliance within a building design may be determined based on the dominance rank of a space. The AI engine assigns a dominance rank to various spaces within the design plan, prioritizing areas based on their function, size, and relevance to accessibility. For example, in a scenario where a kitchen and a bathroom share a common boundary, the bathroom may be assigned a higher dominance rank due to its direct impact on accessibility standards, such as clear floor space and turning radius requirements. As a result, the AI engine may allocate more space to the bathroom, so that the necessary wheelchair turning clearance is met, even if it means reducing the size of the adjacent kitchen area. In another instance, a hallway intersection may be prioritized over a storage closet, allowing for adequate turning space at the intersection, which is critical for wheelchair users to navigate through the building.

In some embodiments, an area 235A between interior boundaries 236-237 and an exterior boundary 235 may be fully assigned to an adjacent region 232-234. An area between interior boundaries 235A may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. Parameters may also be based upon items that are automatically counted using AI analysis of pixel patterns that identify a pattern as an item, such as, by way of non-limiting example, one or more of: doors or other paths of egress; plumbing fixtures; fixed obstacles; stairs; inclines; and declines.

In some examples, a boundary 235-237 and associated area 235A may be allocated to a region 232-234 according to an allocation schema, such as, for example, an area dominance hierarchy, to prioritize a kitchen over a bathroom, or a larger space over a smaller space. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region as illustrated in FIGS. 2A-2D. In various embodiments, different calculated features are included in a user interface floorplan model 231 such as features representing aspects of a wall, such as, for example, center lines, the extent of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence a decision on compliance with a local code.

Once boundaries have been defined a variety of calculations may be made by the system. A controller may be operative to perform method steps resulting in calculation of a variable representative of a floorplan area, which in some embodiments may be performed by integrating areas between different line features that define the regions.

Alternatively, or in addition to method steps operative to calculate a value for a variable representative of an area, a controller may be operative to generate a value for element lengths, which values may also be calculated. For example, if ceiling heights are measured, presented on drawings, or otherwise determined, then volume for the room and surface area calculations for the walls may be made. There may be numerous dimensional calculations that may be made based on the different types of model output and the user-inputted calibration factors and other parameters entered by the user.

In some embodiments, a controller may be provided with two dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects.

Referring now to FIG. 2E, an exemplary portion 240 of a design plan is illustrated, showing a reception area within an office building. The reception area comprises a wheelchair user 241 interacting with a receptionist 242 across a reception counter 243. The AI engine analyzes the design portion 240 for compliance with relevant accessibility standards, focusing on the height 243A of the reception counter 243. The AI engine determines that the height 243A is excessively high, thereby obstructing the wheelchair user 241 from effectively seeing or communicating with the receptionist 242.

The AI engine identifies that the height 243A of the reception counter 243 does not meet the specified guidelines for accessible counters, which generally recommend a lower height to accommodate both standing and seated individuals. In this scenario, the height 243A of the counter 243 impedes direct visual and verbal communication between the wheelchair user 241 and the receptionist 242, thus failing to provide an inclusive and accessible environment.

The AI engine may provide recommendations based on the analysis of the height 243A of the reception counter 243. Such recommendations may include lowering the counter 243 to a height compliant with accessibility standards, or alternatively, adding a separate lower section of the counter to accommodate wheelchair users.

In some embodiments, the AI engine may extend its analysis to other areas of the building, such as break rooms, restrooms, or meeting spaces, to assess the height and accessibility of various fixtures. For example, the AI engine may analyze the height of kitchen countertops in break rooms to confirm that they are accessible to all employees, including those in wheelchairs.

In addition, the AI engine may simulate different user interactions within the reception area, evaluating how multiple users, including wheelchair users, navigate the space during peak times. The AI engine assesses whether the design accommodates these interactions without causing congestion or creating additional barriers for wheelchair users. The AI engine's analysis and recommendations support the creation of an accessible, functional, and inclusive reception area, addressing potential accessibility issues related to the height of the reception counter 243 and other fixtures within the design portion 240.

The AI engine may also consider similar scenarios in different environments, such as hospitals, where the reception or check-in counters are often the first point of contact for patients. In a hospital setting, it is particularly important that reception counters be accessible, as patients arriving in wheelchairs or with other mobility aids need to be able to register, ask questions, or receive assistance without difficulty. If the counter is too high, patients may experience frustration or discomfort, which can exacerbate stress or anxiety during what is already a challenging time.

In addition to reception counters, the AI engine can analyze other fixtures in public and commercial spaces that may be inaccessible due to their height. For example, in a bank or post office, transaction counters where customers complete forms, make payments, or receive service need to be accessible to everyone, including those in wheelchairs. A counter that is too high could prevent a wheelchair user from signing documents comfortably, handing over money, or receiving items without assistance, thereby compromising their independence.

Another example can be found in retail environments, where checkout counters are often placed at a height designed for standing customers. If these counters are not equipped with a lower, accessible section, wheelchair users may struggle to reach the counter to make purchases, interact with cashiers, or pack their bags. The AI engine, in analyzing these spaces, may identify such non-compliant counters and recommend modifications, such as adding a lower counter section or providing an alternative accessible checkout station.

Moreover, in educational institutions, such as schools or universities, service desks in libraries, administrative offices, or counseling centers must be accessible to all students, including those who use wheelchairs. If the desk or counter is too high, students may find it difficult to engage with staff, ask questions, or access resources. The AI engine's analysis in this context may verify that all students have equitable access to services and support, regardless of their mobility.

The AI engine's role in analyzing the height 243A of the reception counter 243 in FIG. 2E extends beyond just identifying the issue. It also provides practical solutions to bring the design into compliance with accessibility standards. For example, the AI engine may suggest lowering the counter to an appropriate height or adding a separate lower section specifically for wheelchair users. Additionally, it may recommend installing technology such as video screens or microphones to facilitate communication if lowering the counter is not feasible due to space constraints or other design considerations.

In some cases, the AI engine may analyze the surrounding environment to identify alternative solutions that improve accessibility. For example, it may recommend creating a separate, accessible check-in station elsewhere in the reception area or providing a mobile check-in option that allows wheelchair users to complete the necessary processes without needing to approach a high counter. These recommendations are tailored to the specific needs of the space and the users it serves, so that the design is both functional and inclusive.

Another important consideration analyzed by the AI engine is the placement of signage and other visual aids at the reception counter. For a wheelchair user, signage placed at a height meant for standing individuals may be difficult or impossible to read. The AI engine may assess whether all necessary information is displayed at a height that is visible and legible from a seated position. This may involve lowering signs, using larger font sizes, or providing digital displays that can be adjusted according to the user's needs.

The analysis performed by the AI engine in FIG. 2E can also be extended to address accessibility in different types of workspaces within the office building. For example, the AI engine may assess the height of desks, conference tables, or workstations to determine if wheelchair users can participate fully in office activities. If a desk is too high or does not provide sufficient knee clearance, the user may be unable to work comfortably or access necessary equipment, such as computers or phones.

In a broader context, the AI engine's capabilities can be applied to other areas of the office building, such as break rooms, restrooms, or shared meeting spaces. For example, in the break room, countertops and kitchen facilities need to be at accessible heights to allow all employees to prepare food, use appliances, or access storage areas. Similarly, in shared meeting spaces, tables and chairs should be arranged to accommodate wheelchair users, providing enough space for them to navigate and participate in discussions without physical barriers.

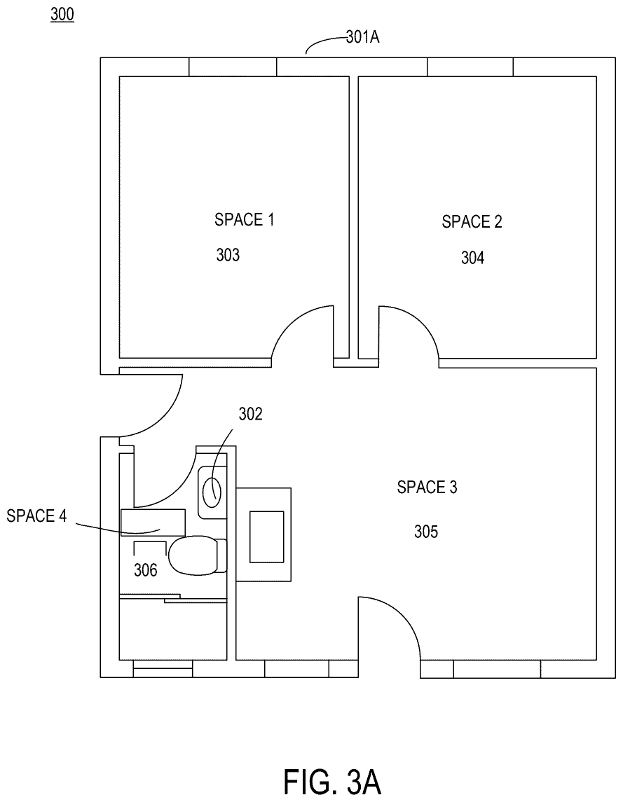

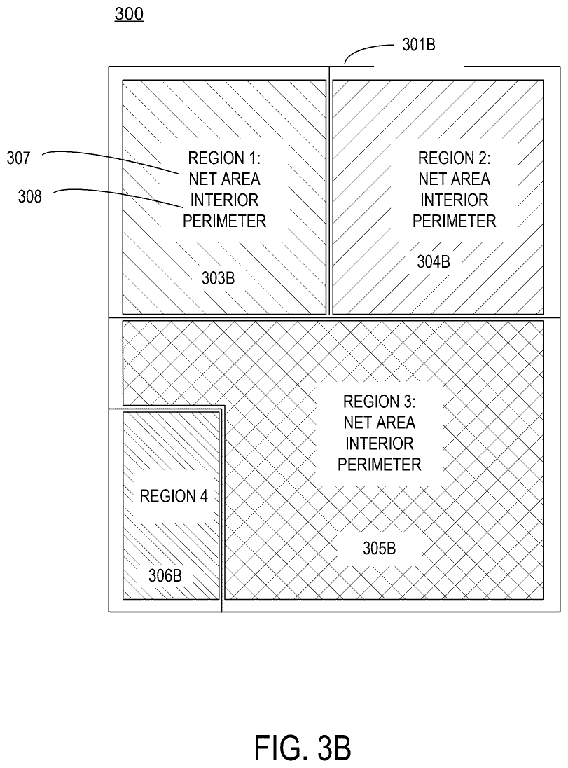

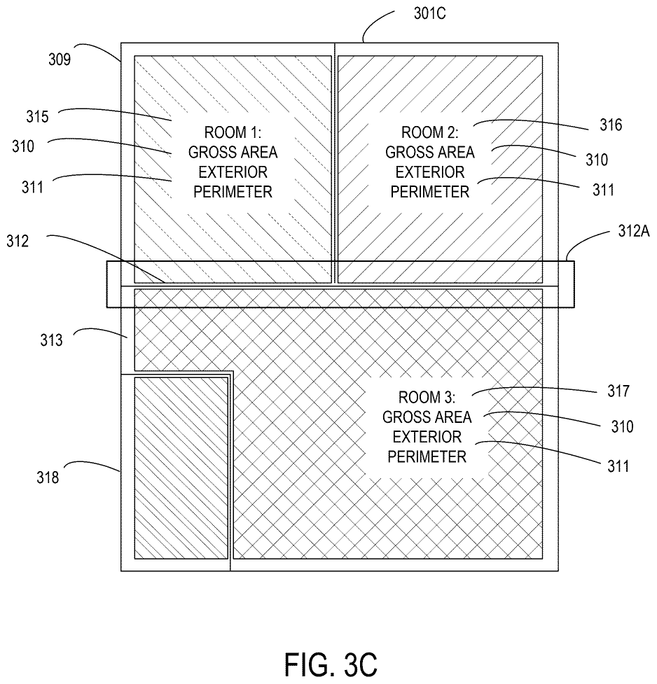

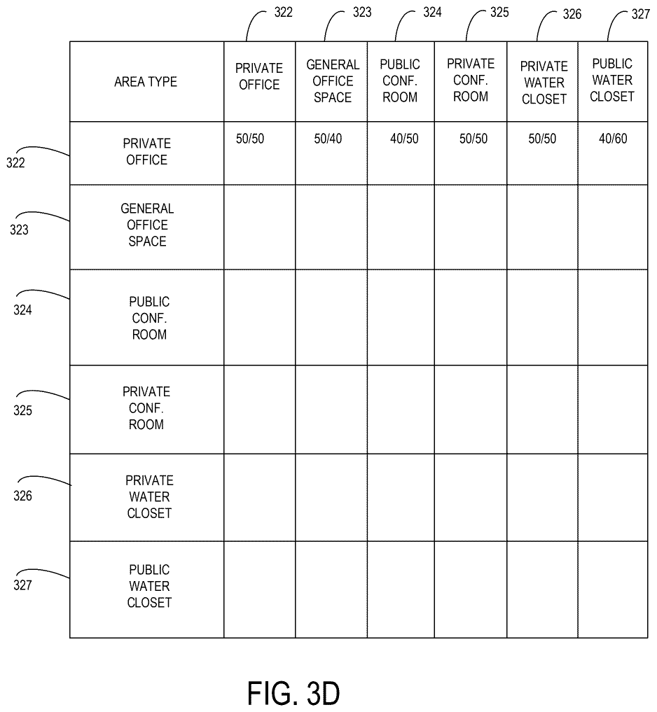

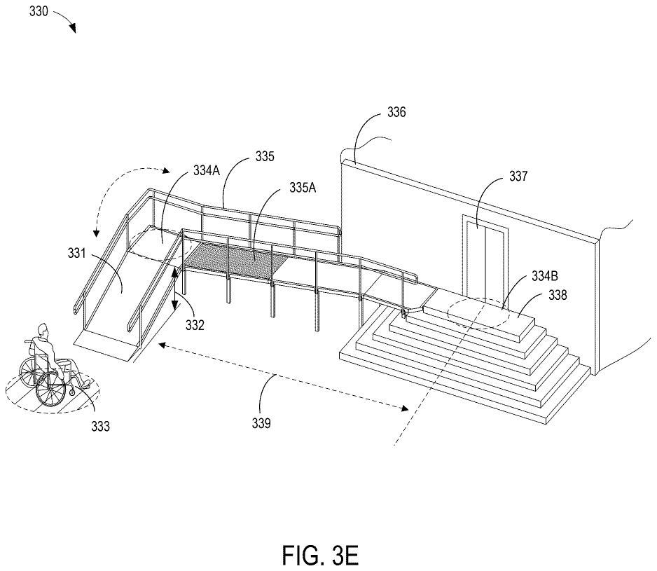

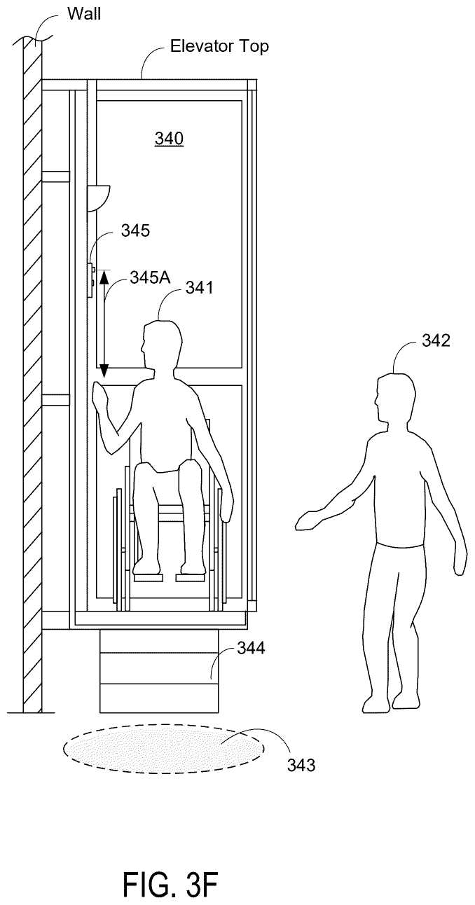

Referring now to FIGS. 3A-3C a user interface 300 may generate multiple different user views, each view has different aspects related to the two-dimensional reference drawing input. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. The controller may generate a tally of multiple fixtures 302 identified in the two-dimensional reference. The tally of multiple fixtures 302 may include some or all of the fixtures identified in the two-dimensional reference and be used to generate an estimate for completion of a project illustrated by, or otherwise represented by the two-dimensional reference. Referring now to FIG. 3B, in the user interface 300 a user may specify to a controller that one of multiple views available to be presented via the interface. For example, a user may designate via an interactive portion of a screen displaying the user interface 300 that a region view 301B be presented. The region view 301B may identify one or more regions and/or spaces 303B-306B identified via processing by a controller, such as for example, via an AI engine running on the controller. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a bathroom; and flooring and wall board associated with Region 4 may be designated as needing to be waterproof material.

Referring now to FIG. 3C a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space, but may be less useful to an occupant than a net interior area 307 and interior perimeter 308. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior).

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms.

In some embodiments, the AI engine within a user interface analyzes various views of a design plan to assess compliance with relevant accessibility codes. For example, in one view, the AI identifies fixtures and calculates the available turning space within regions like bathrooms or hallways. If a fixture encroaches on the required turning radius, the AI flags the issue and suggests modifications. Additionally, the AI may consider the net interior area and ceiling height to verify sufficient space for maneuvering.

In some embodiments, the present invention calculates an area bounded within a series of polygon elements (such as, for example, using mathematical principals or via pixel counting processes), and/or line segments.

In some embodiments, in an area, bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like.

These views may be used in generating estimation analysis documents. Estimation analysis documents may rely on fixtures, region area, or other details. By assisting in generating net area, estimation documents may be generated more accurately and quickly than is possible through human-engendered estimation parameters.

With reference now again to FIGS. 3B and 3C, regions 303B-306B defined by an AI engine may include one or more Rooms in FIG. 3B subsequently have regions assigned as “Rooms” in FIG. 3C.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example, adjacent areas (e.g., area 315 and area 317 or area 317 and area 318), the hierarchical relationship may be used to generate a dominance ranking of one area of another area, or to ascertain factors useful in determining whether a building is in compliance with an applicable code. For example, a dominance ranking may allocate space used to calculate one or more of: an occupancy load; a width and/or area of an egress path; a width and/or area of a common path; a length of a dead end; egress capacity; and travel distance from a furthest point.

In some embodiments, the AI engine analyzes wheelchair turning clearance within the hierarchical framework of area types defined by dominance relationships. For example, in a scenario where a wheelchair turning space intersects with multiple areas such as a hallway and a private office, the AI engine may assign dominance to the area that has a higher priority for compliance based on accessibility codes. If the hallway is ranked higher due to its role as an egress path, the AI engine may allocate more space to the hallway, so that the turning radius is sufficient for wheelchair users.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ratio, but a private office adjacent to a general office space may be allocated 60 percent of an area included in a border region, and so on.

Dominance associated with various areas may be systemic throughout a project, according to customer preference, indicated on a two-dimensional reference by two-dimensional reference basis or another defined basis.

Referring now to FIG. 3E, it illustrates an exemplary ramp system 330 designed for a wheelchair user 333, showcasing its implementation as part of an accessible entrance to a building 336. The ramp system 330 provides access to individuals who use wheelchairs or other mobility aids, allowing them to navigate elevation changes that may otherwise be impossible to traverse independently. The use of ramps is required in public and private buildings to be accessible to all individuals, regardless of mobility limitations, facilitating inclusive design in various environments such as schools, hospitals, government buildings, and commercial establishments.

The ramp system 330 comprises a ramp 331, which the wheelchair user 333 utilizes to enter the building 336. Ramps are indispensable in modern building design, particularly in settings where access to elevated entrances is necessary. For example, ramps are mandatory in facilities such as hospitals, where patients and visitors with mobility issues frequently require a smooth and accessible path to enter the building. Similarly, in educational institutions, ramps provide students and staff with disabilities the means to access classrooms, auditoriums, and other key areas without facing barriers.

As part of a comprehensive design plan, the ramp system 330 is subject to analysis by the AI engine, which evaluates the ramp's compliance with accessibility standards. The AI engine examines various aspects of the ramp 331, including its height 332 from the floor or ground, the slope of the ramp 331, and other critical dimensions that impact its usability. The slope of the ramp 331 may particularly be important, as it determines the ease with which a wheelchair user 333 can ascend or descend the ramp 331. If the slope is too steep, the user 333 may struggle to propel their wheelchair up the incline or may face increased risk of losing control while descending. Conversely, if the slope is too shallow, the ramp 331 may occupy an unnecessarily large footprint, reducing the efficiency of the design.

The AI engine calculates the slope of the ramp 331 by measuring the vertical rise relative to the horizontal run. For most accessibility standards, such as those outlined by the Americans with Disabilities Act (ADA), the recommended slope ratio is 1:12, meaning that for every inch of vertical rise, the ramp should extend 12 inches horizontally. This ratio provides a balance between safety and practicality, so that the ramp is not too steep while also not taking up excessive space. The AI engine determines whether the ramp 331 meets this slope requirement and identifies any deviations that may require correction.

In addition to slope analysis, the AI engine may assess the presence and design of turning areas within the ramp system 330, such as the turning area 334A. Turning areas may be present in ramps that change direction, allowing wheelchair users 333 to reposition themselves as they approach different parts of the ramp 331. The AI engine evaluates the dimensions of turning area 334A, determining if it provides sufficient space for the user 333 to maneuver comfortably. According to accessibility guidelines, a turning area should typically provide at least a 60-inch diameter to allow for a full 360-degree turn, accommodating the needs of different wheelchair models. If the turning area is too small, the user 333 may be unable to navigate the turn, which may lead to difficulties in completing the journey up the ramp 331.

The width of the ramp 331 is another parameter analyzed by the AI engine. The width must be adequate to accommodate a variety of wheelchair sizes, allowing users to move along the ramp 331 without feeling constrained or at risk of veering off the edge. A standard minimum width for accessible ramps is 36 inches, though wider ramps are often recommended in high-traffic areas or in environments where larger mobility devices are used. The AI engine checks whether the ramp 331 meets these width requirements, identifying any sections that may need to be widened to enhance accessibility.

Surface texture is another important consideration in ramp design, as analyzed by the AI engine. The surface of the ramp 331 should neither be too smooth, which may lead to slippage, nor too rough, which may make it difficult for wheelchair users to move across. A smooth surface, particularly when wet, may not provide enough traction, increasing the risk of accidents. On the other hand, a surface that is overly rough or uneven may create excessive resistance, requiring the user to exert more effort to propel the wheelchair, potentially leading to fatigue or discomfort. The AI engine evaluates the texture of the ramp's surface, determining whether it strikes the right balance between safety and usability.

The ramp system 330 may also include railings 335, which provide additional support and security for wheelchair users 333. The AI engine may analyze the height, stability, and placement of these railings, verifying if they are within the recommended height range of 34 to 38 inches from the ramp surface. Railings 335 may be useful for users who may need to steady themselves while navigating the ramp 331, offering a point of contact that enhances confidence and control. The AI engine may assess whether the railings 335 are securely fastened, continuous along the length of the ramp 331, and free from obstructions that may impede their use.

The AI engine may also identify specific issues with the surface of the ramp 331, such as the presence of a rough areas 335A. Rough surfaces, especially if they include obstructions like ridges or grooves, can make it challenging for the wheelchair user 333 to move smoothly across the ramp 331. These obstructions may cause the wheelchair to jerk or require additional force to push, which may be particularly taxing for users with limited upper body strength. The AI engine flags these problematic areas and recommends smoothing the surface or replacing it with a more suitable material that facilitates easy movement.

Another important element of the ramp system 330 is the turning area 334B located at the door threshold 338. The AI engine analyzes this turning area334B to determine if it provides adequate space for the wheelchair user 333 to maneuver before entering the building 336. The turning area 334B must allow for sufficient clearance not only for turning but also for aligning the wheelchair with the door 337. If the space is too constrained, the user 333 may struggle to position themselves properly to open and pass through the door 337, creating a potential bottleneck at the building entrance.

The AI engine also closely examines the door threshold 338 itself. The threshold 3338 should be level with the surrounding surfaces, minimizing the height difference to prevent the wheelchair from catching or becoming stuck. A threshold that is too high can act as a barrier, making it difficult for the wheelchair to roll smoothly into the building. In contrast, a threshold that is too low may not adequately seal the door, leading to issues with weatherproofing or energy efficiency. The AI engine assesses the height and design of the threshold 338, recommending adjustments if it is found to be incompatible with accessibility requirements.

The AI engine may further analyze the distance 339 between the ramp 331 and the door 337. This distance may affect how easily the wheelchair user 333 can transition from the ramp 331 to the building entrance. If the distance is too short, there may not be enough room for the user to position themselves properly before opening the door 337. If the distance is too long, it may create an unnecessary extension of the ramp 331, making the approach to the building 336 less direct and more tiring for the user 333. The AI engine evaluates this distance and suggests modifications to optimize the user's approach to the entrance.

For each non-compliance issue identified by the AI engine, automated recommendations may be provided to correct the deficiencies. For example, if the slope of the ramp 331 is found to be too steep, the AI engine may suggest extending the length of the ramp to achieve a more gradual incline. Similarly, if the turning area 334A is too small, the AI engine may recommend expanding the platform to provide the necessary clearance. In cases where the surface of the ramp 331 is too rough (335A) or includes obstructions, the AI engine may advise resurfacing the ramp with a material that offers better traction and a smoother glide.

In scenarios where the door threshold 338 is not level with the floor (inside door 337), the AI engine may propose raising or lowering the threshold 338 to match the interior floor level, eliminating any height difference that may hinder wheelchair movement. Additionally, if the distance 339 between the ramp 331 and the door 337 is inadequate, the AI engine may recommend adjusting the ramp's placement or redesigning the entryway to provide a more seamless transition.

The AI engine's analysis extends to evaluating the overall safety and usability of the ramp system 330, considering factors such as the potential for water accumulation on the ramp surface, the visibility of the ramp 331 in low-light conditions, and the availability of tactile indicators for visually impaired users. These additional considerations may contribute to a comprehensive assessment that not only addresses the immediate needs of wheelchair users 333 but also enhances the general safety and accessibility of the building entrance.

Referring now to FIG. 3F, it illustrates an exemplary elevator 340, which is subject to compliance analyses as part of certain embodiments of the present invention. Elevators play an important role in providing better accessibility within building to all users, including those who use wheelchairs. For wheelchair users 341, elevators provide a necessary means of vertical transportation between floors, especially in multi-story buildings where stairs or ramps are not an option. It is imperative that elevators be designed with accessibility in mind, allowing wheelchair users 341 to enter, maneuver within, and operate the elevator 340 with ease and independence.

The AI engine may analyze the elevator 340 (as part of a design plan) to determine its compliance with accessibility standards. One of the primary aspects that the AI engine evaluates may be the entrance clearance to the elevator 340. The entrance must be wide enough to allow a wheelchair user 341 to enter without difficulty. Standard guidelines generally recommend a minimum door width of 36 inches, although wider entrances may be required for larger wheelchairs or in high-traffic areas where multiple users may need to enter simultaneously. The AI engine may assess the entrance width, identifying any potential obstructions or design flaws that may impede easy access for wheelchair users.

In addition to the entrance clearance, the AI engine may examine the presence of a sufficient turning area 343 in front of the elevator 340. The turning area 343 may be critical because it allows the wheelchair user 341 to position themselves correctly before entering the elevator 340. The turning area 343 must be spacious enough to accommodate a full 360-degree turn, so that the wheelchair user 341 can approach the elevator 340 from any direction and align their wheelchair with the entrance. The AI engine checks the dimensions of the turning area 343, comparing them to established accessibility standards, and flags any deficiencies that may hinder the user's ability to maneuver effectively.

Further, the AI engine may also analyze the space inside the elevator 340 to determine whether it is adequate to accommodate both the wheelchair user 333 and any other passengers, such as an individual 342 depicted in FIG. 3F. The interior space of the elevator 340 must be sufficient not only to house the wheelchair but also to allow the wheelchair user 341 to turn and position themselves comfortably within the elevator 340. The AI engine assesses whether the elevator's interior dimensions meet the recommended minimums, typically requiring a clear floor space of at least 54 inches deep and 36 inches wide for a standard wheelchair.

The AI engine may also evaluate the height of the elevator 340 to determine if it provides sufficient headroom for all users, including those in wheelchairs. The height must be adequate to prevent any feeling of confinement or claustrophobia, and it must accommodate the stature of both seated and standing passengers. By analyzing the height, the AI engine determines whether the elevator 340 offers a comfortable and accessible environment for users of all heights.

Another aspect that may be analyzed by the AI engine is the control panel 345 inside the elevator 340. The control panel 345 must be positioned at a suitable height 345A to be accessible to all users, including those seated in wheelchairs. The AI engine checks whether the buttons and controls on the panel 345 are within reach of a user seated in a wheelchair, typically verifying if they are placed between 15 to 48 inches above the floor. This height range is designed to be reachable for most users, allowing them to operate the elevator 340 independently without needing assistance from others.

The AI engine also examines the layout and functionality of the control panel 345. It evaluates whether the buttons are clearly labeled, tactilely distinct, and easily operable by users with limited hand dexterity. The arrangement of the buttons may also be analyzed to determine if they are logically placed and easily distinguishable, reducing the likelihood of errors or confusion when selecting a floor or operating other elevator functions.

In scenarios where the AI engine identifies that the control panel 345 is not at an appropriate height 345A, it may provide automated suggestions to adjust the placement of the panel 345. For example, if the panel 345 is too high for a seated user to reach comfortably, the AI engine may recommend lowering it to within the acceptable range. Additionally, if the buttons on the panel 345 are too small or difficult to press, the AI engine may suggest redesigning the buttons to be larger and more responsive, making them easier to use for individuals with limited hand strength or dexterity.

The AI engine's analysis also extends to the placement and accessibility of emergency features within the elevator 340, such as the alarm button and communication system. These features must be easily reachable by wheelchair users 341 in case of an emergency. The AI engine checks whether these buttons are placed within the accessible height range and whether they are clearly marked and distinguishable from other controls on the panel. If the emergency buttons are found to be out of reach or not easily identifiable, the AI engine may recommend repositioning them to enhance safety and accessibility.

Another aspect of the elevator 340 that the AI engine may analyze is the door threshold 344. The threshold 344 should be level with the elevator floor to allow the wheelchair to roll smoothly in and out without getting caught or requiring additional force to cross. The AI engine examines the height of the threshold 344, determining whether it creates a barrier for wheelchair users 341. If the threshold 344 is too high, the AI engine may suggest lowering it or using a beveled edge to create a smoother transition between the elevator and the floor outside. In addition to the physical dimensions and layout of the elevator 340, the AI engine may also assess the overall user experience within the elevator. This may include factors such as lighting, ventilation, and the clarity of visual and auditory signals.

Furthermore, the AI engine may simulate different user scenarios within the elevator 340 to determine if it can accommodate various situations, such as multiple users with different mobility needs. For example, the AI engine may analyze how a wheelchair user 341 and a standing passenger 342 share the space, so that both have enough room to move comfortably and access the control panel 345. If the space is too cramped, the AI engine may suggest increasing the interior dimensions of the elevator 340 to better accommodate multiple users.

The AI engine also considers the door operation of the elevator 340. It checks whether the doors open and close at an appropriate speed, giving wheelchair users 341 enough time to enter and exit without feeling rushed. The AI engine may recommend adjusting the door timing or adding sensors that detect when a user is approaching, automatically holding the door open until they have safely entered or exited.

In buildings with multiple elevators, the AI engine may also analyze the distribution and location of elevators to determine if wheelchair users 341 have convenient access to all areas of the building. This may include assessing whether the elevators are located near accessible entrances and whether there are enough elevators to meet the needs of all users during peak times. If the AI engine determines that the elevator placement is inadequate, it may suggest adding additional elevators or repositioning existing ones to improve accessibility.

In some embodiments of the present invention, the AI engine may be configured to analyze various turning spaces specifically within the context of elevator accessibility for wheelchair users. When analyzing an elevator system, the AI engine first identifies the key locations where turning spaces are required for wheelchair users. These locations may include, but are not limited to, the approach to the elevator from a hallway or lobby, the space directly in front of the elevator door, the interior of the elevator cabin, and the area immediately beyond the elevator on the destination floor. Each of these turning spaces are ascertained by the AI engine to determine if these spaces allow a wheelchair user to navigate smoothly from one area to another, without encountering physical barriers or constraints that may impede their movement.

Once these locations are identified, the AI engine measures the dimensions of the turning spaces and compares them against the standard requirements for wheelchair accessibility. For instance, the AI engine assesses whether the turning space in front of the elevator door allows for a full 360-degree rotation, typically requiring a clear floor space with a minimum diameter of 60 inches. The AI engine may simulate the movement of a wheelchair within this space to determine if the user can turn and align themselves properly with the elevator entrance, regardless of their approach angle.

Inside the elevator, the AI engine may analyze the available space to determine whether it accommodates the turning radius of a wheelchair. This analysis is used to determine if the user can enter, turn, and exit the elevator without needing to back up or perform complex maneuvers. The AI engine checks if the interior cabin dimensions provide sufficient clearance on all sides, allowing the wheelchair user to face forward or sideways as needed when positioning themselves within the elevator. The AI engine also considers the presence of other passengers and evaluates whether the turning space inside the elevator remains adequate even when the cabin is partially occupied.

Additionally, the AI engine examines the transition between the elevator and the surrounding hallway or lobby areas. It analyzes the turning spaces at the elevator exits on each floor, determining if wheelchair users have enough room to maneuver upon leaving the elevator. This may include verifying that there are no obstacles, such as door thresholds, that may interfere with the smooth passage of the wheelchair. If the turning space is found to be insufficient or obstructed, the AI engine generates automated recommendations to modify the design, such as repositioning walls, widening corridors, or adjusting the placement of doors.

In scenarios where the AI engine detects potential issues with turning spaces, it provides detailed suggestions for improving the design. For example, if the turning space in front of the elevator door is too small, the AI engine may recommend extending the hallway or reconfiguring adjacent areas to create the necessary clearance. Similarly, if the interior cabin of the elevator is too narrow to accommodate a full turn, the AI engine may propose enlarging the cabin or reorienting the control panel and handrails to maximize usable space.

Moreover, the AI engine may also monitor the floor surface within the turning spaces, determining if it is smooth and free of obstructions that may hinder the movement of a wheelchair. The AI engine evaluates whether the flooring material provides adequate traction to prevent slipping while still allowing the wheelchair to move with minimal resistance. If the floor surface is found to be inappropriate, the AI engine may recommend resurfacing the area with a more suitable material.

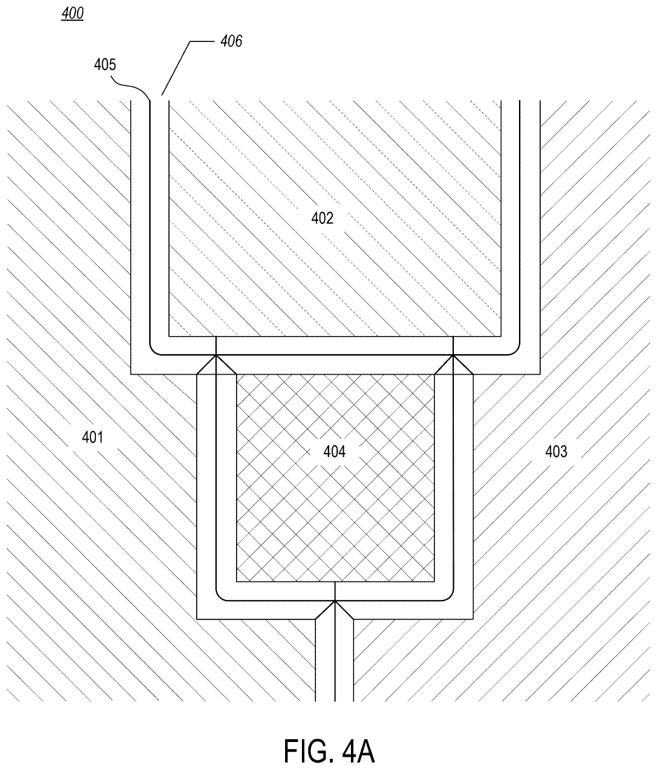

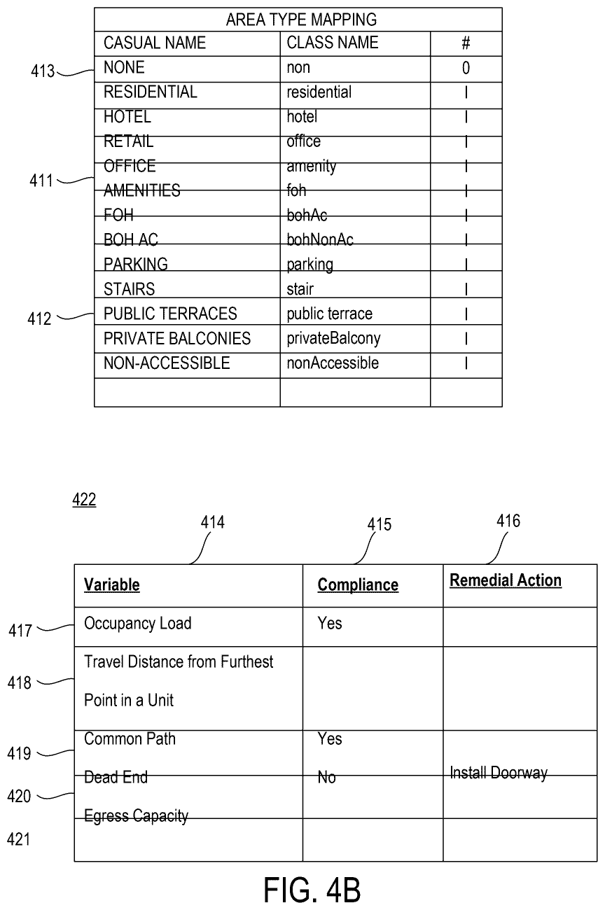

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. Different classes or types of spaces or areas may be scored to be equal to, dominant (e.g., above) others or subservient (e.g., below) others.

Referring now to FIG. 4B, an exemplary table A indicating classes of space types and their associated ranks. In some embodiments, a controller may be operative via execution of software to determine relative ranks associated with a region on one or either side of a boundary. For example, area 402 may represent office space and area 404 may represent a stair well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect compliance with conditions that must be met in order to be compliant with a code, such as, for example, compliance and remedial actions. For example, as illustrated, variables 417-421 may include occupancy load 417, travel distance from a furthest point 418, Common path 419, dead end 420, and egress capacity 421.

### Area Takeoff Classification

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. As mentioned, this can be important to support processes executed by a controller that assigns boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. There may be numerous functionalities and purposes to automatic classification of regions from an input drawing.

An AI engine or other process executed by a controller may be refined, trained, or otherwise instructed to utilize a number of recognized characteristics to accomplish area classification. For example, an AI engine may base predictions for a type “/”category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of recognized text may provide direct evidence upon which to infer a decision. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces may allow a training set to train a relevant AI engine to classify a space with added accuracy. Furthermore, certain space classes may typically fall into ranges of areas which also may aid in the identification of a region's class. Accordingly, it may be important to influence the makeup of training sets for classification that contain common examples of various classes as well as common variations on that theme.

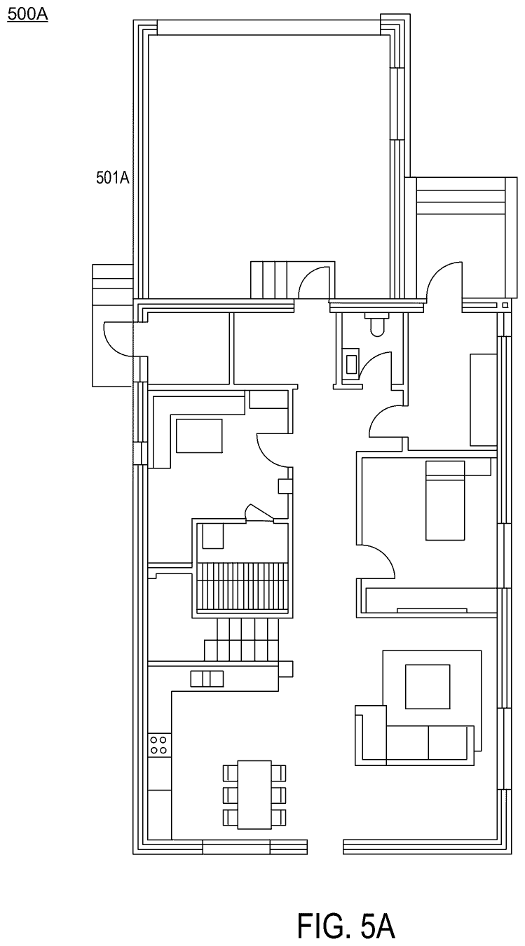

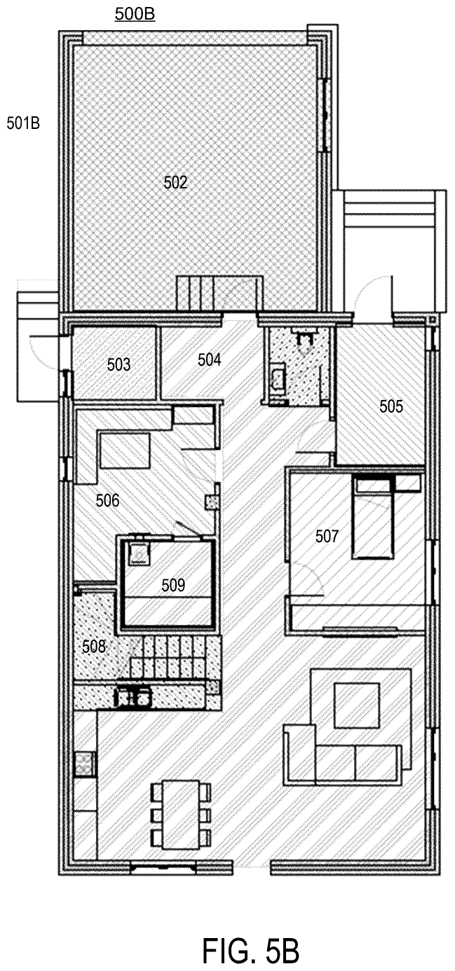

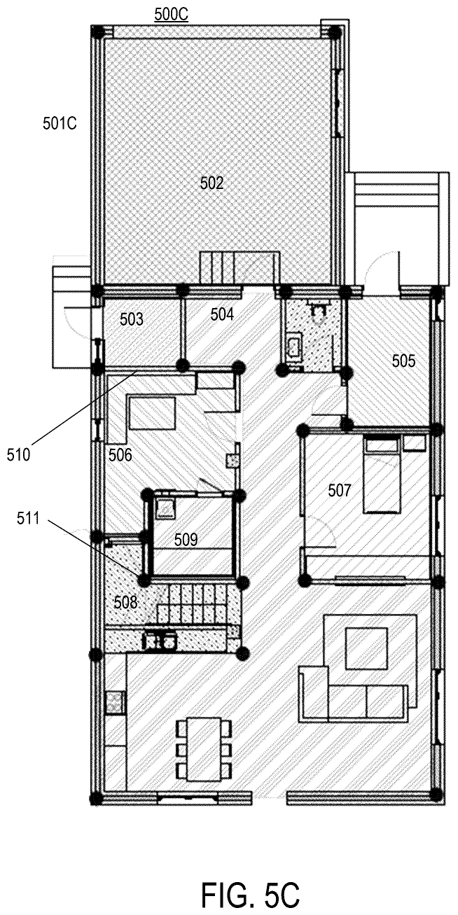

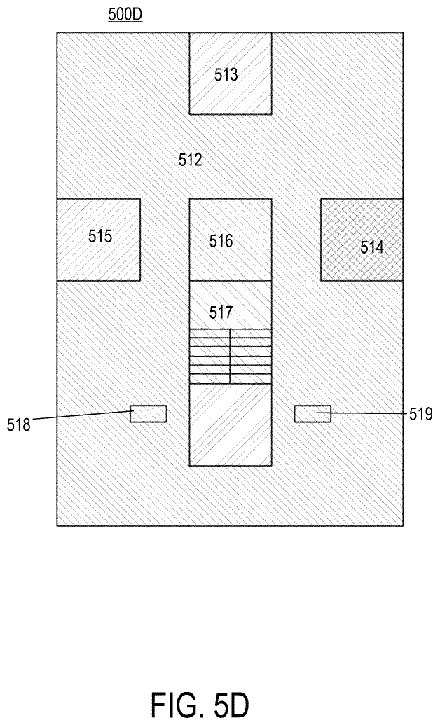

Referring now to FIGS. 5A-5D, a progressive series of outputs that may be included in various user interfaces, are illustrated and may provide examples of a recognition process that may be implemented in some embodiments of the present invention. Referring now to FIG. 5A, a relatively complex drawing of a floorplan may be input as a design plan 501A into a controller running an AI engine. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon to a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of: regions; spaces; patterned portions; line segments; polygons; symbols; icons or other portions of the user interfaces may be assembled and presented in a user output and our user interface, or as input into another automated process.

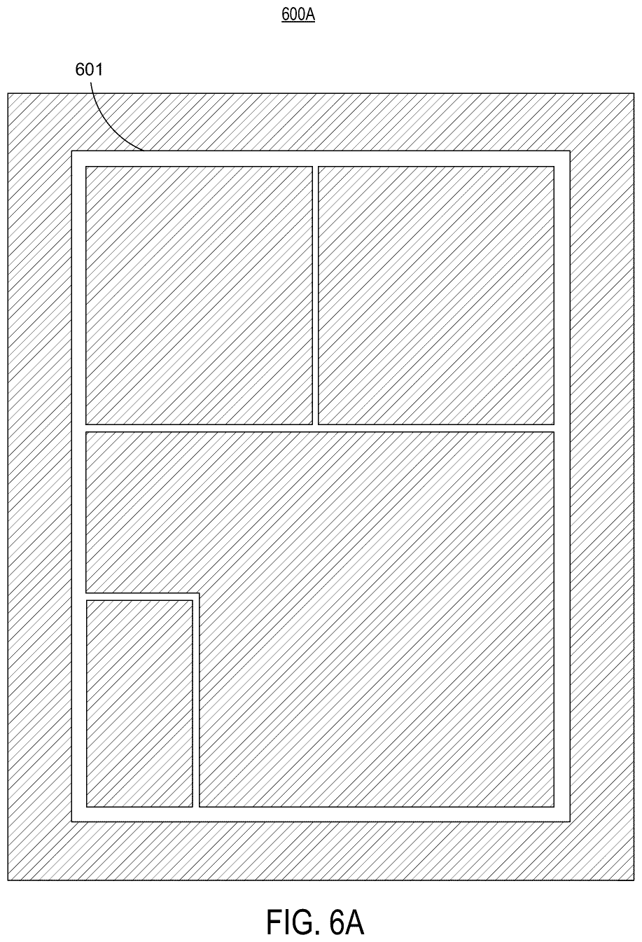

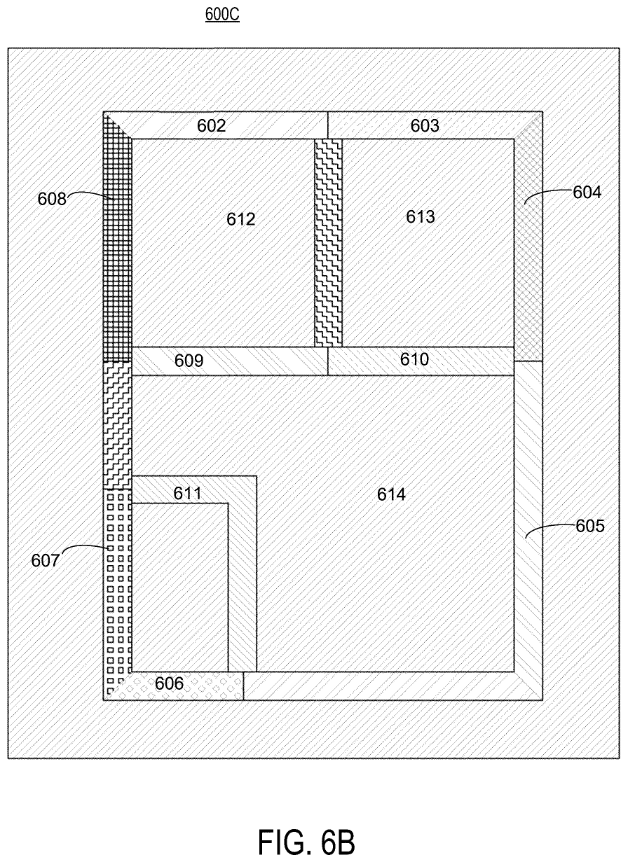

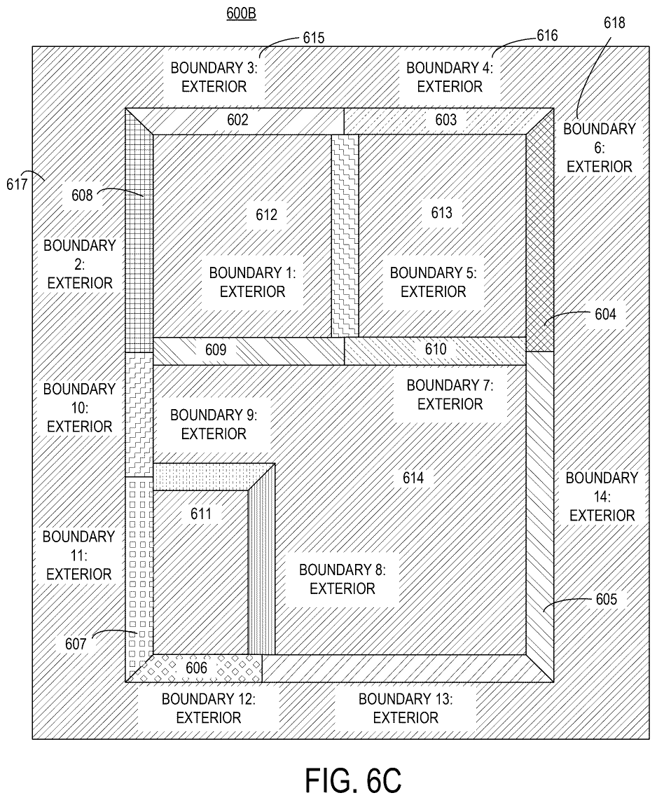

Referring now to FIGS. 6A-6C, in some embodiments, automated and/or user-initiated processes may include refinement of regions, spaces, or areas may involve one or both of a user and a controller identifying individual wall segments 211A from previously defined boundaries.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C.

In some embodiments, functionality may be allocated to classified individual line segments 602-611, such as, by way of non-limiting example, a process that generates an estimated materials list for a region or an area defined by a boundary, based on the regions or area's characteristics and its classification.

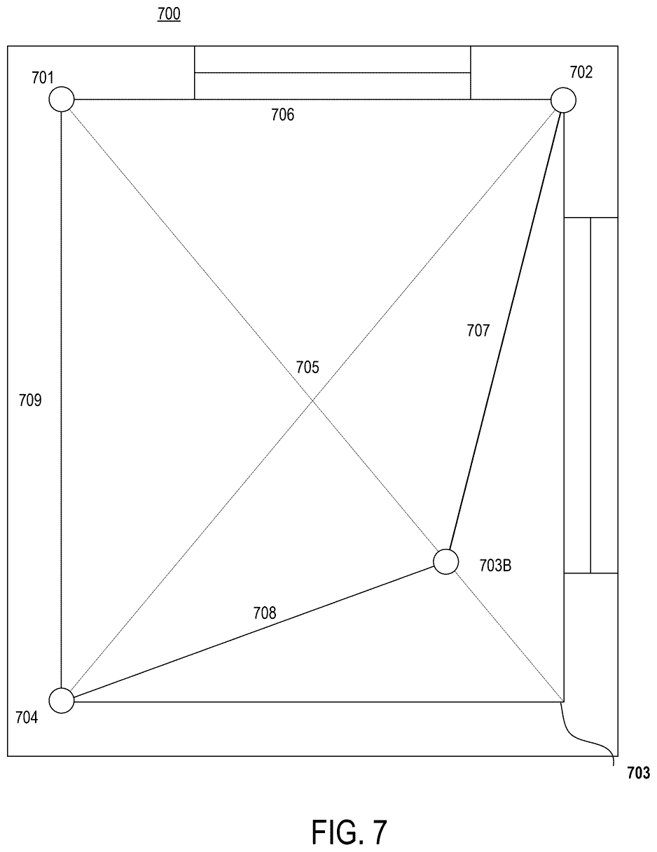

Referring now to FIG. 7, in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments.

For example, a user interface may include one or more vertex 701-704 (e.g., points where two or more line segments meet) that may be user interactive such that a user may position the one or more vertex 701-704 at a user selected position. User positioning may include, for example, user drag and drop the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other items 701-709 in the user interface 700 that may facilitate achievement of a purpose by allowing one or both of: the user, and the controller, to control dynamic sizing and/or placement of a feature or other items 701-709.

Still further, in some embodiments, user interaction involving positioning of a vertex 701-704 or modification of an item 705-709 may be used to train an AI engine to improve performance.

### Model Training Procedures

An important aspect of the operation of the systems as has been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied by a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. Also, a text input or other narrative may be recognized to provide a more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, a user interface or other output display or on reports, different layers may be illustrated at different times along with associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with a set of codes, standards and the like and review the discovered design elements for compliance. In some embodiments, a list of variances or discovered potential issues may be presented to a user on a display or in a report form. In some embodiments, a function may be offered to remove user entered data and other personally identifiable information associated in the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

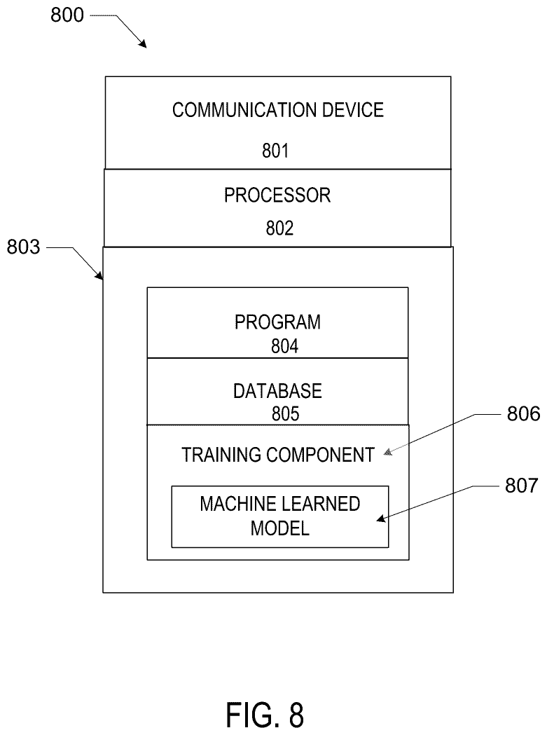

Referring now to FIG. 8, an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

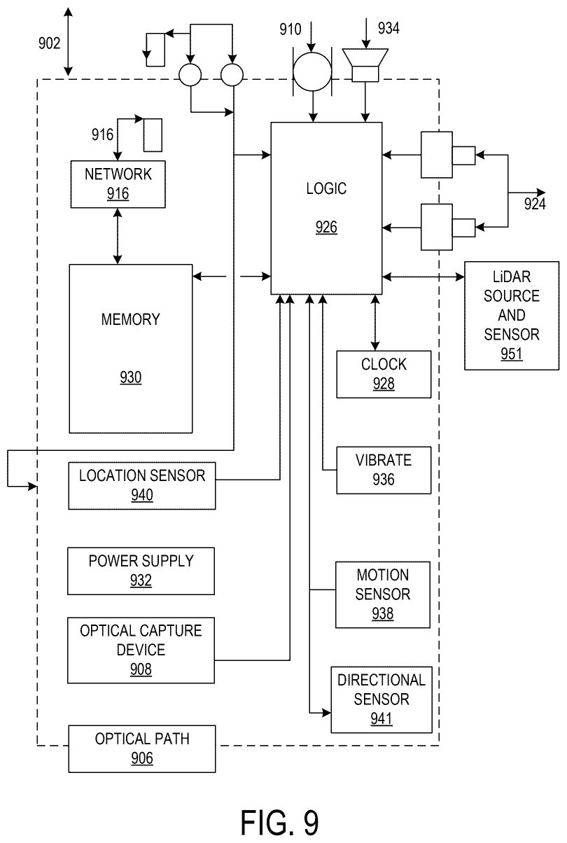

Referring now to FIG. 9, a block diagram of an exemplary mobile device (apparatus) 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record time and strength of returned signal that is reflected off of surfaces in the environment of the mobile device 902. In some embodiments, as have been described herein, a two-dimensional drawing or representation may be used as the input data source, and vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBie. Features in the BIM or CAD datafile may already have defined boundary aspects having innate definitions such as walls and ceilings and the like. An interactive interface may be generated that receives input from a user indicating a user choice of types of innate boundary aspects a user provides instruction to the controller to perform subsequent processing on.

In some embodiments of the present invention, an apparatus is designed to analyze wheelchair turning clearance within a building design to determine compliance with relevant building codes. The apparatus includes a display screen, a digital storage medium, and a controller with a processor. The digital storage medium contains executable software code, which, when executed by the processor, enables the apparatus to perform various functions critical to assessing and enhancing wheelchair accessibility.

The process begins by receiving a design plan of at least a portion of a building into the controller. The design plan may be a detailed architectural drawing, floor plan, or another type of schematic that outlines the spatial layout of the building, including key structural elements and fixtures. The controller then converts the design plan into multiple dynamic components, each representing a structural element or fixture within the building. These dynamic components may include boundaries (such as walls or partitions), paths (such as corridors or doorways), and spaces (such as rooms or open areas). This conversion allows the apparatus to break down the design into manageable parts that can be individually analyzed and manipulated.

Once the dynamic components are generated, the controller creates a first interactive user interface on the display screen. The user interface visualizes at least some of the dynamic components, allowing the user to interact with the design plan in a flexible and intuitive way. For example, a user may modify the layout of a room, adjust the position of a doorway, or change the dimensions of a corridor. Each dynamic component within the user interface includes one or more parameters that can be adjusted by the user, providing a powerful tool for exploring different design configurations and their impact on wheelchair accessibility.

The controller then identifies one or more wheelchair turning points within the design plan. These turning points may be critical areas where a wheelchair user needs to execute a turn, such as at hallway intersections, room entrances, or around corners. The controller calculates the turning radius at each of these points to determine whether there is sufficient space for a wheelchair to maneuver. For example, the apparatus may identify a T-shaped turning space or a circular area with a sixty-inch diameter, both of which are common configurations in accessibility standards.

To further enhance the analysis, the controller is configured to simulate the movement of a virtual wheelchair user through the identified turning points. This simulation provides a realistic assessment of how a wheelchair would navigate the space, taking into account factors like the dimensions and turning radii of different types of wheelchairs, including both manual and powered models. By simulating various scenarios, the apparatus can identify potential usability issues that may not be apparent from a static analysis, such as difficulties in turning around tight corners or maneuvering through narrow corridors.

If the design plan is determined to be non-compliant with the set of conditions related to wheelchair turning clearance, the controller provides suggested modifications within the interactive user interface. These suggestions may include adjusting the layout to increase the available turning radius, repositioning fixtures that encroach on the turning space, or altering the dimensions of corridors to improve accessibility.

In addition to analyzing the turning points, the controller may evaluate surface conditions along identified paths within the design plan, particularly those leading to points of egress. The controller checks for potential hazards in the surface conditions, such as slippery surfaces or excessive slopes, which may impede safe wheelchair movement. If any hazards are detected, the controller flags them and provides recommendations for modifications, such as adding non-slip surfaces or reducing the slope of a ramp, to enhance wheelchair accessibility.

The controller may identify any obstructions within the calculated turning radius of the identified wheelchair turning points. These obstructions may include furniture, fixtures, or structural elements that reduce the available space for turning. The apparatus assesses the impact of these obstructions on wheelchair accessibility and provides recommendations for their removal or repositioning to so that the space meets the necessary compliance standards.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determining classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition, or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

### User Interface With Single and Multiple Layers

In some embodiments, the user may be given access to movement of boundary elements and vertices of boundary elements. In examples where lines or vectors are used to represent boundaries and surrounding area, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a features or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

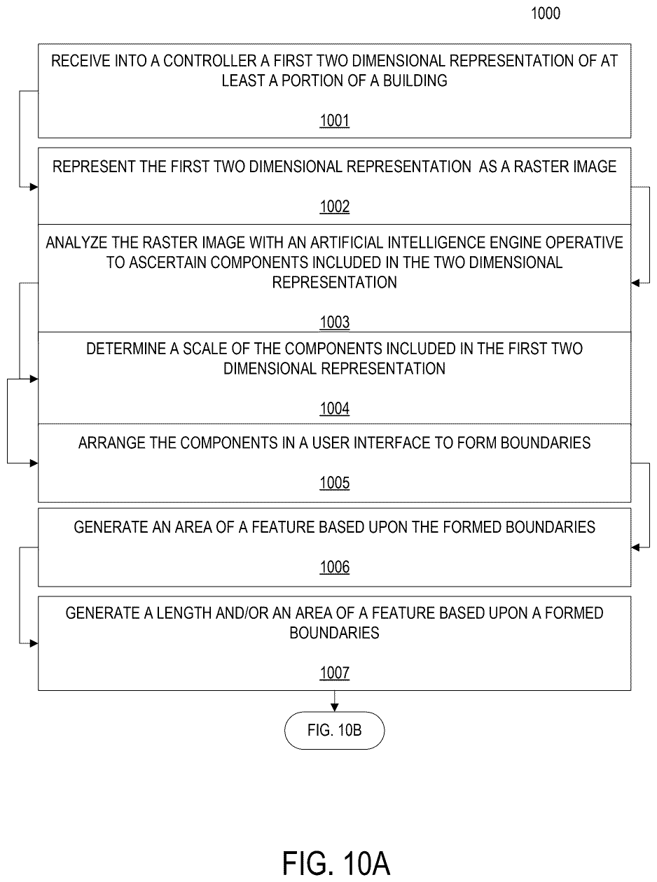

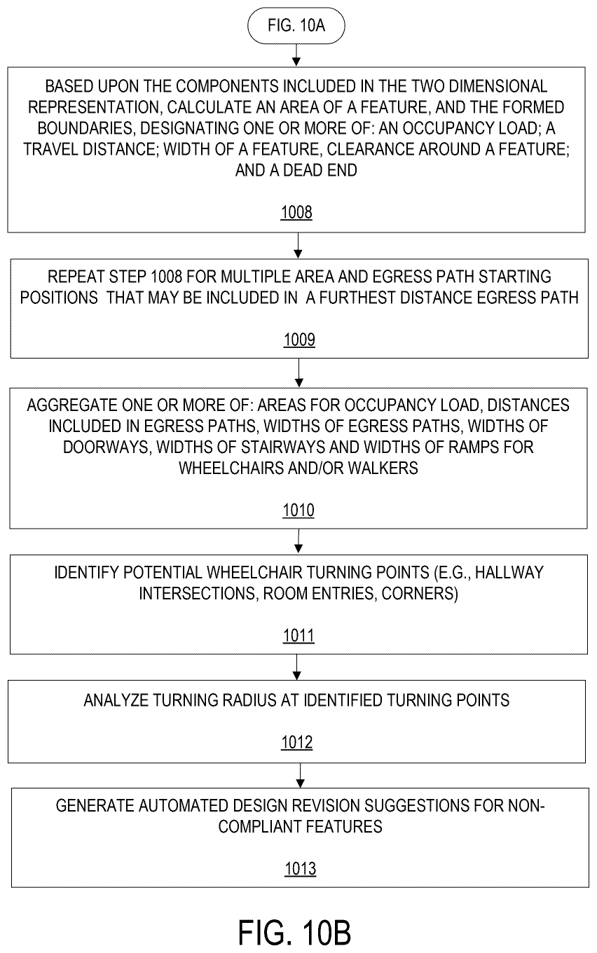

Referring now to FIGS. 10A-10B method steps 1000 are illustrated for quantifying requirements for compliance of a selected code applied to a building based upon artificial intelligence analysis of a design plan according to some embodiments of the present invention. At step 1001, the method includes receiving into a controller a design plan of at least a portion of a building. As described above, the design plan may include an architectural drawing, floor plan, design drawing, and the like.

At step 1002, the portion of a design plan may be represented as a raster image or other image type that is conducive to artificial intelligence analysis, such as, for example, a pixel-based drawing. This conversion into a raster format allows for precise pixel-based analysis, enabling the AI engine to detect minute details and spatial relationships between components in the design plan, which is used by the AI engine for compliance analysis, particularly for wheelchair turning areas.

At step 1003, the raster image may be analyzed with an artificial intelligence engine that is operative on a controller to ascertain components included in the design plan. The AI engine identifies key structural elements, including walls, doors, fixtures, and open spaces, which are critical in determining the feasibility of wheelchair maneuverability within the building's layout.

At step 1004, a scale of components included in the design plan may be determined. The scale may be determined for example, via a scale indicator or ruler included in the design plan, or inclusion in the design plan of a component of a known dimension (e.g., standard door width). Based, on the determined scale, the AI engine can accurately calculate distances and dimensions relevant to wheelchair accessibility, such as corridor widths and turning radii.

At step 1005, a user interface may be generated that includes at least some of the multiple components. The user interface provides a visual representation of the design plan, allowing users to interact with and review the identified components. The interface may include interactive features that highlight areas of interest, such as potential wheelchair turning points.

At step 1006, the components may be arranged in the user interface to form boundaries. These boundaries delineate specific areas within the building, such as rooms, corridors, and open spaces, where compliance with accessibility standards, including wheelchair turning capabilities, needs to be verified.

At step 1007, a length of a feature may be generated based upon a formed boundary. This step may involve calculating the dimensions of identified features, such as the length of a corridor or the diameter of a circular turning area. Accurate dimensioning is required for assessing whether these features meet the required standards for wheelchair accessibility.

At step 1008, based upon one or more of components included in at least one or the user interface and the design plan, at least one of: the area of a feature, space or region may be generated and/or a length of a feature may be generated and one or more of: an occupancy load; a travel distance of an egress path; a dead end; a common path; clearance around a feature such as a plumbing fixture (e.g. ADA specified clearance around a toilet); a width of an egress path including doorways, stairways, elevators, and ramps. This step allows the AI engine to calculate critical spatial parameters that influence wheelchair maneuverability and overall accessibility.

At step 1009, one or more of the above steps may be repeated for multiple areas, units and egress paths of a building being described by the design plan. Repetition of these analyses across different areas of the building allows the entire structure to be analyzed for compliance with accessibility standards, particularly for those requiring wheelchair access.

At step 1010, values of variables specified in a relevant code may be aggregated. The aggregated quantities may include, by way of non-limiting example, one or more of: areas for occupancy, authorized use during occupancy; distances of egress paths; widths of egress paths; widths of doorways; widths of stairways; and widths (and slopes) of ramps suitable for use by a wheelchair and/or walker.

At step 1011, the AI engine identifies potential wheelchair turning points (e.g., hallway intersections, room entries, corners) based on the layout of the design plan. The AI engine may pinpoint specific areas within the building where wheelchair users are likely to need sufficient space to turn around, especially at intersections of hallways, entrances to rooms, and other transitional spaces. For example, an L-shaped hallway may require analysis at the corner to determine that a wheelchair can make a 90-degree turn.

At step 1012, the AI engine analyzes the turning radius at identified turning points. This analysis involves calculating the available space at each identified turning point to determine if it meets or exceeds the required turning radius for wheelchair users, which is typically 60 inches for a 360-degree turn as per ADA standards. For example, in a restroom, the AI engine may verify that there is sufficient space around fixtures like toilets and sinks to allow a wheelchair user to turn without obstruction. If the space is found to be inadequate, the AI engine may flag this as non-compliant and suggest modifications, such as reconfiguring the layout or increasing the space around the fixtures.

At step 1013, the AI engine may recommend design modifications based on the analysis of the turning radii. If the analysis reveals that certain areas do not provide sufficient space for wheelchair maneuverability, the AI engine may suggest specific design changes, such as widening corridors, reconfiguring room layouts, or altering the placement of fixtures to enhance accessibility. For example, if a turning point in a hallway is too narrow, the AI engine may recommend expanding the width of the hallway or relocating nearby furniture to increase the available turning space.

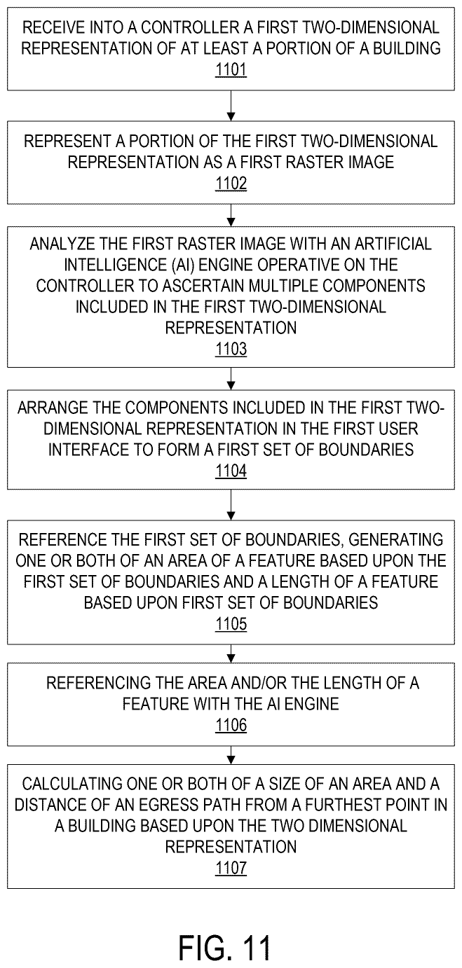

Referring now to FIG. 11, a system including one or more controllers can be configured to perform particular operations or actions by virtue of having executable software, firmware, hardware, or a combination of them that in operation cause the controllers to be operative to perform method steps. In some embodiments, the controller may perform method steps directed to quantifying requirements for construction and accessibility compliance of a building based upon artificial intelligence analysis of design plans.

At step 1101, the method of quantifying whether requirements for compliance with a relevant code are present in a building may include receiving into a controller a first design plan (two-dimensional reference) of at least a portion of a building. The design plan may include architectural drawings, floor plans, or similar documentation that provides a detailed representation of the building's layout.

At step 1102, the method may include representing a portion of the first design plan as a first raster image. Rasterization allows for pixel-level analysis of the design plan, making it possible for the AI engine to process and analyze the layout with high precision.

At step 1103, analyzing the first raster image with an artificial intelligence (AI) engine operative on the controller to ascertain multiple components included in the first design plan. These components may include walls, doors, fixtures, and open spaces. The controller may also generate a first interactive user interface that includes at least some of the multiple components included in the first design plan.

At step 1104, the method arranges the components included in the first design plan in a first interactive user interface that forms a first set of boundaries. These boundaries may delineate specific areas such as rooms, corridors, and other critical spaces within the building where compliance with accessibility standards, such as those for wheelchair turning areas, must be verified.

At step 1105, the method may include generating one or both of an area of a feature based upon the first set of boundaries and a length of a feature based upon first set of boundaries. This step involves calculating the dimensions of identified features, such as the width of a corridor, the diameter of a turning space, or slope of a ramp to determine whether they meet the required standards for accessibility, particularly for wheelchair maneuverability.

At step 1106, the method may include using the AI engine to reference at least one of: the area of the feature and the length of a feature, and analyzing these dimensions against relevant accessibility codes. This may include evaluating whether the space available within the identified boundaries is sufficient for wheelchair users to navigate without obstruction. For example, the AI engine may reference ADA standards to determine if a hallway provides at least 36 inches of clear width and that turning spaces have a minimum diameter of 60 inches.

At step 1107, the controller may calculate an area or distance of an aspect of the building, such as an area of a unit and/or a distance of an egress path. This step may also include calculating the distance from any given point within the building to the nearest egress, determining if wheelchair users can quickly and safely exit the building in an emergency. The AI engine can simulate various evacuation scenarios to assess the effectiveness of these egress paths, identifying potential bottlenecks or obstructions that may impede wheelchair movement.

In some embodiments, following step 1107, the AI engine may additionally analyze and simulate the turning radius at critical points within the building, such as hallway intersections or room entrances. If the turning radius at these points is insufficient for a wheelchair to maneuver comfortably, the AI engine can suggest modifications to the layout, such as widening corridors or repositioning fixtures.

Any or all of steps 1101-1107 may be repeated for different portions of the two-dimensional reference descriptive of the building, determining comprehensive coverage of the entire building's layout. The iterative process allows the AI engine to continuously refine its analysis and provide up-to-date recommendations as the design evolves. For example, if a new room is to added, or a corridor is expanded, the AI engine will automatically reassess the turning radii and egress paths, determining if the entire building remains compliant with accessibility standards.

A scale of one or more components may be determined and a parameter of one or both of a polygon and a line segment may be modified based upon receipt of an instruction for a user; and a boundary may be set based upon reference to a boundary allocation hierarchy.

The steps may be performed multiple times and may include two or more two dimensional references with results of the process be compared one against the other to ascertain when a change has been made to a two-dimensional reference that places a building in compliance with a selected code. In various embodiments, a change in subsequent two-dimensional references may be used to generate a change in one or more of a take-off, labor costs, project management input, or other aspects that may impact construction of a building and/or associated costs.

Implementations may include one or more of the following features. The method additionally determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the interactive user interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via an interactive user interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in construction of the building. In addition, a type of labor associated with at least one of the items to be included in construction of the building may be designated based upon AI analysis of the first two-dimensional reference and the second two-dimensional reference, respectively.

Methods of practice may additionally include the steps of: determining whether a design plan received into the controller includes a vector image, and if one of the first and the second design plan received into the controller includes a vector image converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of: a size and shape of at least one of the dynamic components. At least one of the dynamic components may include a polygon and the method further includes the steps of: receiving an instruction via the interactive user interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit, or other defined space. A change in area of a unit may allow for a recalculation that results in a modification of one or more of: an occupancy load; a length of a path of egress; an length and/or area of a common path; a width of a stair; a travel distance to traverse a dead end; an existence of a dead end; or other variable referenced in determination of compliance with a set of conditions, such as a code relevant to a geopolitical locality and a building.

A dynamic component may include a line segment and/or vector, and the method may further include the steps of: receiving an instruction via the interactive user interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor.

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

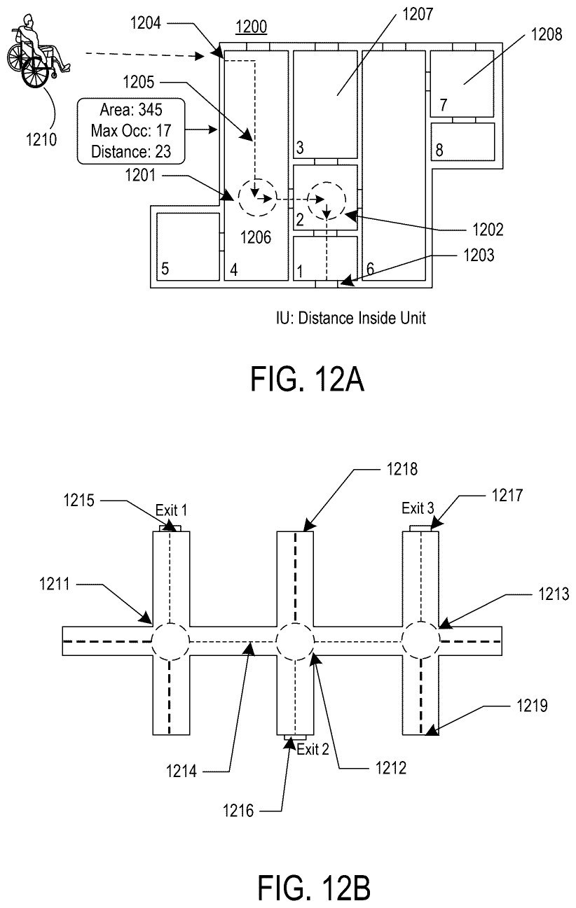

Referring now to FIG. 12A, an exemplary design plan 1200, showcasing a path of egress 1205 that extends from a furthest point 1204 (within a building space 1206) in a building to a designated point of egress 1203, is illustrated. The path of egress 1205 is a critical component in the design of accessible buildings, as it outlines the route that occupants, including wheelchair users 1210, may take to evacuate the building in the event of an emergency. The AI engine analyzes the path of egress 1205 with a particular focus on the multiple wheelchair turning areas 1201-1202 located along the route, determining if the wheelchair turning areas 1201-1202 are compliant with accessibility standards and are adequate to facilitate a safe and efficient evacuation.

The wheelchair turning areas 1201-1202 depicted in the design plan 1200 are integral to the overall safety of the egress route. The wheelchair turning areas 1201-1202 allow wheelchair users 1210 to change direction, navigate around corners, and reorient themselves as they move toward the point of egress 1203. The AI engine evaluates whether the wheelchair turning areas 1201-1202 are large enough to accommodate the turning radius of various wheelchair models, including manual and power wheelchairs. Typically, a turning area needs to have a minimum diameter of 60 inches to allow for a full 360-degree turn, but larger spaces may be required in corridors or pathways that see higher traffic or involve more complex navigational challenges.

The effectiveness of the wheelchair turning areas 1201-1202 is directly linked to the ability of wheelchair users 1210 to evacuate the building quickly and safely during an emergency. If the turning areas are too small or poorly positioned, they may impede the user's ability to turn efficiently, leading to delays and potentially dangerous situations, especially in high-stress scenarios such as fires. The AI engine may simulate the movement of wheelchair users1210 through the wheelchair turning areas 1201-1202, identifying any potential bottlenecks or obstacles that may hinder the evacuation process. It then assesses whether these areas are adequate or if improvements are necessary to provide wheelchair users 1210 ability to navigate the path of egress 1205 without undue difficulty.

The AI engine's analysis also extends to evaluating various other paths that lead to the point of egress 1203 from other parts of the building, such as spaces 1207-1208. Each of these paths are analyzed for determining how quickly and safely all occupants, including those using wheelchairs, can exit the building. The AI engine examines the layout of these paths, identifying where additional wheelchair turning areas may be required, and determining if these areas are properly sized and positioned to facilitate smooth and continuous movement toward the point of egress.

One aspect that the AI engine analyzes may be the number of turning areas along the longest path of egress 1205. While turning areas are necessary for navigation, too many turns can increase the time it takes for wheelchair users 1210 to reach the point of egress 1203, particularly in an emergency. The AI engine evaluates whether the number of turning areas is excessive, potentially slowing down the evacuation process. The AI engine also considers whether the path can be reconfigured to reduce the number of turns, thereby shortening the egress time without compromising the safety and accessibility of the route.

In addition to assessing the number of turning areas, the AI engine may examine the quality and usability of these spaces. Issues that the AI engine may identify include inadequate turning radius, poor surface conditions, obstructions within the turning areas, or too many turning areas in a single path that could make it difficult for wheelchair users to navigate safely. For example, a turning area that is too narrow or cluttered with furniture or other objects may prevent the wheelchair user 1210 from completing a turn, forcing them to backtrack or attempt to maneuver in a confined space, which may be dangerous during an evacuation.

To address these issues, the AI engine may provide automated recommendations to bring the design plan 1200 into compliance with relevant building codes. If the turning areas 1201-1202 are too small, the AI engine may suggest expanding these spaces by widening the corridor or adjusting the layout of the walls to create more room. It may also recommend relocating certain turning areas to more advantageous positions where they can better serve the needs of wheelchair users without disrupting the flow of the egress route.

The AI engine may also suggest improving the surface conditions within the turning areas, such as providing the flooring to be smooth and slip-resistant to facilitate easy movement of the wheelchair. In cases where lighting is inadequate, the AI engine may recommend adding or repositioning light fixtures so that all turning areas are well-illuminated, reducing the risk of accidents during an evacuation. Additionally, the AI engine may propose installing visual or tactile indicators that guide wheelchair users toward the point of egress, particularly in complex layouts where navigation may be challenging.

For the longest path of egress 1205, the AI engine may determine that the current design involves too many turning areas, leading to an extended evacuation time. In such cases, the AI engine may suggest reconfiguring the path to minimize the number of turns, such as by straightening certain corridors or repositioning doorways to create a more direct route to the point of egress 1203. The AI engine may suggest reducing the number of turning areas if there are excessive turning points along a single path of egress, regardless of whether it is the longest path. This not only enhances the speed of evacuation but also simplifies the navigation process for wheelchair users 1210, making the building safer and more accessible.

In scenarios where the building design includes multiple egress routes from different areas (e.g., 1207-1208), the AI engine can compare these routes to determine which provides the quickest and safest exit for wheelchair users 1210. For example, the AI engine may identify that a particular path offers fewer turning areas and a more direct line to the point of egress 1203, making it the preferred route during an emergency. The AI engine may then recommend designating this route as the primary egress path for wheelchair users 1210, with appropriate signage and guidance systems to direct them accordingly.

Moreover, the AI engine's analysis includes assessing the connectivity between different building spaces (1206-1208) and the paths of egress. For example, the AI engine evaluates whether all rooms and areas within the building, such as spaces 1207-1208, have easy access to a respective path of egress. If the AI engine identifies any isolated areas that lack a clear and accessible route to the egress path, it may suggest modifications to the building layout, such as adding additional doors or corridors, so all occupants can reach the point of egress 1203 quickly.

The AI engine also considers the overall design of the building in relation to fire safety and evacuation planning. It may analyze whether a path of egress is adequately protected against fire hazards, such as by providing walls and doors along the route to be fire-rated and that there are sufficient fire alarms and sprinklers in place. The AI engine may also assess whether the egress path is clear of potential hazards, such as flammable materials or electrical equipment, that may pose additional risks during an evacuation.

Furthermore, the AI engine evaluates the accessibility of the point of egress 1203 itself. It checks whether the doorway at the point of egress 1203 is wide enough to accommodate wheelchair users and whether the threshold is level with the floor to prevent any tripping hazards. The AI engine may recommend adjustments to the door size, the installation of automatic door openers, or the leveling of the threshold to improve accessibility and safety.

In buildings with multiple floors, the AI engine also analyzes how wheelchair users can transition from one floor to another during an evacuation. This may include assessing the accessibility of elevators and ramps that connect to the paths of egress. The AI engine may assess if these vertical transportation options are located along the egress route and are properly equipped to function during an emergency, providing wheelchair users with a reliable means of evacuation.

In some embodiments, the AI engine may predict and simulate potential congestion in turning areas during an emergency. By modeling the movement of all building occupants, not just wheelchair users, the AI engine can identify areas where congestion may occur, particularly in high-traffic intersections or narrow corridors. The AI engine may then recommend solutions to alleviate this congestion, such as by widening corridors, adding additional egress paths, or staggering evacuation times to reduce the number of people moving through the space simultaneously.

The AI engine may be equipped with advanced predictive capabilities that allow it to proactively analyze and forecast potential compliance issues related to wheelchair turning areas and egress paths. The predictive analysis may particularly be useful in dynamic environments where building layouts may change over time, or where occupant behavior varies, influencing the usability and safety of paths and turning areas.

The AI engine's predictive capabilities may include forecasting how effectively the path of egress 1205 will serve wheelchair users 1210 during an emergency evacuation. The AI engine does not only analyze the current state of the egress path 1205 but may also predict how factors such as increased building occupancy, changes in layout, or new construction within the building may impact the efficiency of this path in the future.

For example, the AI engine may predict that the current path of egress 1205, which includes multiple wheelchair turning areas 1201 and 1202, may become less efficient if the building undergoes expansion, leading to increased traffic along this route. The AI engine may simulate scenarios where additional occupants are present, forecasting potential bottlenecks or congestion points, particularly in the turning areas where space is limited. By simulating these scenarios, the AI engine identifies areas where the path may need to be widened or re-routed to maintain efficient and safe egress for wheelchair users. In some embodiments, the AI engine may determine the exact count of wheelchair users that a building plan can accommodate safely during emergency evacuations, considering the analysis of design plan including various turning points, paths of egress, and length of egress paths.

Referring now to FIG. 12B, an exemplary diagram showcasing a plurality of intersecting paths 1214 within a design plan is illustrated. The intersecting paths 1214 form the network of corridors or walkways within a building, leading to various exits or potentially to dead ends. The AI engine may be configured to analyze these intersecting paths 1214 to assess their overall functionality, especially in the context of emergency egress routes and accessibility for wheelchair users.

The AI engine starts by mapping out the entire network of paths within the building, identifying each intersection point where multiple paths converge, such as intersections 1211, 1212, and 1213. These intersections are critical junctures where users make decisions about which direction to take, particularly in an emergency situation where speed and clarity are paramount. The AI engine evaluates whether these intersections are designed to facilitate easy navigation for all users, including those in wheelchairs.

The AI engine then assesses the paths that lead from these intersections to various points of egress, such as Exit 1 (1215), Exit 2 (1216), and Exit 3 (1217). These exits represent the designated safe zones where occupants, including wheelchair users, can leave the building during an emergency. The AI engine analyzes the distance, direction, and accessibility of each path leading to these exits, determining whether the layout provides a clear, direct, and unobstructed route for wheelchair users. The Ai engine may also assess whether the width of these paths is sufficient to accommodate wheelchair users, particularly in high-traffic scenarios where multiple people may be evacuating simultaneously.

In contrast to the paths leading to points of egress, the AI engine also identifies and evaluates paths that lead to dead ends, such as 1218-1219. Dead ends in a building's layout can pose significant risks during an emergency evacuation, as they can trap occupants who are unable to proceed further or turn around quickly. The AI engine analyzes these dead-end paths to assess the potential impact on wheelchair users, who may find it particularly challenging to reverse direction in a confined space. The AI engine considers whether these dead ends are appropriately marked with signage and whether alternative egress routes are clearly indicated to prevent confusion so that all occupants are guided towards safe exits (1215-1217).

The AI engine may also analyze the wheelchair turning areas 1211, 1212, and 1213 located at the intersections. The wheelchair turning areas 1211-1213 allow wheelchair users to navigate the intersecting paths effectively, especially when making sharp turns or when choosing a different direction to reach an exit. The AI engine may measure the dimensions of the turning areas1211-1213 to determine if they provide sufficient space for a full 360-degree turn, which is required for wheelchair users to change direction without having to back up or perform complex maneuvers.

The AI engine also evaluates the placement and design of these turning areas in relation to the intersecting paths. For example, if a turning area is too close to a wall or other obstacle, it may restrict the wheelchair user's ability to maneuver comfortably, leading to delays or difficulties during an evacuation. The AI engine simulates various scenarios to determine whether the current design facilitates smooth navigation through the intersections, or whether adjustments are needed to improve accessibility and safety.

The AI engine may perform a comprehensive assessment of the overall evacuation strategy for the building. This may involve simulating different emergency scenarios, such as a fire or an earthquake, to evaluate how effectively the intersecting paths and turning areas facilitate a safe and efficient evacuation for all occupants. The AI engine takes into account the possibility of congestion at key intersections and turning areas, particularly during peak occupancy times (the AI engine may determine occupancy load of the building for such analyses). It may suggest staggering evacuation routes or implementing a phased evacuation plan to reduce congestion and provide wheelchair users with ample space to navigate the paths.

Another aspect of the AI engine's analysis may be the evaluation of the building's compliance with relevant fire and safety codes. The AI engine may check whether the intersecting paths and turning areas meet the minimum requirements for fire-rated construction, so that these spaces provide sufficient protection against fire and smoke during an evacuation. It also assesses whether the paths are equipped with appropriate fire detection and suppression systems, such as smoke alarms and sprinklers, to enhance the safety of the evacuation routes.

In addition to fire safety, the AI engine may also analyze the accessibility of the building's paths and turning areas for other types of mobility aids, such as scooters or walkers. As the building's layout evolves or as new occupants with different mobility needs move in, the AI engine can re-evaluate the design to determine if it remains compliant with accessibility standards.

In some embodiments, the AI engine uses its predictive capabilities to anticipate how these intersecting paths and associated turning areas 1211, 1212, and 1213 will perform under different conditions over time. The AI engine considers factors such as potential changes in the building's usage patterns, modifications in interior layouts, and even seasonal variations in occupant behavior that may affect the flow of traffic through these intersections.

For example, the AI engine may predict that the intersection at turning area 1211 will become a pinch point during peak occupancy hours or in the event of an emergency, especially if future renovations reduce the width of the adjoining corridors. To mitigate this predicted issue, the AI engine may recommend preemptive design adjustments, such as increasing the diameter of the turning area or reconfiguring adjacent spaces to allow for smoother flow and easier navigation for wheelchair users.

The AI engine may also leverage its predictive capabilities to manage risks associated with dead ends and egress points. The AI engine forecasts the likelihood of wheelchair users encountering dead ends like those shown at points 1218 and 1219 in FIG. 12B. It predicts how these dead ends may impact evacuation times and whether they could cause confusion or delays during an emergency.

Based on these predictions, the AI engine may provide recommendations for risk mitigation, such as installing clear signage that directs occupants away from dead ends or suggesting alternative egress paths that are less prone to congestion. The AI engine may also recommend converting a dead-end corridor into an additional exit point, thus enhancing the overall safety and accessibility of the building.

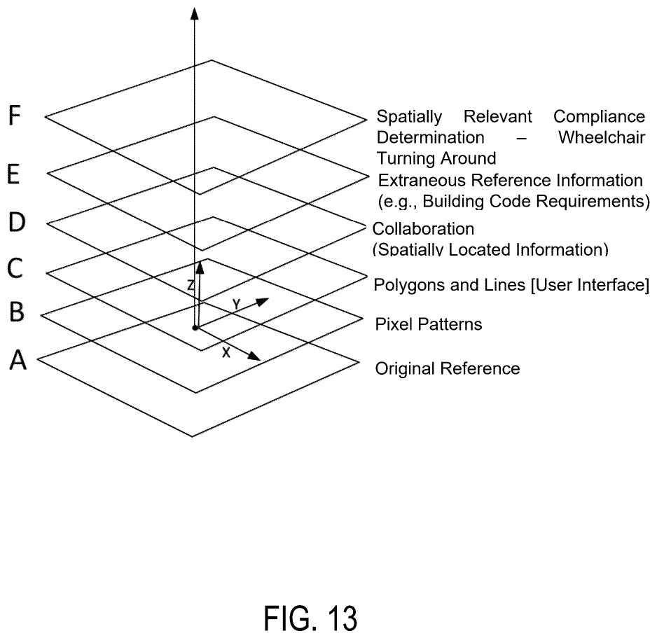

Referring now to FIG. 13, a schematic diagram represents a multi-layered conceptual framework of an AI-powered system specifically designed for the compliance analysis of wheelchair turning areas in architectural design plans. The framework is organized into six distinct levels, labeled A through F, each corresponding to a different stage or component of the system's operation. This layered approach enables the AI engine to progressively transform static design inputs into dynamic, interactive, and compliant spatial models, ultimately leading to a comprehensive compliance determination for wheelchair turning areas.

At Level A, the system begins with the intake of an original two-dimensional reference, which typically includes architectural drawings or floor plans. These original references may be in various formats such as PDF, CAD files, or scanned images. The AI engine ingests these static design plans as the initial data entry point, where the transformation from static information to a dynamic, interactive model begins. Here, the AI engine starts by identifying the basic discernable components of the design, such as walls, corridors, rooms, and fixtures. In the context of wheelchair turning area compliance, this level is where the system recognizes potential turning points and pathways that require further analysis.

Progressing to Level B, the original reference is converted into pixel patterns, forming the foundational data structure for the AI engine's analytical processes. Each pixel in the design plan is treated as a data point that contributes to the overall pattern recognition. The AI engine utilizes these patterns to detect and distinguish between various design elements, such as the outline of rooms, the location of doors, or the placement of obstacles like furniture or fixtures. In the context of wheelchair turning areas, this level is critical for identifying potential turning radii and the spatial layout that may impact maneuverability. For example, the AI engine may recognize that a corridor narrows at a specific turning point, which may affect the ability of a wheelchair user to turn smoothly.

At Level C, the pixel patterns identified in Level B are further processed into dynamic elements (or discernible components) within the user interface. This layer involves converting raw pixel data into interactive components such as polygons, vectors, and lines that delineate various design elements and boundaries within the user interface. These dynamic components allow users to interact with the design plan by adjusting and manipulating elements as needed. For example, a corridor identified in Level B as too narrow for a compliant turning area may now be represented as a manipulatable line, allowing users to test different configurations and adjustments. The AI engine provides feedback on whether these changes improve compliance with wheelchair turning area requirements.

Moving to Level D, the system introduces a collaborative platform where multiple users, such as architects, engineers, and compliance officers, can interact with the design plan in real-time. This level allows for simultaneous contributions, modifications, and annotations by different stakeholders. For example, an architect may suggest widening a corridor to improve turning space, which an engineer can then assess for structural feasibility, while a compliance officer evaluates the change against accessibility standards. The collaborative nature of this platform may particularly be valuable in large-scale projects, where real-time communication and coordination are required so that all aspects of the design meet the required standards. The AI engine tracks these changes and updates the compliance status dynamically, so that all participants are working with the most current version of the plan.

At Level E, the system expands its functionality by integrating various standards and compliance protocols related to wheelchair turning areas. The AI engine cross-references the spatial data generated in the previous levels with a database of relevant building codes, safety regulations, and accessibility standards. This level is where the AI engine applies these standards to determine whether the design plan complies with requirements such as minimum turning radius, path width, and obstacle clearance. The AI engine may check, for example, whether the turning space within a corridor meets the required 60-inch diameter for a full 360-degree turn, or if any furniture placement within the turning area obstructs the required clearance. This level also allows the AI engine to manage multiple sets of compliance standards, so that the design plan meets the specific requirements of the jurisdiction in which the building is located.

Finally, at Level F, the system reaches the culmination of the process, where a spatially relevant compliance determination is made. Based on the analyses performed in the previous levels, the AI engine generates a comprehensive assessment of the design plan's compliance status. This final level provides a detailed report outlining areas of compliance, non-compliance, and suggested improvements. For example, the AI engine may identify that a particular turning area does not meet ADA standards due to insufficient space around a corner, and recommend adjusting the layout to increase the available turning radius. Additionally, this level allows users to visualize the compliance status within the design plan, highlighting compliant areas in one color and non-compliant areas in another. This visual feedback helps users quickly identify problem areas and understand the spatial context of compliance issues.

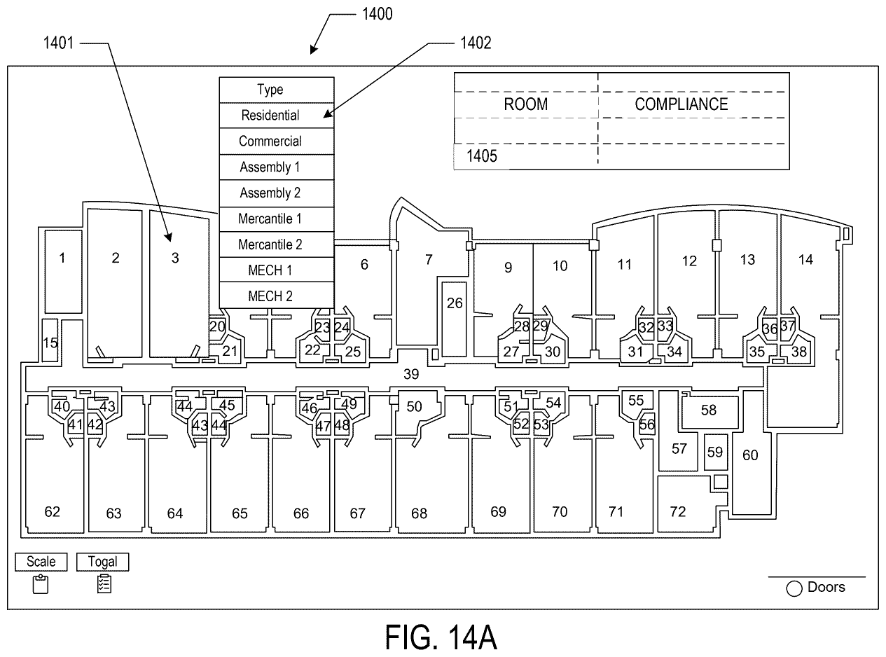

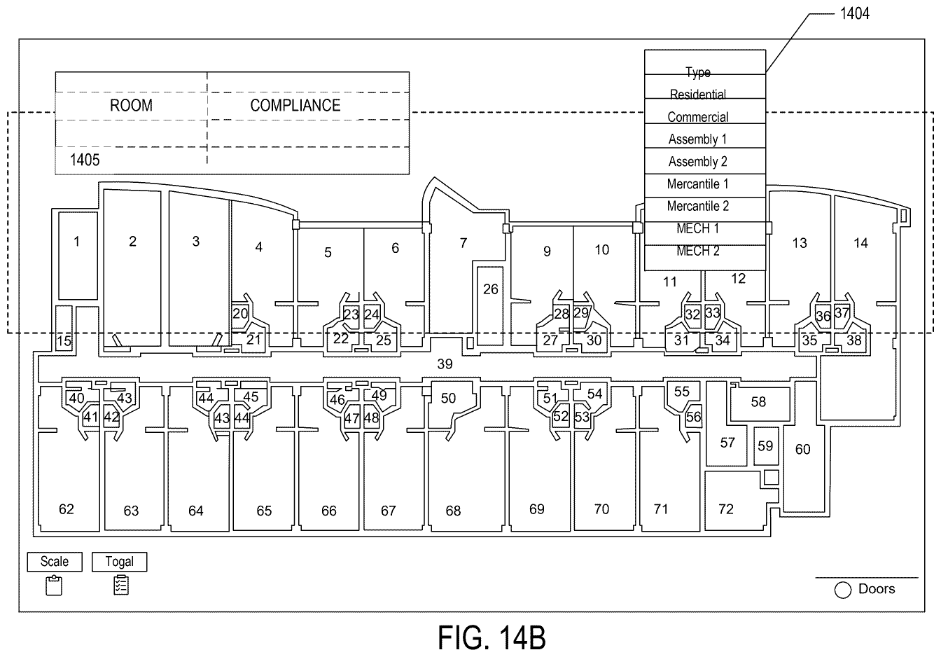

Referring now to FIG. 14A, an example of how an AI engine classifies and analyzes various spaces within a design plan, specifically focusing on compliance analyses related to wheelchair turning areas is illustrated. The AI engine processes the inputted design plan, which may include architectural layouts, floor plans, or other building schematics, and extracts critical elements such as room spaces, corridors, walls, doors, and key fixtures. These elements are then modeled to create a space model that is visually represented on an interactive user interface 1400. This space model allows users to interact with the design and assess it from a compliance perspective, focusing on the adequacy of wheelchair turning areas and overall accessibility.

In some embodiments, individual spaces 1401 within the design plan are color-coded to reflect their compliance status with respect to wheelchair accessibility standards, particularly focusing on the sufficiency of turning areas. For example, compliant areas are displayed in green, indicating that these spaces meet all relevant accessibility standards, including adequate turning radii for wheelchairs. Non-compliant areas, on the other hand, are highlighted in red, drawing immediate attention to spaces that require further review or modification to accommodate wheelchair users effectively. This color-coding system provides a quick visual reference, enabling users to easily identify areas that need to be addressed to provide accessibility.

The AI engine may automatically identify and assign space types to each area based on the elements and layout detected in the design. For example, the AI engine may recognize a narrow corridor with inadequate width or turning radius as a non-compliant space, thus highlighting it in red. The space types can be visualized using different colors or patterns, as shown in the drop-down menu 1402, which allows users to manually adjust or confirm the space types assigned by the AI engine. The drop-down menu 1402 provides a selection of different space types such as “Residential,” “Commercial,” “Assembly,” “Mercantile,” and “Mechanical,” each represented by a specific color or symbol for easy identification and compliance verification.

In the scenario depicted, non-compliant areas 1401 are highlighted in red, signaling that these spaces do not meet the required accessibility standards for wheelchair users, specifically in terms of turning area sufficiency. For example, a red area may indicate a corridor where the width is insufficient to allow a wheelchair to make a required 90-degree turn, or it may highlight a restroom where the turning radius around fixtures like toilets and sinks is inadequate. The AI engine flags these areas to prompt users to take corrective action, either by revising the design directly within the interface or by consulting with experts to make necessary adjustments to provide compliance.

Additionally, the interactive user interface 1400 allows users to drill down into the details of each space. By clicking on a red-highlighted area, the user can view specific information about the nature of the non-compliance, such as the exact measurements that are out of specification or the specific accessibility code requirements that are not being met. This feature empowers users to make informed decisions about how to revise the design to bring it into compliance with accessibility standards. The system is designed to be flexible and user-friendly, enabling both automatic and manual classification of spaces. For example, if the AI engine misclassifies a space, or if the user wants to override the AI's decision, the drop-down menu 1402 allows for easy reassignment of space types to reflect the accurate compliance status.

The AI engine's analysis also considers the interaction between different spaces within the design plan. For example, AI engine may assess whether the paths leading from one area to another, such as from a corridor into a room, provide adequate space for wheelchair users to turn and navigate without encountering obstacles. If the AI engine identifies that a turning area is too constrained by nearby furniture or structural elements, it will highlight the area in red and provide recommendations on how to rearrange the space or adjust the layout to improve accessibility.

Moreover, the AI engine can simulate different scenarios within the design plan, predicting how wheelchair users would navigate the spaces during normal use and in emergency situations. This predictive capability allows the AI engine to identify potential bottlenecks or problematic areas that may not be immediately apparent in the static design. For example, it may forecast that a corridor becomes too narrow when multiple wheelchair users are present, or that an emergency exit route is obstructed by a non-compliant turning area. Based on these simulations, the AI engine can suggest modifications to the design to mitigate these issues, so that the final layout is both accessible and safe for all users.

The AI engine's analysis is also adaptive, meaning that it can continuously update its assessments as the design evolves. If a user makes changes to the layout, such as widening a corridor or relocating a door, the AI engine will re-analyze the affected areas and update the compliance status in real-time. Furthermore, the AI engine may integrate with other compliance tools and databases to cross-reference the design plan with relevant accessibility codes and standards. This integration allows the AI engine to provide detailed compliance reports that outline not only the areas that are non-compliant but also the specific code violations and the actions needed to address them. These reports can be generated in various formats, making them suitable for submission to regulatory bodies or for internal review by the design team.

In cases where the design plan includes specialized spaces, such as assembly areas or mechanical rooms, the AI engine applies additional layers of analysis to determine if these spaces meet the unique accessibility requirements associated with their use. For example, in an assembly area, the AI engine may check that there is sufficient space for wheelchair seating and that the paths to and from the seating area are accessible. In mechanical rooms, the AI engine determines if there is adequate clearance around equipment for wheelchair users who may need to access these areas for maintenance purposes.

The AI engine also supports collaborative workflows, allowing multiple stakeholders to interact with the design plan simultaneously. This feature may particularly be useful in large projects where architects, engineers, accessibility consultants, and other professionals need to work together to determine if the design plan meets all relevant standards. The collaborative platform tracks changes made by different users and updates the compliance status in real-time, so that everyone is working with the most current version of the design.

Referring now to FIG. 14B, an example of how an AI engine, working in conjunction with user input, can designate and analyze multiple spaces within a design plan for wheelchair turning around compliance. The AI engine provides a powerful tool for assessing large areas or multiple spaces simultaneously, determining if the entire building design adheres to relevant accessibility standards, particularly those related to wheelchair maneuverability.

In some embodiments, a regional boundary 1403 may be created around one or more identified spaces within the design plan. The boundary 1403 can be drawn manually by the user or automatically generated by the AI engine based on predefined criteria or identified patterns in the design. For example, the AI engine may automatically group together all areas where wheelchair turning is likely to be required, such as intersections of corridors, restrooms, and other transition spaces on a particular floor or within a specific section of the building. The creation of this regional boundary allows the AI engine to treat the enclosed spaces as a single unit for the purpose of comprehensive compliance analysis, streamlining the evaluation process.

Once the regional boundary 1403 is established, the user or AI engine can select a space type from a predefined list of types 1404. This list may include various space types such as “Residential,” “Commercial,” “Assembly,” “Mercantile,” and “Mechanical,” each associated with specific accessibility requirements for wheelchair users. For example, if the selected space type is “Commercial,” the AI engine will apply the relevant commercial accessibility standards to the spaces within the boundary, checking for aspects such as the required turning radii, unobstructed pathways, and the placement of fixtures and furniture relative to these turning spaces. The user also has the option to create a new space type if the predefined options do not fully capture the intended use of the space, allowing for a tailored compliance analysis.

After the space type is selected, a tabular display 1405 presents the user with a detailed overview of the spaces within the boundary, along with their assigned types. The table 1405 provides a clear and organized summary of the analysis, showing which spaces have been classified, what types have been assigned, and any preliminary findings from the AI engine's compliance check. For example, the table 1405 may list each corridor or room within the boundary and indicate whether it meets the required turning radii for the “Commercial” space type. Non-compliant areas may be flagged in red within the boundary, as illustrated in FIG. 14B, prompting further investigation and potential design modifications.

The selection of a space like 1403 within the design plan triggers the AI engine to perform a comprehensive compliance analysis focused on wheelchair accessibility. This analysis may include checking for adequate turning radii at intersections, to verify if corridors are wide enough to accommodate both wheelchair users and other occupants, and verifying that spaces such as restrooms are designed to allow for smooth wheelchair navigation. The AI engine may also analyze the impact of door swings on wheelchair access, determining if doors obstruct turning areas when opened.

In addition to evaluating turning areas, the AI engine may assess the overall layout for potential obstacles that may hinder wheelchair maneuverability. For example, the AI engine may flag areas where furniture placement encroaches on the required turning space, or where a fixture like a sink or toilet is positioned too close to a wall, reducing the available space for a wheelchair to turn. The AI engine provides detailed feedback on these issues, allowing users to make informed decisions about how to adjust the design to meet accessibility standards. In some embodiments, the AI engine may also generate one or more versions of design plans with all non-compliant issues corrected automatically.

By combining these various analyses, the AI engine provides a holistic view of accessibility compliance for the selected spaces within the regional boundary 1403. If any issues are identified, the system can suggest automated revision options. For example, if a corridor is too narrow to allow a 360-degree turn for a wheelchair, the AI engine may recommend widening the corridor or reconfiguring adjacent rooms to create additional space. Similarly, if the layout of a restroom does not provide sufficient turning space around fixtures, the AI engine may suggest relocating the fixtures or altering the room dimensions to improve accessibility.

### User Interaction and Experience

In some embodiments, the present invention includes a controller operative to analyze a building described via one or more of: a floorplan, two-dimensional reference, and/or Revit® compatible file, to ascertain whether the building described possesses a set of conditions useful to determine compliance with code set. In addition, in some embodiments, a process executed by an AI engine may ascertain building attributes and analyze the building attributes may be modified in order to bring the building into compliance. A user interface may present suggested modifications to a user. Some embodiments may also include designation and/or ranking of variables that may be modified in order to bring a building into compliance. By way of non-limiting example, variables may relate to one or more of: magnitude of structural changes, cost to implement changes, time to implement changes, impact of a change(s) on a desired use of the building, and duration of a proposed change.

In another aspect, in some embodiments, suggested modifications may be ranked according to a priority ranking of features input via a user interface. For example, a user may input priority rankings that dictate that a number of a certain type of room or unit must be maintained above a threshold within the plan, such as, for example, the plan must include: ten residential units, each unit with three bedrooms and two bathrooms and kitchen a living room; or at least four units with three bedrooms each; a second priority may include room sizes of a minimum and/o maximum size; a third priority may include a washer and dryer area; a fourth priority may include a common area of a minimum size; and other prioritized attributes to be included in a building design. AI and/or user input may modify a design of the building to bring the building into compliance with an applicable code while also adhering to the priority ranking of features.

Still further, in some embodiments, the controller may assess how assignment of different classes of space to one or more designated areas may alter conformance of a design with a specified code. Furthermore, in some embodiments, particular attributes of a building may be analyzed based upon laws or regulations in effect within a geopolitical boundary encompassing the building. In some embodiments, multiple disparate user interfaces may be used to communicate calculated parameters associated with determined attributes in order to give a user an improved experience while determining code compliance of a given design plan, as well as changes in a determination of code compliance based upon a change in one or more of the building attributes.

In an example, a user interface may be designed for an optimal user experience in evaluating an existence (or non-existence) of attributes necessary in order for a design plan to be in compliance with a specified code. In some embodiments a design may be evaluated by any of the various processes as have been described herein. After a design plan is received into a controller, an interface may be presented to a user to allow for interactive assessment of attributes required for code compliance.

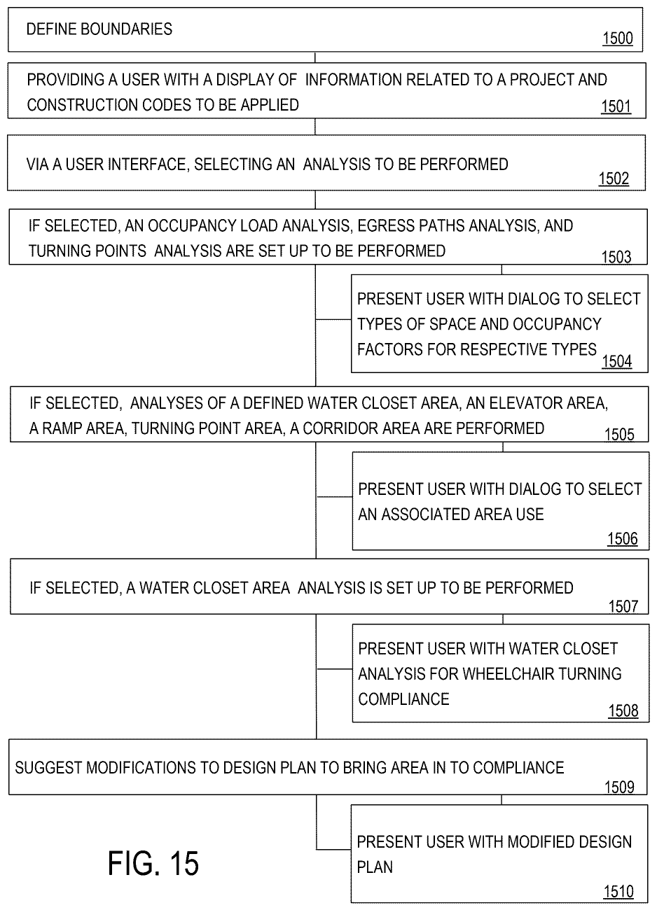

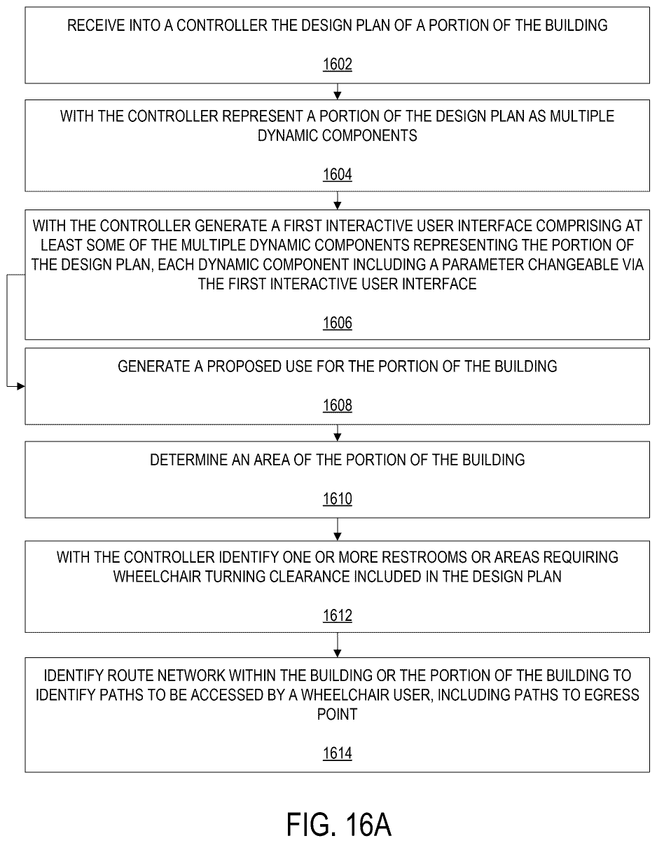

Referring now to FIG. 15, an exemplary method for conducting wheelchair turning compliance analysis within a building design is illustrated, providing detailed steps that guide a user through the process of assessing and improving the accessibility of a given space. The method is embedded in a user experience designed to be both interactive and thorough, so that every aspect of wheelchair maneuverability is considered and evaluated.

At step 1500, the user begins by defining boundaries within the design plan that are relevant to the analysis. These boundaries may encompass specific areas of interest, such as corridors, rooms, or transitional spaces where wheelchair turning is critical. For example, a user may draw a boundary around a hallway intersection or the space in front of an elevator to determine if these areas are properly designed with wheelchair turning radii. The defined boundaries set the stage for focused analysis, allowing the AI engine to concentrate on the most critical spaces where wheelchair maneuverability could be compromised.

At step 1501, the user is provided with an interactive user interface that displays project-specific information, including the attributes of the building that must be considered for compliance with accessibility standards, related to wheelchair turning. The user interface may include data on corridor widths, door swing directions, the presence of obstacles, and other factors that influence wheelchair accessibility. The user interface may also be designed to offer a comprehensive overview of the relevant codes and standards that apply to the project, so that the analysis is grounded in the correct regulatory framework.

At step 1502, the user selects the type of analysis to be performed. The options available may include various types of accessibility analyses, such as turning radius assessment, egress path evaluation, or overall space usability for wheelchair users. In some embodiments, the user may choose to perform a comprehensive analysis that encompasses all aspects of wheelchair accessibility within the defined boundaries. For example, the user may select an analysis that checks the turning radius at every critical intersection within a floor plan, determining if wheelchair users can navigate the space without obstruction.

At step 1503, if the user has selected an analysis related to occupancy load, egress paths, and turning points, the system sets up these analyses for the designated spaces. The AI engine calculates the maximum occupancy load based on the space's size and intended use, determining if the egress paths and turning areas are sufficient to accommodate all occupants, including those using wheelchairs. The system may simulate an emergency evacuation scenario, analyzing how wheelchair users navigate the space and identifying any potential bottlenecks or obstacles that may hinder safe egress.

At step 1504, the user may be presented with a dialog that allows them to select the types of spaces within the defined boundaries and the associated occupancy factors. For example, the user may select “Commercial Office” as the space type and choose an occupancy factor that reflects the expected density of occupants. The system may provide predefined options or allow the user to manually input specific details. Additionally, the dialog may offer guidance on the relevant accessibility codes that apply to each space type, helping the user make informed decisions.

At step 1505, the system performs detailed analyses of specific areas (e.g., selected by the user at step 1504) that are critical for wheelchair accessibility, such as water closet areas, elevator lobbies, ramps, turning points, and corridors. For example, the AI engine may analyze the space in front of an elevator to determine if a wheelchair user can turn around comfortably without being obstructed by nearby walls or other fixtures. The system also evaluates ramps for their slope, surface texture, and the presence of handrails, determining if they are safe and accessible for wheelchair users.

At step 1506, the user may be presented with a dialog to select the associated area use, such as a residential unit, commercial space, or public assembly area. This selection may influence the specific accessibility requirements that the AI engine applies to the analysis. For example, a commercial space may require wider corridors and larger turning areas to accommodate higher foot traffic and more frequent use by wheelchair users. The dialog provides the user with options to either accept the AI engine's automatic classification of the space or to manually input the intended use, allowing for a tailored analysis.

At step 1507, if the user has selected to perform an analysis specifically for water closet areas, the system sets up this analysis with a focus on wheelchair turning compliance. The AI engine checks whether the water closet area provides sufficient space for a wheelchair to turn around, including evaluating the clearances around fixtures such as toilets, sinks, and partitions. The system may simulate a wheelchair user navigating the water closet area, identifying any potential issues with space or layout that may hinder accessibility.

At step 1508, the system presents the user with the results of the analysis. The results may include detailed metrics on the dimensions of turning areas, the width of corridors, the slope of ramps, and other critical factors that influence wheelchair accessibility. The system highlights any areas that do not meet the required standards, providing the user with a clear understanding of where improvements are needed. For example, if a corridor is too narrow for a wheelchair to make a 180-degree turn, the system may flag this area and provide specific measurements to guide necessary modifications.

At step 1509, based on the analysis results, the system may suggest modifications to the design plan to bring the identified non-compliant areas into compliance with accessibility standards. These suggestions may include widening corridors, increasing the size of turning areas, repositioning fixtures, or altering the layout of a space to remove obstacles. The system provides detailed recommendations, including suggested dimensions and alternative configurations, helping the user make informed decisions about how to improve the design.

Finally, at step 1510, the system presents the user with a modified design plan that incorporates the suggested changes. This updated plan is designed to meet all relevant accessibility standards, particularly those related to wheelchair turning compliance. The user can review the modified plan, make further adjustments if necessary, and finalize the design with confidence that it meets the required codes. The system may also offer a comparison view, showing the original plan alongside the modified version, highlighting the improvements made to enhance wheelchair accessibility. In some embodiments, the system may provide automatically revised design plan versions with corrected non-compliant spaces. The user can either accept any of the automatically revised design plan versions or make further changes which are then re-analyzed by the system.

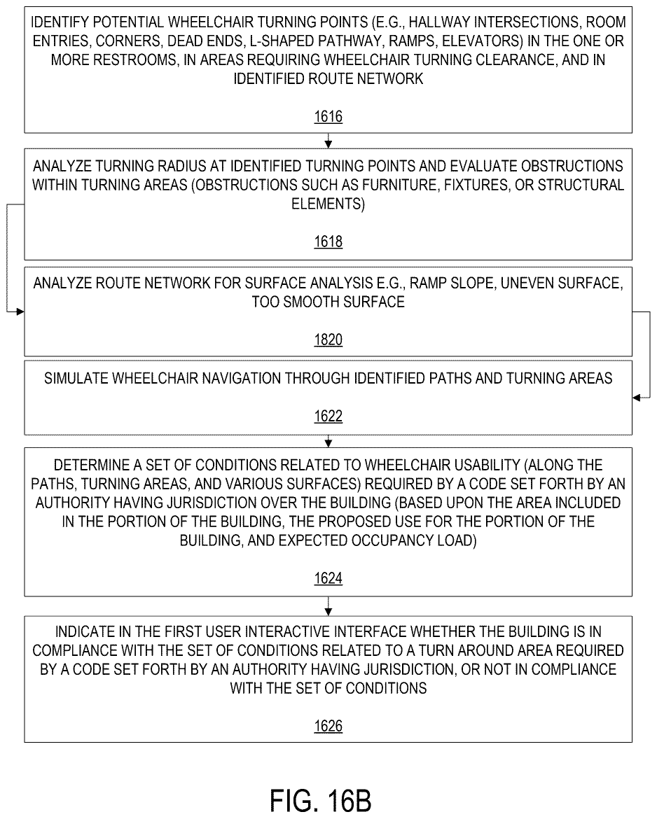

Referring now to FIGS. 16A-16B, a flowchart of an exemplary process is illustrated that may be performed by a controller running an AI engine for analyzing and enhancing wheelchair turning compliance within a portion of a building's design plan.

At step 1602, the method begins by receiving into a controller the design plan of a portion of the building. The design plan can be a detailed architectural drawing, a floor plan, or any other type of schematic that represents the spatial layout of the building. The received design plan serves as the foundation for the subsequent analysis, providing the AI engine with the necessary information to evaluate the space for wheelchair accessibility. For example, in a large commercial building, this step may involve uploading a detailed floor plan that includes corridors, restrooms, and entry points, all of which are critical areas for wheelchair users.

At step 1604, with the controller, the portion of the design plan is represented as multiple dynamic or discernible components. These dynamic components may include walls, doors, fixtures, and open spaces, which are all used for determining how wheelchair users will navigate the space. Each component may be modeled with flexibility in mind, allowing the AI engine to simulate various scenarios and assess how changes to the design may impact accessibility. For example, a door may be represented as a dynamic component that can be virtually opened or closed to see how its placement affects the available turning space for a wheelchair.

At step 1606, with the controller, a first user interactive interface is generated, comprising at least some of the multiple dynamic components representing the portion of the design plan. Each dynamic component includes a parameter that is changeable via the first interactive user interface. This interactive user interface provides a powerful tool for designers and architects, allowing them to manipulate the design plan in real-time and immediately see the effects of their changes on wheelchair accessibility. For example, an architect may adjust the width of a corridor within the interface and observe how this change impacts the ability of a wheelchair to turn around or navigate through the space.

At step 1608, the method involves generating a proposed use for the portion of the building. The proposed use may include designations such as residential, commercial, or mixed-use, which will influence the specific accessibility standards that the AI engine applies during its analysis. For example, a space designated as a healthcare facility will require different considerations for wheelchair accessibility than a space intended for office use. The proposed use helps the AI engine tailor its analysis to the specific requirements of the intended function of the space. In some embodiments, the proposed use may include designations such as restroom, water closet area, ramp area, elevator area, corridor, or even a room. The proposed use may be determined by the AI engine automatically e.g., based on markings on the design plan, or may be specified by a user through the first interactive user interface.

At step 1610, the area of the portion of the building is determined. This step may involve calculating the square footage of the space within the defined boundaries, which is a useful factor in assessing compliance with accessibility standards. The AI engine may also break down the area into smaller sections to provide a more detailed analysis of each component's accessibility. For example, in a large open office space, the AI engine may calculate the area around workstations, corridors, and entryways to determine if each section provides adequate space for wheelchair maneuverability. In some embodiments, dimensions like length, width, height, or distance may also be calculated for various dynamic components.

At step 1612, with the controller, the method identifies one or more restrooms or areas requiring wheelchair turning clearance included in the design plan. This step targets the specific areas where wheelchair users are most likely to encounter difficulties. The AI engine scans the design plan for areas like restrooms, where sufficient turning space is critical. For example, if a restroom has a narrow entrance or insufficient space around fixtures like sinks or toilets, the AI engine will highlight these areas for further analysis and possible redesign.

At step 1614, the method identifies the route network within the building or the portion of the building to identify paths to be accessed by a wheelchair user, including paths to egress points. This step involves mapping out all the possible routes a wheelchair user may take within the building, from entry to egress. The AI engine analyzes these routes to determine if they are unobstructed and provide sufficient space for wheelchair users to navigate comfortably. For example, in an emergency evacuation scenario, the AI engine may assess whether the designated egress paths are wide enough and free from obstructions to allow a quick and safe exit for wheelchair users.

At step 1616, the method involves identifying potential wheelchair turning points within the building design. These points may include hallway intersections, room entries, corners, dead ends, L-shaped pathways, ramps, and elevators. The AI engine meticulously scans the design plan to pinpoint these areas where wheelchair users will need to execute turns, which are often the most challenging maneuvers in terms of space requirements. For example, an L-shaped hallway where a wheelchair user needs to make a 90-degree turn may be flagged for detailed analysis. The identification process is comprehensive, covering all possible scenarios within the building, including restrooms where wheelchair turning clearance is especially important.

At step 1618, the AI engine analyzes the turning radius at the identified turning points and evaluates any obstructions within these areas. Obstructions may include furniture, fixtures, structural elements, or any other physical barriers that may impede a wheelchair's ability to turn. This analysis is also critical because even a space that meets the minimum width requirements may be rendered non-compliant if obstructions reduce the effective turning space. For example, a hallway may be wide enough, but if a column or a piece of furniture is placed too close to a corner, it may prevent a wheelchair from making a full turn. The AI engine evaluates these scenarios, providing precise measurements and identifying areas where adjustments are needed.

At step 1620, the method involves analyzing the route network for surface conditions that may impact wheelchair usability. This includes evaluating the slope of ramps, checking for uneven surfaces, and assessing whether surfaces are too smooth, which may make them slippery and hazardous for wheelchair users. The AI engine simulates how different surface conditions may affect a wheelchair's traction and stability, particularly in areas like ramps and entryways. For example, a ramp with an excessive slope may meet code requirements for height, but if the surface is too smooth, it may pose a significant risk to wheelchair users. The AI engine flags such issues and suggests modifications, such as adding a textured surface or reducing the slope of the ramp.

At step 1622, the AI engine may simulate wheelchair navigation through the identified paths and turning areas. This step is used for understanding how the design functions in real-world scenarios. The AI engine uses virtual models of various types of wheelchairs (and wheelchair users), including both manual and power wheelchairs, to simulate their movement through the building. These simulations reveal potential problem areas that may not be immediately apparent in the static design. For example, a simulation may show that a wheelchair user would struggle to navigate a tight corner near an elevator bank, leading to recommendations for design changes. The simulations also consider the interaction between multiple wheelchair users in shared spaces, such as large corridors or public areas.

At step 1624, the AI engine determines a set of conditions related to wheelchair usability that are required by the relevant building codes. These conditions may include the necessary dimensions for paths, turning areas, and surface treatments. The AI engine cross-references the building design with the specific code requirements set forth by the authority having jurisdiction over the building, based on the measured area or dimensions for the space, the proposed use of the space, and the expected occupancy load. For example, in a commercial building, the AI engine may determine if all corridors and doorways are wide enough to accommodate the number of wheelchair users anticipated during peak occupancy, and that all turning spaces comply with the required dimensions. The AI engine may also determine the compliance based on simultaneous use of the space by both, the multiple standing users and the users sitting on wheelchairs.

At step 1626, the method concludes by indicating in the first interactive user interface whether the building design is in compliance with the identified set of conditions related to wheelchair turning and usability. The interface provides a clear, visual representation of compliant and non-compliant areas within the design. For example, areas that meet the required standards may be highlighted in green, while those that need further attention may be marked in red. This visual feedback allows designers and architects to quickly identify problem areas and take corrective action. If the design is not in compliance, the AI engine provides specific recommendations for adjustments, such as widening a corridor or relocating a fixture to increase the available turning space.

In some examples, where there are non-compliant aspects, a trained artificial intelligence analysis of numerous examples of non-compliant designs and their subsequent design changes that remediated the issues may be used to suggest modifications based on an analysis of the design under review. In other examples, other algorithms may be used to provide such suggestions, such as by review of databases which track common required changes to make a building conform to requirements. Examples of improvements which the system may recommend to a user may include adding space free of impediments around a water closet. In other examples, design elements such as walls, lavatories, doors, etc. may be relocated to address non-compliance. Still further examples may address non-compliance aspects by adding features such as by suggesting the adding of a water closet or area of a building as a non-limiting example.

Highlighting, such as in the ways previously described, may be used to indicate one or both of points of compliance and points of non-compliance. The relevant portions of the code may be displayed such as in an overlay, or a pop-up window and may be matched in various manners to the design under analysis, such as with coloration as a non-limiting example. Alternatively, points of non-compliance may be highlighted. These aspects of the user interface experience may improve effectiveness and/or efficiency for inspectors by providing this highlighting or other summarization of points of compliance and points of non-compliance.

Other tools may also be provided through the user interface experience to support users such as, for example, allowing the user to click and drag a cursor over a space designated as a room. Various symbols and icons may be overlayed on the design to indicate various artifacts, corners, stairs, measurements such as door width, access to measurements or design data of various kinds and the like. The user may be able to zoom to portions of the drawing for more detailed review and/or the display of more detailed measurements and design data. Furthermore, the user may be able to zoom to features such as in a non-limiting example a doorway to allow a check of calibration of the scale of the design or even a recalibration of the scale, where such a recalibration may drive a reassessment of compliance by the system.

### Additional Methods of Model Formation

There may be alternative methods of receiving data from various sources that can be used to generate a design or to supplement a design created in the manners as have been described previously. For example, the system may receive an architectural file with intelligent features of various kinds which will be discussed in further detail following. The present system may operate in concert with a BIM or CAD design system, for example, as an add-in to these design systems and then the present system may have access to design elements, location data, and the like directly. In other examples, the present system may access BIM or CAD design system data by loading data files from said systems. In further examples, the present system may operate to capture data from display screens that are displaying designs from the said BIM or CAD design systems.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

These various elements may be loaded from exemplary files and extracted for their relevant information. Other file types in addition to the Revit® types previously mentioned may include in a non-limiting sense DGN, DWF, DWG, DXF, IFC, SAT, SKP, ODBC, HTML, TXT, and gbXML file types. As mentioned, systems of the present type may be configured to extract information based on defined file structure of the input file times. In addition, learned aspects may be applied to interpret the designs and assign components or alter certain information about a component.

### Glossary

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Vector File” as used herein a vector file is a computer graphic that uses mathematical formulas to render its image. In some embodiments, a sharpness of a vector file will be agnostic to size within a range of sizes viewable on smart device and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The methods and apparatus of the present invention are presented herein generally, by way of example, to actions, processes, and deliverables important to industries such as the construction industry, by generating improved determination of compliance with specified codes, based on inputted design plans, floor plans or other construction related diagrams, however, design plans may include almost any artifact that may be converted to a pixel pattern.

Some specific embodiments of the present invention include input of a design plan (e.g., a blueprint, design plan floorplan, or other two-dimensional artifact) so that it may be analyzed using artificial intelligence and used to generate a determination of compliance with specified conditions included in one or multiple building codes in a short time period. However, unless expressly indicated in an associated claim, the present invention is not limited to analysis of design plans for any particular industry. The examples provided herein are illustrative in nature and show that the present invention may use controllers and/or neural networks and artificial-intelligence (AI) techniques to identify aspects of a building described by a design plan and specify quantities for variables used to generate a bid or other proposal for completion of a project (or some subset of a project) represented by the design plan. For example, aspects of a building that are identified may include one or more of: walls or other boundaries; doorways; doors; plumbing; plumbing fixtures; hardware; fasteners; wall board; flooring; a level of complexity and other variables ascertainable via analysis of the design plan. AI analysis provides values for variables used in estimations involved in a project bidding process or related activity.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### CONCLUSION

A number of embodiments of the present disclosure have been described. While this specification contains many specific implementation details, there should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood that the drawings and the detailed description thereto are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

What is claimed:

1-30. (canceled)

31. An apparatus for analyzing wheelchair turning clearance with a relevant building code based upon artificial intelligence analysis of a design plan, the apparatus comprising: a display screen; a digital storage medium comprising executable software code; and a controller including a processor, wherein the executable software code, when executed by the processor, causes the processor to: receive a design plan of at least a portion of a building; convert the design plan into multiple dynamic components, each representing a structural element or fixture; generate a first interactive user interface on the display screen comprising at least some of the dynamic components, each including one or more parameters changeable via the interface; identify one or more wheelchair turning points within the design plan; calculate a turning radius at each identified turning point; determine a set of conditions related to wheelchair turning clearance compliance required by the relevant building code based on the identified turning points; and indicate in the first interactive user interface whether the building is in compliance with the set of conditions.

32. The apparatus of claim 1, wherein the controller is further configured to simulate, within the first interactive user interface, a movement of a virtual wheelchair user through the identified turning points to assess real-world usability and identify potential issues with the design plan.

33. The apparatus of claim 1, wherein the controller is further configured to receive as input a digital representation of a building code, parse the code to extract requirements for wheelchair turning clearance, and apply the extracted requirements to the analysis of the design plan.

34. The apparatus of claim 1, wherein the controller is further configured to provide, within the first interactive user interface, suggested modifications to the design plan if the building is determined to be non-compliant with the set of conditions.

35. The apparatus of claim 1, wherein the controller is further configured to evaluate surface conditions along a path identified within the design plan, the path leading to a point of egress, and to flag potential hazards in the surface conditions.

36. The apparatus of claim 1, wherein the controller is further configured to identify obstructions within the calculated turning radius at each turning point, the obstructions comprising at least one of a fixture, a piece of furniture, or a structural element.

37. The apparatus of claim 1, wherein the controller is further configured to determine a proposed use of the building based on the design plan and to select a relevant building code for compliance analysis based on the proposed use.

38. The apparatus of claim 1, wherein the controller is further configured to generate a visual representation in the first interactive user interface, including color-coded indicators to signify whether the calculated turning radius at each turning point complies with or deviates from the set of conditions.

39. The apparatus of claim 1, wherein the controller is further configured to analyze the design plan to identify one or more restrooms or areas requiring wheelchair turning clearance and to perform a compliance analysis specific to those areas.

40. The apparatus of claim 1, wherein the controller is further configured to determine a count of wheelchair users that the building can accommodate safely during emergency evacuations based on the analysis of turning points and egress paths.

41. The apparatus of claim 1, wherein the controller is further configured to analyze a route network within the design plan, the route network comprising the identified turning points, and to evaluate the number of turning points along a path to a point of egress.

42. The apparatus of claim 11, wherein the controller is further configured to determine whether the number of turning points along the path to the point of egress exceeds a permissible number as specified by the relevant building code.

43. The apparatus of claim 1, wherein the controller is further configured to analyze a slope of a ramp included in the route network and to determine compliance with the relevant building code for ramp accessibility.

44. The apparatus of claim 1, wherein the controller is further configured to receive user input via the first interactive user interface to modify at least one parameter of a dynamic component, and to update the compliance analysis in real time based on the modification.

45. The apparatus of claim 1, wherein the controller is further configured to parse a building code document to extract variable requirements for different types of wheelchair turning spaces, including circular and T-shaped turning areas, and to apply the appropriate requirements to each identified turning point.

46. The apparatus of claim 1, wherein the controller is further configured to store a history of user modifications and compliance analyses, and to use the stored history to train the artificial intelligence engine for improved future analyses.

47. The apparatus of claim 1, wherein the controller is further configured to generate a compliance report summarizing compliant and non-compliant areas, the report including suggested modifications and references to specific building code provisions.

48. The apparatus of claim 1, wherein the controller is further configured to simulate occupancy load scenarios and to analyze the impact of predicted occupancy on wheelchair turning clearance compliance.

49. The apparatus of claim 1, wherein the controller is further configured to analyze the effect of door swing direction and door width on the available turning radius at each identified turning point.

50. The apparatus of claim 1, wherein the controller is further configured to receive as input both a design plan and a building code in digital format, to automatically map requirements from the building code to corresponding features in the design plan, and to generate a visual overlay in the user interface indicating compliance status for each mapped feature.
